(19) United States
(12) Patent Application Publication
(10) Pub. No.: US 2017/0062739 A1
(43) Pub. Date: Mar. 2, 2017

(54) ORGANOMETALLIC COMPOUND AND ORGANIC LIGHT-EMITTING DEVICE INCLUDING THE SAME

(71) Applicant: SAMSUNG ELECTRONICS CO., LTD., Suwon-si (KR)

(72) Inventors: Whail CHOI, Seoul (KR); Seungyeon KWAK, Yongin-si (KR); Yoonhyun KWAK, Seoul (KR); Sangdong KIM, Seoul (KR); Sangyoon LEE, Seoul (KR); Byoungki CHOI, Hwaseong-si (KR); Hyeonho CHOI, Seoul (KR); Kyuyoung HWANG, Anyang-si (KR)

(21) Appl. No.: 15/245,431

(22) Filed: Aug. 24, 2016

(30) Foreign Application Priority Data
Aug. 25, 2015 (KR) 10-2015-0119823
Aug. 19, 2016 (KR) 10-2016-0105589

(51) Int. Cl. H01L 51/00; C09K 11/06; C07F 15/00

(52) U.S. Cl. CPC H01L 51/0088; C07F 15/0026; C09K 11/06; C09K 2211/1007; C09K 2211/1044; C09K 2211/185; H01L 51/5012

(57) ABSTRACT

An organometallic compound represented by Formula 1:

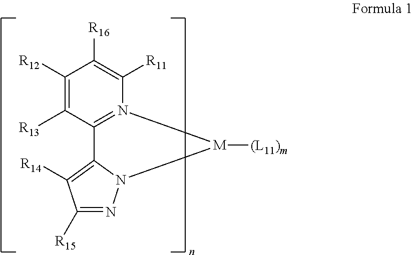

wherein, in Formula 1, L₁₁, M, m, n, and R₁₁ to R₁₆ are the same as described in the specification.

### CROSS-REFERENCE TO RELATED APPLICATION

This application claims priority to Korean Patent Application No. 10-2015-0119823, filed on Aug. 25, 2015 and Korean Patent Application No. 10-2016-0105589, filed on Aug. 19, 2016, and all the benefits accruing therefrom under 35 U.S.C. §119, in the Korean Intellectual Property Office, the contents of which are incorporated herein in their entirety by reference.

### BACKGROUND

1. Field

The present disclosure relates to an organometallic compound and an organic light-emitting device including the same.

2. Description of the Related Art

Organic light-emitting devices (OLEDs) are self-emission devices that have wide viewing angles, high contrast ratios, and short response times. In addition, OLEDs exhibit excellent luminance, driving voltage, and response speed characteristics, and produce full-color images.

In an example, an organic light-emitting device includes an anode, a cathode, and an organic layer disposed between the anode and the cathode, wherein the organic layer includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transit from an excited state to a ground state to thereby generate light.

Various types of organic light emitting devices are known. However, there still remains a need in OLEDs having low driving voltage, high efficiency, high brightness, and long lifespan.

### SUMMARY

Provided are an organometallic compound and an organic light-emitting device including the same.

Additional aspects will be set forth in part in the description which follows and, in part, will be apparent from the description, or may be learned by practice of the presented embodiments.

According to an aspect of an embodiment, an organometallic compound is represented by Formula 1:

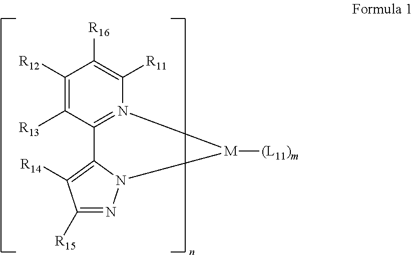

wherein, in Formula 1,

M is selected from osmium (Os) and ruthenium (Ru),

R₁₁ to R₁₃ and R₁₆ are each independently selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, and a substituted or unsubstituted monovalent non-aromatic condensed heteropolycyclic group, provided that at least one selected from R₁₁ to R₁₃ and R₁₆ is selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, R₁₄ and R₁₅ are each independently selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, and a substituted or unsubstituted C₆-C₆₀ aryl group,

n is selected from 1, 2, and 3,

L₁₁ is selected from a monodentate ligand and a bidentate ligand, and

m is selected from 0, 1, 2, 3, and 4.

According to an aspect of another embodiment, an organic light-emitting device includes:

a first electrode;

a second electrode; and

an organic layer disposed between the first electrode and the second electrode,

wherein the organic layer includes an emission layer and at least one organometallic compound represented by Formula 1.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view of an organic light-emitting device according to an embodiment;

FIG. 2 is a graph of normalized intensity (arbitrary units, a.u.) versus wavelength (nanometers, nm) illustrating photoluminescence (PL) spectra of Compounds 1 and 3; and

FIG. 3 is a graph of weight (percent, %) versus temperature (° C.) illustrating thermal gravimetric analysis (TGA) result of Compound 3.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Expressions such as “at least one of,” when preceding a list of elements, modify the entire list of elements and do not modify the individual elements of the list.

The present disclosure will now be described more fully with reference to exemplary embodiments. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art. Advantages, features, and how to achieve them of the present disclosure will become apparent by reference to the embodiment that will be described later in detail, together with the accompanying drawings. This inventive concept may, however, be embodied in many different forms and should not be limited to the embodiments.

Hereinafter, embodiments are described in detail by referring to the attached drawings, in which like reference numerals denote like elements, and a redundant explanation thereof will not be provided herein.

As used herein, the singular forms “a,” “an”, and “the” are intended to include the plural forms as well, unless the context clearly indicates otherwise.

The term “or” means “and/or.” It will be further understood that the terms “comprises” and/or “comprising” or “includes” and/or “including” as used herein specify the presence of stated features, regions, integers, steps, operations, elements, and/or components, but do not preclude the presence or addition of one or more other features, regions, integers, steps, operations, elements, and/or components.

It will be understood that when a layer, region, or component is referred to as being “on” or “onto” another layer, region, or component, it may be directly or indirectly formed on the other layer, region, or component. That is, for example, intervening layers, regions, or components may be present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Sizes of components in the drawings may be exaggerated for convenience of explanation. In other words, since sizes and thicknesses of components in the drawings are arbitrarily illustrated for convenience of explanation, the following embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

The term “organic layer” as used herein refers to a single layer and/or multiple layers disposed between a first electrode and a second electrode of an organic light-emitting device. A material included in the “organic layer” is not limited to an organic material.

An organometallic compound may be represented by Formula 1:

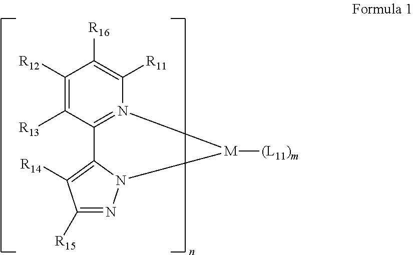

wherein, in Formula 1, M may be selected from a Group 1 transition metal, a Group 2 transition metal, and a Group 3 transition metal.

R₁₁ to R₁₃ and R₁₆ in Formula 1 may each independently be selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, and a substituted or unsubstituted monovalent non-aromatic condensed heteropolycyclic group, provided that at least one selected from R₁₁ to R₁₃ and R₁₆ may be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

In an embodiment, R₁₁, R₁₂, R₁₃, or R₁₆ in Formula 1 may be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, but embodiments are not limited thereto.

For example, in Formula 1, R₁₁ may be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, R₁₂, R₁₃, and R₁₆ may each independently be selected from hydrogen, deuterium, —F, —Cl, —Br, —I, a cyano group, a substituted or unsubstituted Cᵣ C₆₀ alkyl group, and a substituted or unsubstituted C₃-C₁₀ cycloalkyl group;

R₁₂ may be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₁, R₁₃, and R₁₆ may each independently be selected from hydrogen, deuterium, —F, —Cl, —Br, —I, a cyano group, a substituted or unsubstituted C₁-C₆₀ alkyl group, and a substituted or unsubstituted C₃-C₁₀ cycloalkyl group;

R₁₃ may be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₁, R₁₂, and R₁₆ may each independently be selected from hydrogen, deuterium, —F, —Cl, —Br, —I, a cyano group, a substituted or unsubstituted C₁-C₆₀ alkyl group, and a substituted or unsubstituted C₃-C₁₀ cycloalkyl group; or

R₁₆ may be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₁ to R₁₃ may each independently be selected from hydrogen, deuterium, —F, —Cl, —Br, —I, a cyano group, a substituted or unsubstituted C₁-C₆₀ alkyl group, and a substituted or unsubstituted C₃-C₁₀ cycloalkyl group, but embodiments are not limited thereto.

In another embodiment, two substituents of among R₁₁, R₁₂, R₁₃, and R₁₆ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, but embodiments are not limited thereto.

For example, in Formula 1, R₁₁ and R₁₆ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₂ and R₁₃ may each independently be selected from hydrogen, deuterium, —F, —Cl, —Br, —I, a cyano group, a substituted or unsubstituted C₁-C₆₀ alkyl group, and a substituted or unsubstituted C₃-C₁₀ cycloalkyl group;

R₁₁ and R₁₂ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₃ and R₁₆ may each independently be selected from hydrogen, deuterium, —F, —Cl, —Br, —I, a cyano group, a substituted or unsubstituted C₁-C₆₀ alkyl group, and a substituted or unsubstituted C₃-C₁₀ cycloalkyl group;

R₁₁ and R₁₃ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₂ and R₁₆ may each independently be selected from hydrogen, deuterium, —F, —Cl, —Br, —I, a cyano group, a substituted or unsubstituted Cᵣ C₆₀ alkyl group, and a substituted or unsubstituted C₃-C₁₀ cycloalkyl group;

R₁₂ and R₁₆ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₁ and R₁₃ may each independently be selected from hydrogen, deuterium, —F, —Cl, —Br, —I, a cyano group, a substituted or unsubstituted Cᵣ C₆₀ alkyl group, and a substituted or unsubstituted C₃-C₁₀ cycloalkyl group;

R₁₃ and R₁₆ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₁ and R₁₂ may each independently be selected from hydrogen, deuterium, —F, —Cl, —Br, —I, a cyano group, a substituted or unsubstituted Cᵣ C₆₀ alkyl group, and a substituted or unsubstituted C₃-C₁₀ cycloalkyl group; or

R₁₂ and R₁₃ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₁ and R₁₆ may each independently be hydrogen, deuterium, —F, —Cl, —Br, —I, a cyano group, a substituted or unsubstituted C₁-C₆₀ alkyl group, and a substituted or unsubstituted C₃-C₁₀ cycloalkyl group, but embodiments are not limited thereto.

In still another embodiment, three substituents of among R₁₁, R₁₂, R₁₃, and R₁₆ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, but embodiments are not limited thereto.

For example, in Formula 1, R₁₁, R₁₂, and R₁₆ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₃ may be selected from hydrogen, deuterium, —F, —Cl, —Br, —I, a cyano group, a substituted or unsubstituted Cᵣ C₆₀ alkyl group, and a substituted or unsubstituted C₃-C₁₀ cycloalkyl group;

R₁₁, R₁₃, and R₁₆ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₂ may be selected from hydrogen, deuterium, —F, —Cl, —Br, —I, a cyano group, a substituted or unsubstituted C₁-C₆₀ alkyl group, and a substituted or unsubstituted C₃-C₁₀ cycloalkyl group;

R₁₁ to R₁₃ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₆ may be selected from hydrogen, deuterium, —F, —Cl, —Br, —I, a cyano group, a substituted or unsubstituted C₁-C₆₀ alkyl group, and a substituted or unsubstituted C₃-C₁₀ cycloalkyl group; or

R₁₂, R₁₃, and R₁₆ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and R₁₁ may be selected from hydrogen, deuterium, —F, —Cl, —Br, —I, a cyano group, a substituted or unsubstituted C₁-C₆₀ alkyl group, and a substituted or unsubstituted C₃-C₁₀ cycloalkyl group, but embodiments are not limited thereto.

In still another embodiment, R₁₁, R₁₂, R₁₃, and R₁₆ may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, but embodiments are not limited thereto.

In some embodiments, in Formula 1, R₁₁ to R₁₃ and R₁₆ may each independently be selected from hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a neo-pentyl group, a cyclopentyl group, a cyclohexyl group, and a cycloheptyl group;

a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, and a neo-pentyl group, each substituted with at least one selected from deuterium, —F, —Cl, —Br, —I, and a cyano group;

a cyclopentyl group, a cyclohexyl group, and a cycloheptyl group, each substituted with at least one selected from deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, and a neo-pentyl group;

a phenyl group, a naphthyl group, a phenanthrenyl group, an anthracenyl group, a pyrenyl group, a chrysenyl group, a pyrrolyl group, a thiophenyl group, a furanyl group, an imidazolyl group, a thiazolyl group, an oxazolyl group, a pyridinyl group, a pyrazinyl group, a pyrimidinyl group, a quinolinyl group, an isoquinolinyl group, a benzoquinolinyl group, a quinoxalinyl group, a quinazolinyl group, a naphthyridinyl group, a benzofuranyl group, a benzothiophenyl group, a triazinyl group, a dibenzofuranyl group, and a dibenzothiophenyl group; and

a phenyl group, a naphthyl group, a phenanthrenyl group, an anthracenyl group, a pyrenyl group, a chrysenyl group, a pyrrolyl group, a thiophenyl group, a furanyl group, an imidazolyl group, a thiazolyl group, an oxazolyl group, a pyridinyl group, a pyrazinyl group, a pyrimidinyl group, a quinolinyl group, an isoquinolinyl group, a benzoquinolinyl group, a quinoxalinyl group, a quinazolinyl group, a naphthyridinyl group, a benzofuranyl group, a benzothiophenyl group, a triazinyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a pyridinyl group, a pyrazinyl group, a pyrimidinyl group, a triazinyl group, and —Si(Q₁)(Q₂)(Q₃),

provided that at least one selected from R₁₁ to R₁₃ and R₁₆ may be selected from a phenyl group, a naphthyl group, a phenanthrenyl group, an anthracenyl group, a pyrenyl group, a chrysenyl group, a pyrrolyl group, a thiophenyl group, a furanyl group, an imidazolyl group, a thiazolyl group, an oxazolyl group, a pyridinyl group, a pyrazinyl group, a pyrimidinyl group, a quinolinyl group, an isoquinolinyl group, a benzoquinolinyl group, a quinoxalinyl group, a quinazolinyl group, a naphthyridinyl group, a benzofuranyl group, a benzothiophenyl group, a triazinyl group, a dibenzofuranyl group, and a dibenzothiophenyl group; and

a phenyl group, a naphthyl group, a phenanthrenyl group, an anthracenyl group, a pyrenyl group, a chrysenyl group, a pyrrolyl group, a thiophenyl group, a furanyl group, an imidazolyl group, a thiazolyl group, an oxazolyl group, a pyridinyl group, a pyrazinyl group, a pyrimidinyl group, a quinolinyl group, an isoquinolinyl group, a benzoquinolinyl group, a quinoxalinyl group, a quinazolinyl group, a naphthyridinyl group, a benzofuranyl group, a benzothiophenyl group, a triazinyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a pyridinyl group, a pyrazinyl group, a pyrimidinyl group, a triazinyl group, and —Si(Q₁)(Q₂)(Q₃), wherein Q₁ to Q₃ may each independently be selected from a C₁-C₂₀ alkyl group and a C₆-C₆₀ aryl group.

In some embodiments, in Formula 1, R₁₁ to R₁₃ and R₁₆ may each independently be selected from hydrogen, a methyl group, an ethyl group, an n-propyl group, an iso-propyl group, an n-butyl group, an iso-butyl group, a sec-butyl group, a tert-butyl group, a cyclopentyl group, and a cyclohexyl group;

a methyl group, an ethyl group, an n-propyl group, an iso-propyl group, an n-butyl group, an iso-butyl group, a sec-butyl group, and a tert-butyl group, each substituted with at least one selected from deuterium, —F, —Cl, —Br, —I, and a cyano group;

a cyclopentyl group and a cyclohexyl group, each substituted with at least one selected from deuterium, —F, —Cl, —Br, —I, a cyano group, a methyl group, and an ethyl group;

a phenyl group, a thiophenyl group, a furanyl group, a thiazolyl group, an oxazolyl group, a dibenzofuranyl group, and a dibenzothiophenyl group; and

a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃, provided that at least one selected from R₁₁ to R₁₃ and R₁₆ may be selected from a phenyl group, a thiophenyl group, a furanyl group, a thiazolyl group, an oxazolyl group, a dibenzofuranyl group, and a dibenzothiophenyl group; and a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃, but embodiments are not limited thereto.

In some embodiments, in Formula 1, R₁₁ to R₁₃ may each independently be selected from hydrogen, a methyl group, an ethyl group, an n-propyl group, an iso-propyl group, an n-butyl group, an iso-butyl group, a sec-butyl group, a tert-butyl group, a cyclopentyl group, and a cyclohexyl group;

a methyl group, an ethyl group, an n-propyl group, an iso-propyl group, an n-butyl group, an iso-butyl group, a sec-butyl group, and a tert-butyl group, each substituted with at least one selected from deuterium, —F, —Cl, —Br, —I, and a cyano group;

a cyclopentyl group and a cyclohexyl group, each substituted with at least one selected from deuterium, —F, —Cl, —Br, —I, a cyano group, a methyl group, and an ethyl group;

a phenyl group, a thiophenyl group, a furanyl group, a thiazolyl group, an oxazolyl group, a dibenzofuranyl group, and a dibenzothiophenyl group; and

a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃, and

R₁₆ may be selected from a phenyl group, a thiophenyl group, a furanyl group, a thiazolyl group, an oxazolyl group, a dibenzofuranyl group, and a dibenzothiophenyl group; and

a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃, but embodiments are not limited thereto.

In some embodiments, in Formula 1, R₁₁, R₁₃, and R₁₆ may each independently be selected from hydrogen, a methyl group, an ethyl group, an n-propyl group, an iso-propyl group, an n-butyl group, an iso-butyl group, a sec-butyl group, a tert-butyl group, a cyclopentyl group, and a cyclohexyl group;

a methyl group, an ethyl group, an n-propyl group, an iso-propyl group, an n-butyl group, an iso-butyl group, a sec-butyl group, and a tert-butyl group, each substituted with at least one selected from deuterium, —F, —Cl, —Br, —I, and a cyano group;

a cyclopentyl group and a cyclohexyl group, each substituted with at least one selected from deuterium, —F, —Cl, —Br, —I, a cyano group, a methyl group, and an ethyl group;

a phenyl group, a thiophenyl group, a furanyl group, a thiazolyl group, an oxazolyl group, a dibenzofuranyl group, and a dibenzothiophenyl group; and

a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃, and

R₁₂ may be selected from a phenyl group, a thiophenyl group, a furanyl group, a thiazolyl group, an oxazolyl group, a dibenzofuranyl group, and a dibenzothiophenyl group; and

a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃, but embodiments are not limited thereto.

R₁₄ and R₁₅ in Formula 1 may each independently be selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, and a substituted or unsubstituted C₆-C₆₀ aryl group.

In some embodiments, R₁₄ and R₁₅ in Formula 1 may each independently be selected from hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a neo-pentyl group, a cyclopentyl group, a cyclohexyl group, a cycloheptyl group, a phenyl group, a naphthyl group, a phenanthrenyl group, an anthracenyl group, a pyrenyl group, and a chrysenyl group;

a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, and a neo-pentyl group, each substituted with at least one selected from deuterium, —F, —Cl, —Br, and —I; and a cyclopentyl group, a cyclohexyl group, a cycloheptyl group, a phenyl group, a naphthyl group, a phenanthrenyl group, an anthracenyl group, a pyrenyl group, and a chrysenyl group, each substituted with at least one selected from deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, and a neo-pentyl group, but embodiments are not limited thereto.

In some embodiments, R₁₄ and R₁₅ in Formula 1 may each independently be selected from hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, a cyclopentyl group, a cyclohexyl group, a phenyl group, and a naphthyl group; and

a methyl group, an ethyl group, an n-propyl group, an iso-propyl group, an n-butyl group, an iso-butyl group, a sec-butyl group, and a tert-butyl group, each substituted with at least one selected from deuterium and —F, but embodiments are not limited thereto.

In some embodiments, R₁₄ and R₁₅ in Formula 1 may each independently be selected from hydrogen, deuterium, —F, a cyano group, a methyl group, an ethyl group, an n-propyl group, an iso-propyl group, an n-butyl group, an iso-butyl group, a sec-butyl group, a tert-butyl group, —CD₃, —CD₂H, —CDH₂, —CF₃, —CF₂H, —CFH₂, and a phenyl group, but embodiments are not limited thereto.

In some embodiments, in Formula 1, R₁₄ may be hydrogen, and R₁₅ may be selected from —F, a cyano group, a methyl group, an ethyl group, an n-propyl group, an iso-propyl group, an n-butyl group, an iso-butyl group, a sec-butyl group, a tert-butyl group, —CD₃, —CD₂H, —CDH₂, —CF₃, —CF₂H, —CFH₂, and a phenyl group, but embodiments are not limited thereto.

In some embodiments, in Formula 1, R₁₅ may be hydrogen, and R₁₄ may be selected from —F, a cyano group, a methyl group, an ethyl group, an n-propyl group, an iso-propyl group, an n-butyl group, an iso-butyl group, a sec-butyl group, a tert-butyl group, —CD₃, —CD₂H, —CDH₂, —CF₃, —CF₂H, —CFH₂, and a phenyl group, but embodiments are not limited thereto.

In some embodiments, R₁₄ and R₁₅ in Formula 1 may each independently be selected from —F, a cyano group, a methyl group, an ethyl group, an n-propyl group, an iso-propyl group, an n-butyl group, an iso-butyl group, a sec-butyl group, a tert-butyl group, —CD₃, —CD₂H, —CDH₂, —CF₃, —CF₂H, —CFH₂, and a phenyl group, but embodiments are not limited thereto.

In Formula 1, n indicates the number of ligands represented by

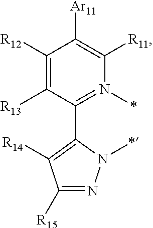

and * and *′ each indicate a binding site to M in Formula 1. In Formula 1, n may be selected from 1, 2, and 3, and when n is 2 or greater, the ligands may be identical to or different from each other.

In some embodiments, n in Formula 1 may be 2, but embodiments are not limited thereto.

In Formula 1, L₁₁ may be selected from a monodentate ligand and a bidentate ligand.

Examples of the monodentate ligand may include an iodide ion, a bromide ion, a chloride ion, sulfide, a thiocyanate ion, a nitrate ion, an azide ion, a hydroxide ion, a cyanide ion, an isocyanide ion, water, acetonitrile, pyridine, carbene, ammonia, carbon monoxide, PPh₃, PPh₂CH₃, PPh(CH₃)₂, and P(CH₃)₃, but embodiments are not limited thereto.

Examples of the bidentate ligand may include an oxalate ion, acetylacetonate, a picolinic acid, 2-(2-hydroxyphenyl)-pyridine, 2-phenylpyridine, 1,2-bis(diphenylphosphino)ethane (dppe), 1,1-bis(biphenylphosphino)methane (dppm), glycinate, ethylenediamine, 2,2′-bipyridine, and 1,10-phenanthroline, but embodiments are not limited thereto.

In some embodiments, L₁₁ in Formula 1 may be a ligand represented by one of Formulae 2-1 to 2-12, but embodiments are not limited thereto:

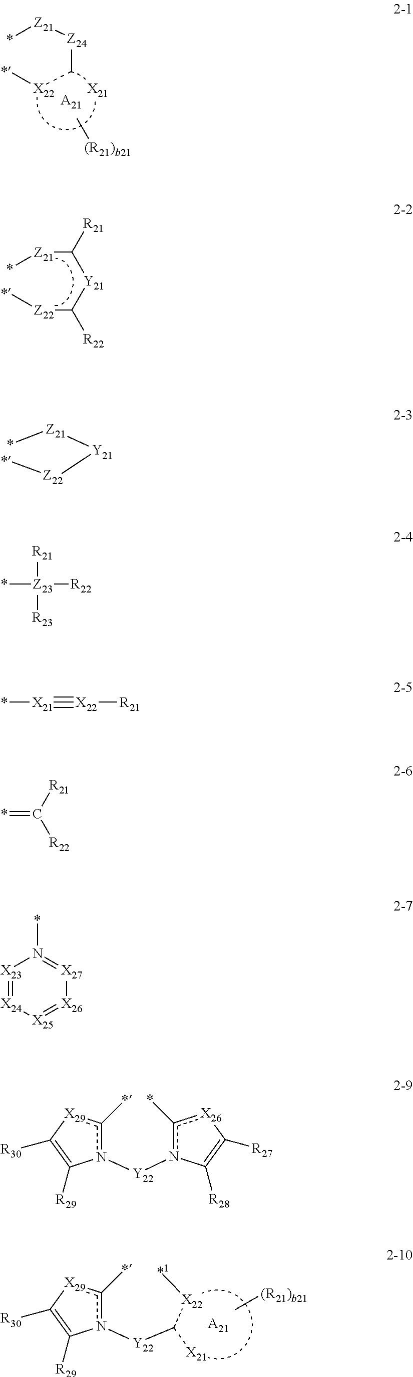

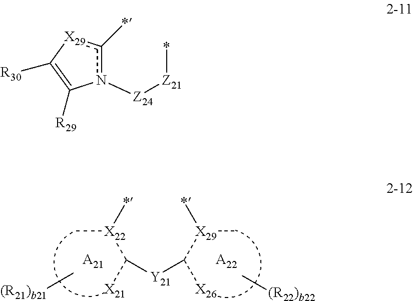

wherein, in Formulae 2-1 to 2-12,

A₂₁ and A₂₂ may each independently be selected from a C₅-C₂₀ carbocyclic group and a C₁-C₂₀ heterocyclic group,

X₂₁, X₂₂, X₂₅, and X₂₉ may each independently be selected from C and N,

X₂₃ may be N or C(Q₂₃), X₂₄ may be N or C(Q₂₄), X₂₅ may be N or C(Q₂₅), X₂₆ may be N or C(Q₂₆), X₂₇ may be N or C(Q₂₇),

X₂₈ may be O, S, or N(Q₂₈), X₂₉ may be O, S, or N(Q₂₉),

Y₂₁ and Y₂₂ may each independently be selected from a single bond, a double bond, a substituted or unsubstituted C₁-C₅ alkylene group, a substituted or unsubstituted C₂-C₅ alkenylene group, and a substituted or unsubstituted C₆-C₁₀ arylene group,

Z₂₁ and Z₂₂ may each independently be selected from N, O, N(R₂₅), P(R₂₅)(R₂₆), and As(R₂₅)(R₂₆),

Z₂₃ may be selected from phosphorus (P) and arsenic (As),

Z₂₄ may be selected from CO and CH₂,

R₂₁ to R₃₀ and Q₂₃ to Q₂₉ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, R₂₁ and R₂₂ may optionally be bound to form a ring, R₂₇ and R₂₈ may optionally be bound to form a ring, R₂₈ and R₂₉ may optionally be bound to form a ring, R₂₉ and R₃₀ may optionally be bound to form a ring,

b21 and b22 may each independently be selected from 1, 2, and 3, and

* and *′ each independently indicate a binding site to an adjacent atom.

In some embodiments, A₂₁ and A₂₂ in Formula 2-1 may each independently be a benzene group, a naphthalene group, an imidazole group, a benzimidazole group, a pyridine group, a pyrimidine group, a triazine group, a quinoline group, and an isoquinoline group, but embodiments are not limited thereto.

In some embodiments, X₂₂ and X₂₉ in Formula 2-1 may be N, but embodiments are not limited thereto.

In some embodiments, in Formula 2-7, X₂₃ may be C(Q₂₃), X₂₄ may be C(Q₂₄), X₂₅ may be C(Q₂₅), X₂₆ may be C(Q₂₆), and X₂₇ may be C(Q₂₇), but embodiments are not limited thereto.

In some embodiments, in Formula 2-8, X₂₈ may be N(Q₂₈) and X₂₉ may be N(Q₂₉), but embodiments are not limited thereto.

In some embodiments, Y₂₁ and Y₂₂ in Formulae 2-2, 2-3, and 2-8 may each independently be selected from a substituted or unsubstituted methylene group and a substituted or unsubstituted phenylene group, but embodiments are not limited thereto.

In some embodiments, Z₂₁ and Z₂₂ in Formulae 2-1 and 2-2 may be 0, but embodiments are not limited thereto.

In some embodiments, Z₂₃ in Formula 2-4 may be P, but embodiments are not limited thereto.

In some embodiments, R₂₁ to R₃₀ and Q₂₃ to Q₂₉ in Formulae 2-1 to 2-8 may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a pyridinyl group, and a pyrimidinyl group;

a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, and an imidazopyridinyl group; and a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, and an imidazopyridinyl group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, and an imidazopyridinyl group, but embodiments are not limited thereto.

In some embodiments, L₁₁ in Formula 1 may be a ligand represented by one of Formulae 3-1 to 3-25, but embodiments are not limited thereto:

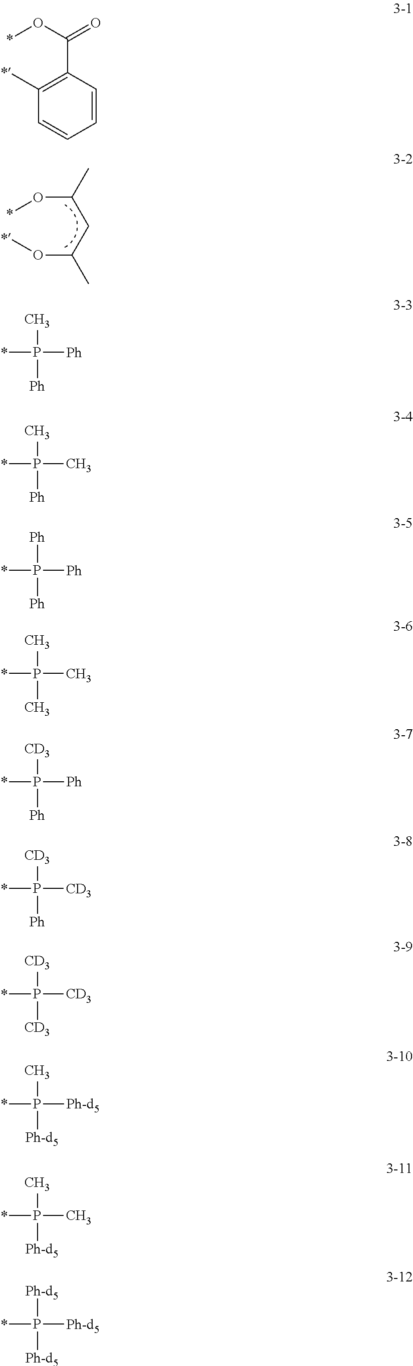

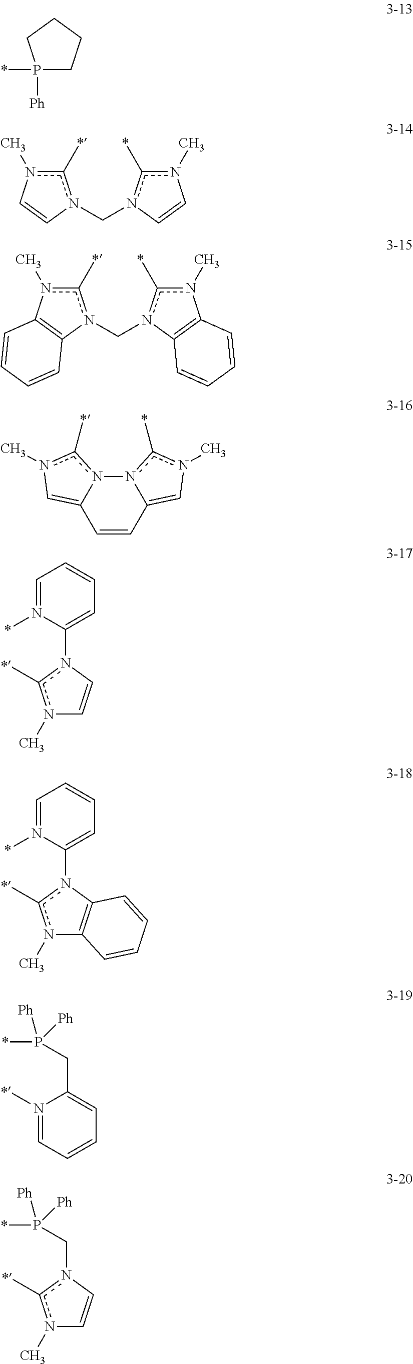

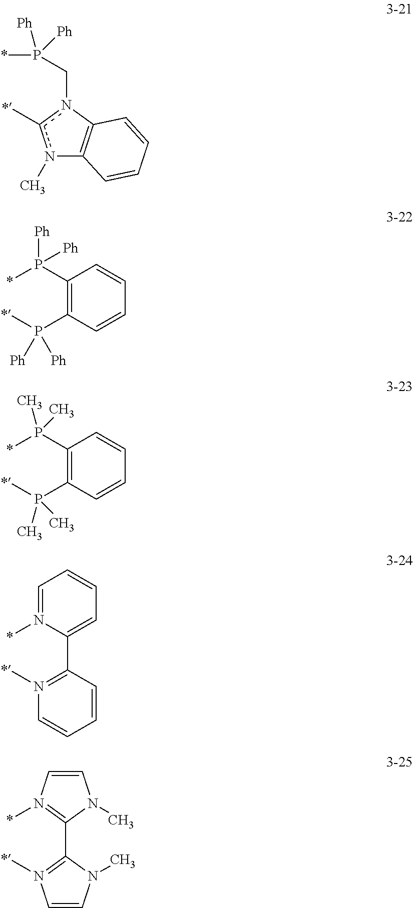

wherein, in Formulae 3-1 to 3-25,

“Ph” represents a phenyl group,

“Ph-d₅” represents a phenyl group of which all hydrogen atoms are substituted with deuterium atoms, and

* and *′ each indicate a binding site to an adjacent atom.

m in Formula 1 indicates the number of groups L₁₁, and m may be selected from 0, 1, 2, 3, and 4. When m is 2 or greater, groups L₁₁ may be identical to or different from each other.

In some embodiments, m in Formula 1 may be selected from 1 and 2, but embodiments are not limited thereto.

In some embodiments, the organometallic compound represented by Formula 1 may be a heteroleptic organometallic compound or a homoleptic organometallic compound, but embodiments are not limited thereto.

In some embodiments, in Formula 1, n may be 2 and m may be 2, but embodiments are not limited thereto.

In some embodiments, in Formula 1, n may be 2 and m may be 1, but embodiments are not limited thereto.

In some embodiments, in Formula 1, M may be selected from iridium (Ir), platinum (Pt), osmium (Os), ruthenium (Ru), rhodium (Rh), palladium (Pd), copper (Cu), silver (Ag), gold (Au), titanium (Ti), zirconium (Zr), hafnium (Hf), europium (Eu), terbium (Tb), and thulium (Tm). For example, M may be selected from Os or Ru.

In Formula 1, R₁₁ to R₁₃ may each independently be selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group,

R₁₆ may be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group,

R₁₄ and R₁₅ may each independently be selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, and a substituted or unsubstituted C₆-C₆₀ aryl group,

n may be selected from 1, 2, and 3,

L₁₁ may be selected from a monodentate ligand and a bidentate ligand, and

m may be selected from 0, 1, 2, 3, and 4, but embodiments are not limited thereto.

In some embodiments, the organometallic compound represented by Formula 1 may be represented by one of Formulae 1-1 to 1-9, but embodiments are not limited thereto:

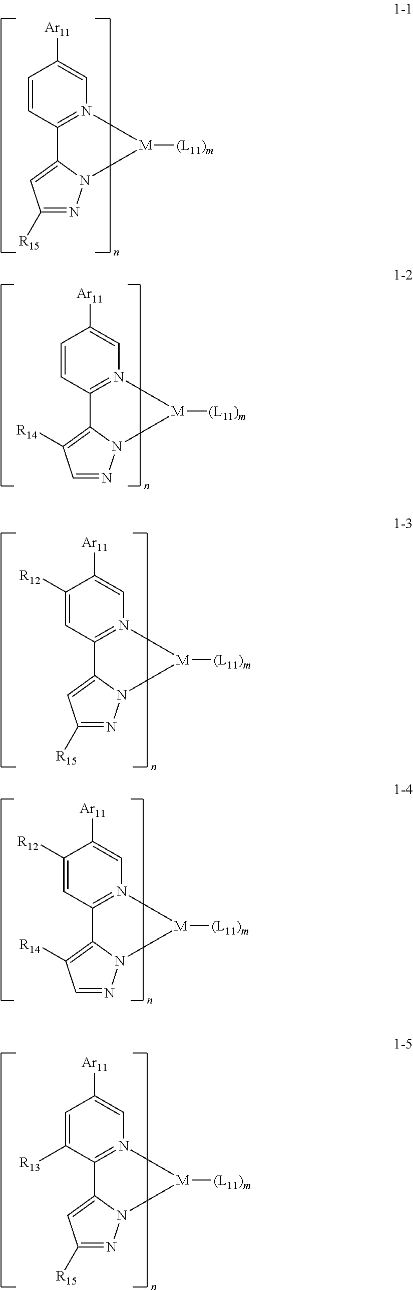

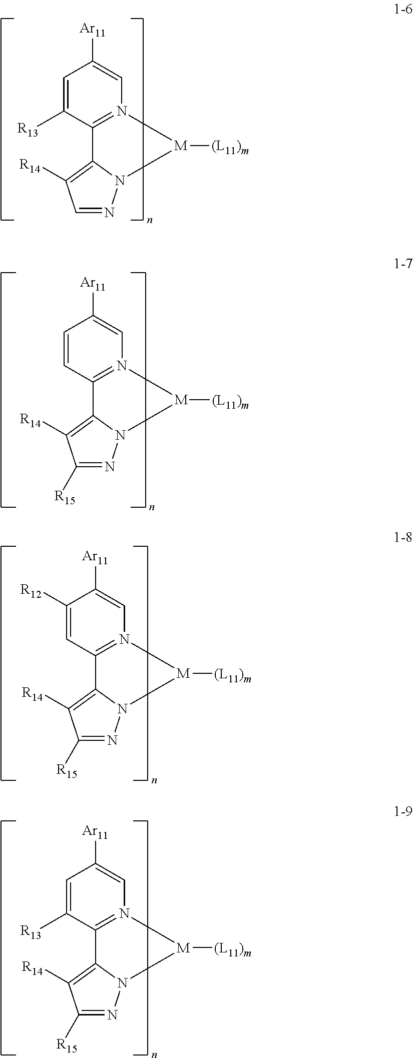

wherein, in Formulae 1-1 to 1-9,

M, R₁₂ to R₁₅, n, L₁₁, and m may be the same as those described above in connection with Formula 1, and

Ar₁₁ may be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, provided that each of R₁₂ to R₁₅ may not be hydrogen.

The organometallic compound represented by Formula 1 may be represented by one of Formulae 1-11 to 1-19 and 1-21 to 1-29, but embodiments are not limited thereto:

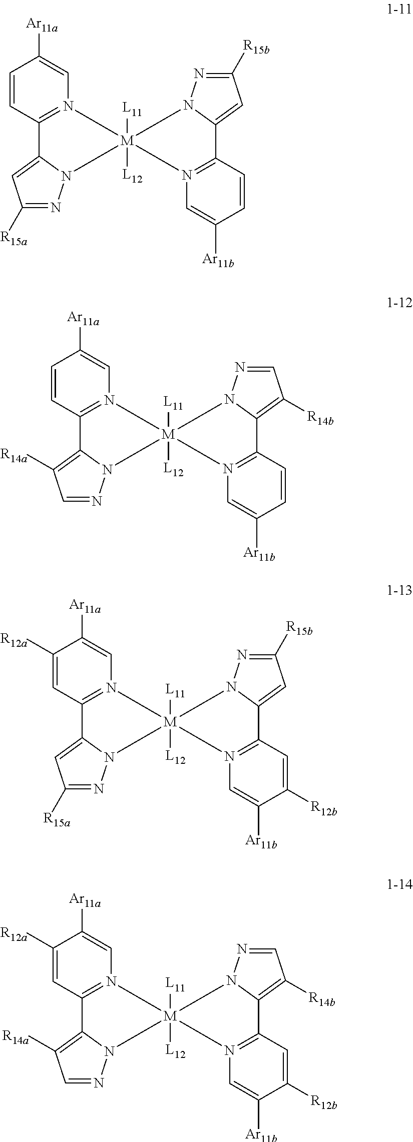

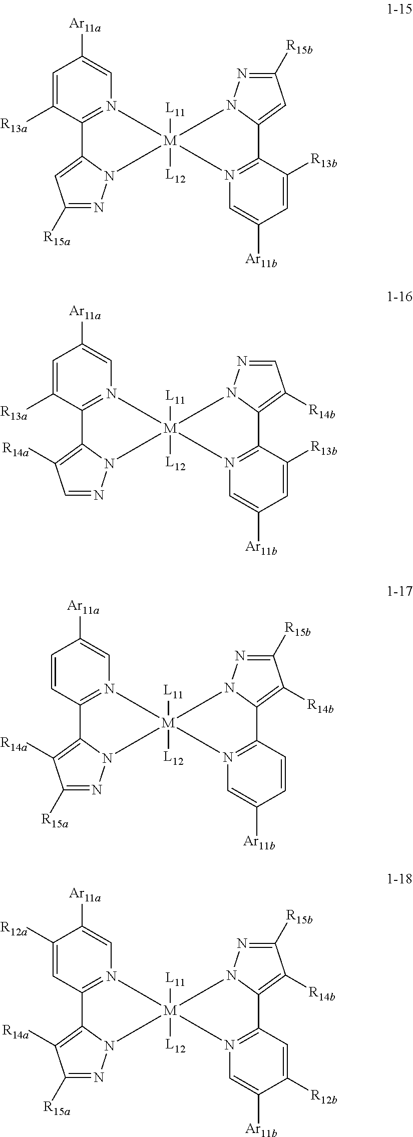

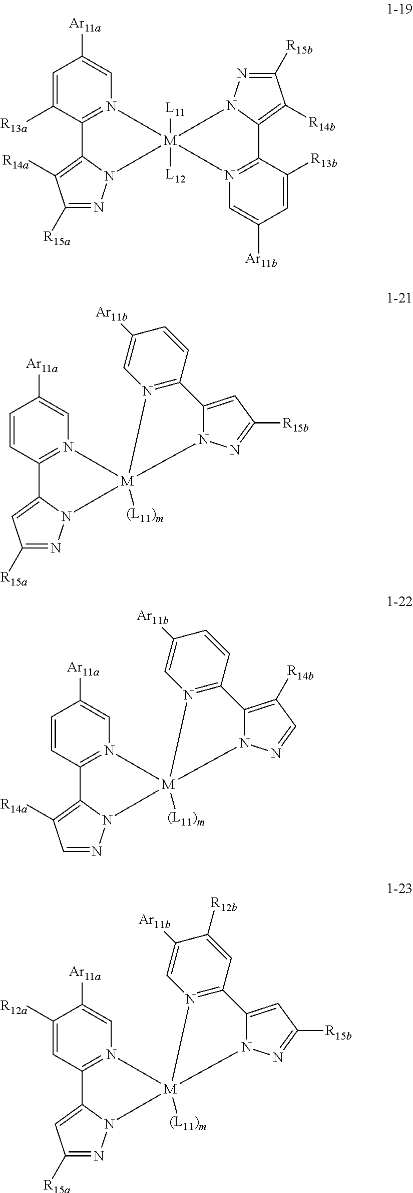

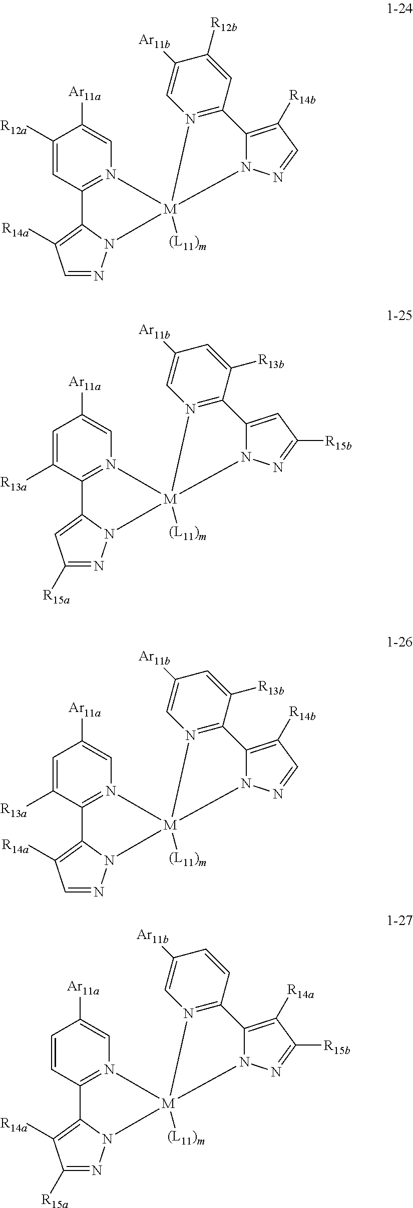

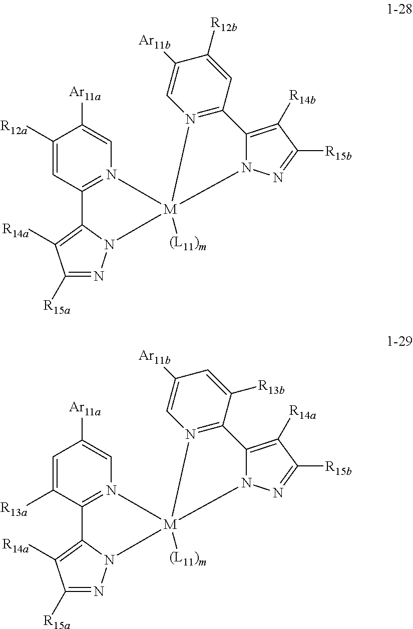

wherein, in Formulae 1-11 to 1-19 and 1-21 to 1-29,

L₁₁ and m may be the same as those described above in connection with Formula 1,

Ar₁₁ₐ and Ar_{11b} may each independently be selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group,

R₁₂ₐ and R_{12b} may each independently be the same as those described in Formula 1 in connection with R₁₂,

R₁₃ₐ and R_{13b} may each independently be the same as those described in Formula 1 in connection with R₁₃,

R₁₄ₐ and R_{14b} may each independently be the same as those described in Formula 1 in connection with R₁₄,

R₁₅ₐ and R_{15b} may each independently be the same as those described in Formula 1 in connection with R₁₅, and

L₁₂ may be the same as L₁₁ described in Formula 1,

provided that each of R₁₂ to R₁₅ may not be hydrogen.

The organometallic compound represented by Formula 1 may be selected from Compounds 1 to 176, but embodiments are not limited thereto:

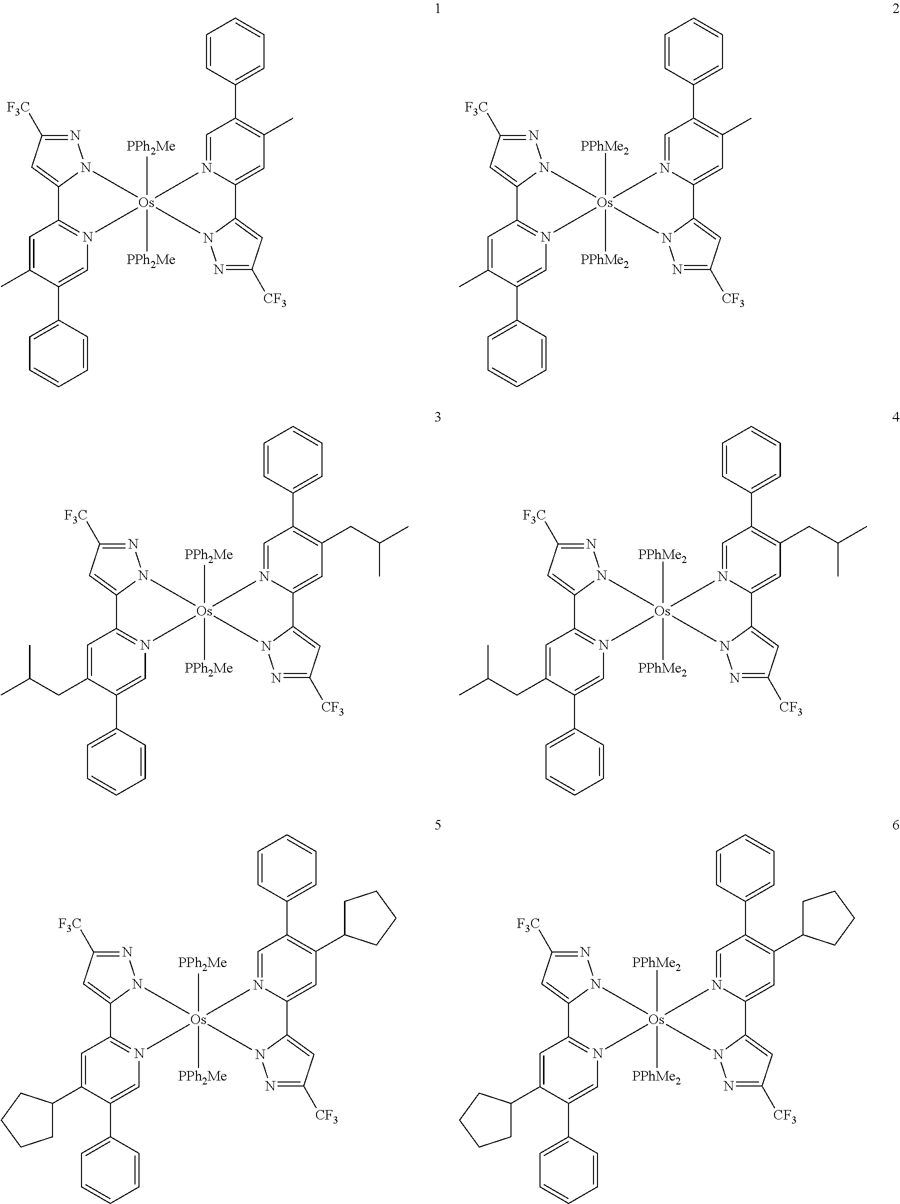

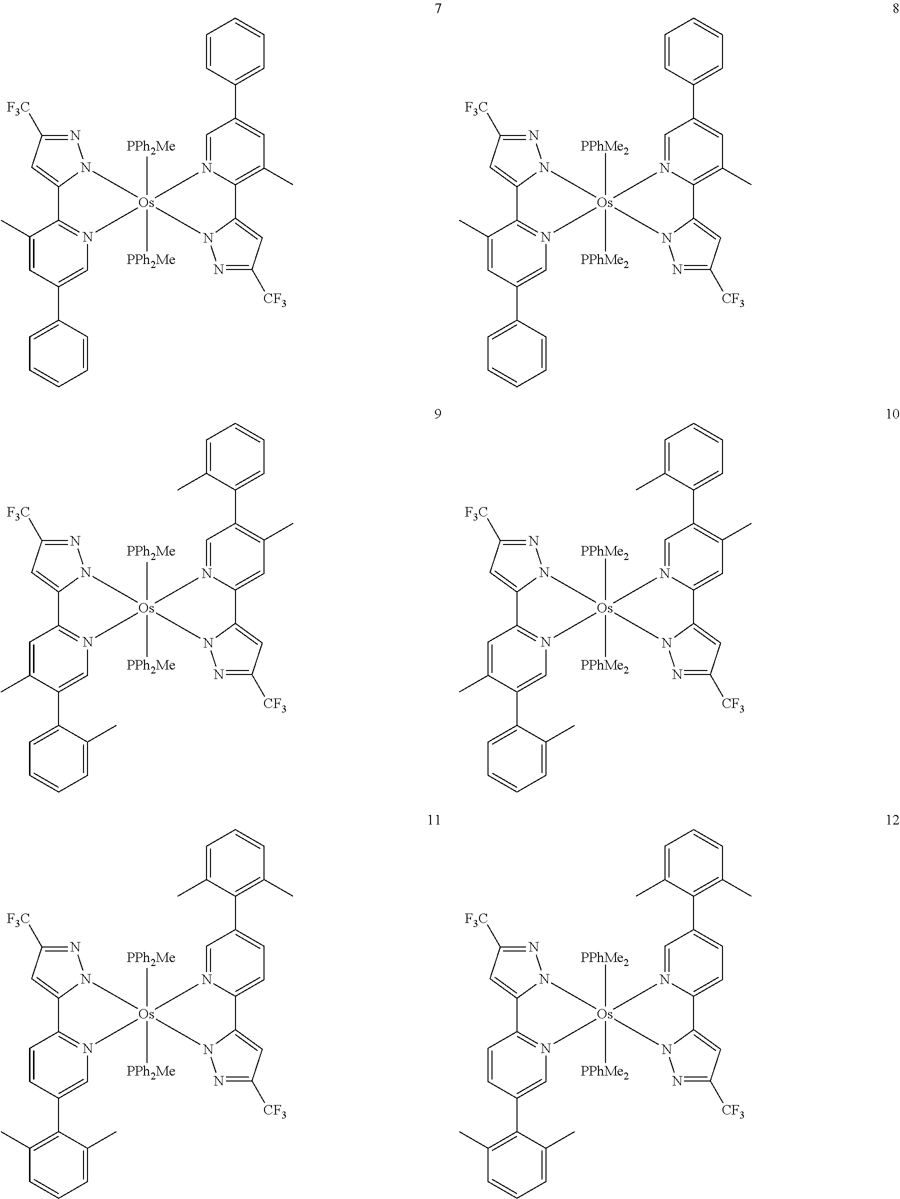

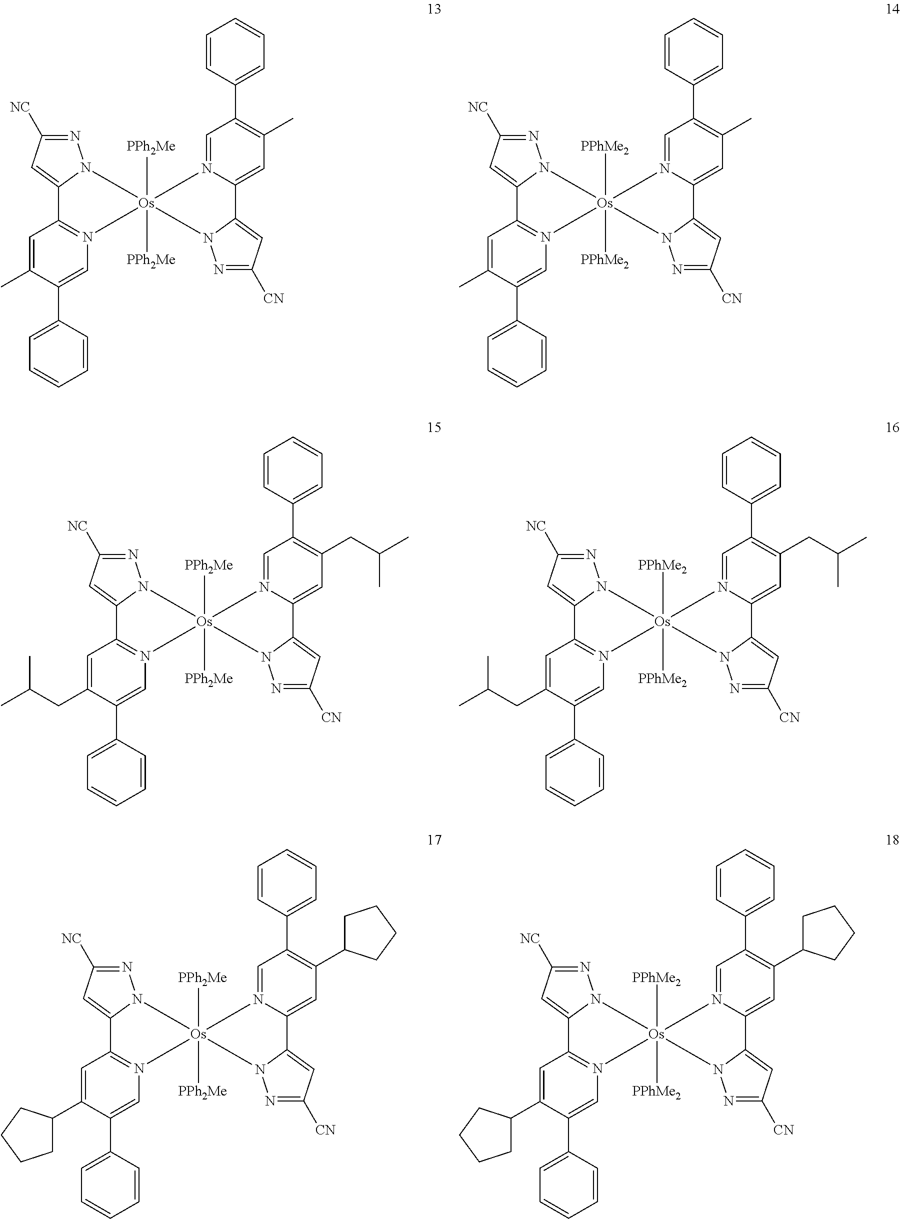

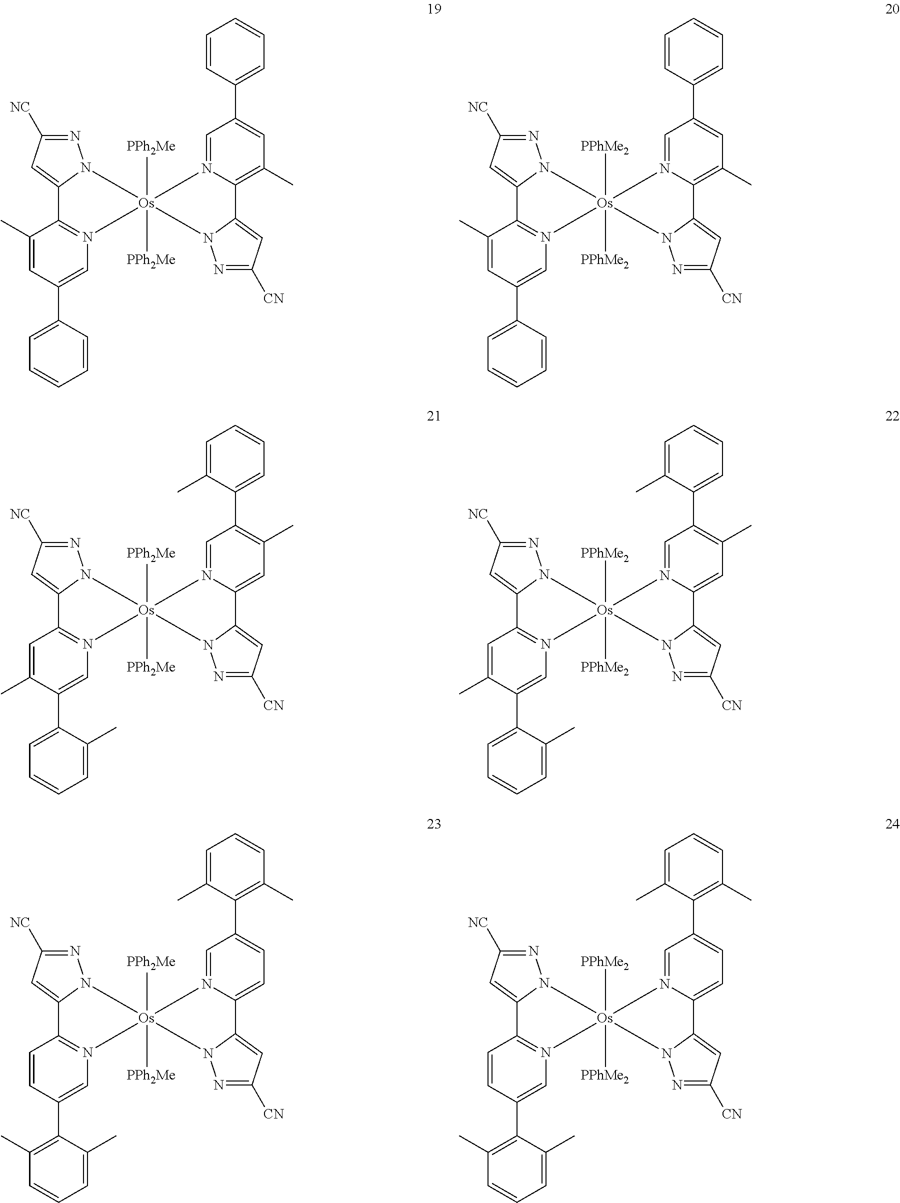

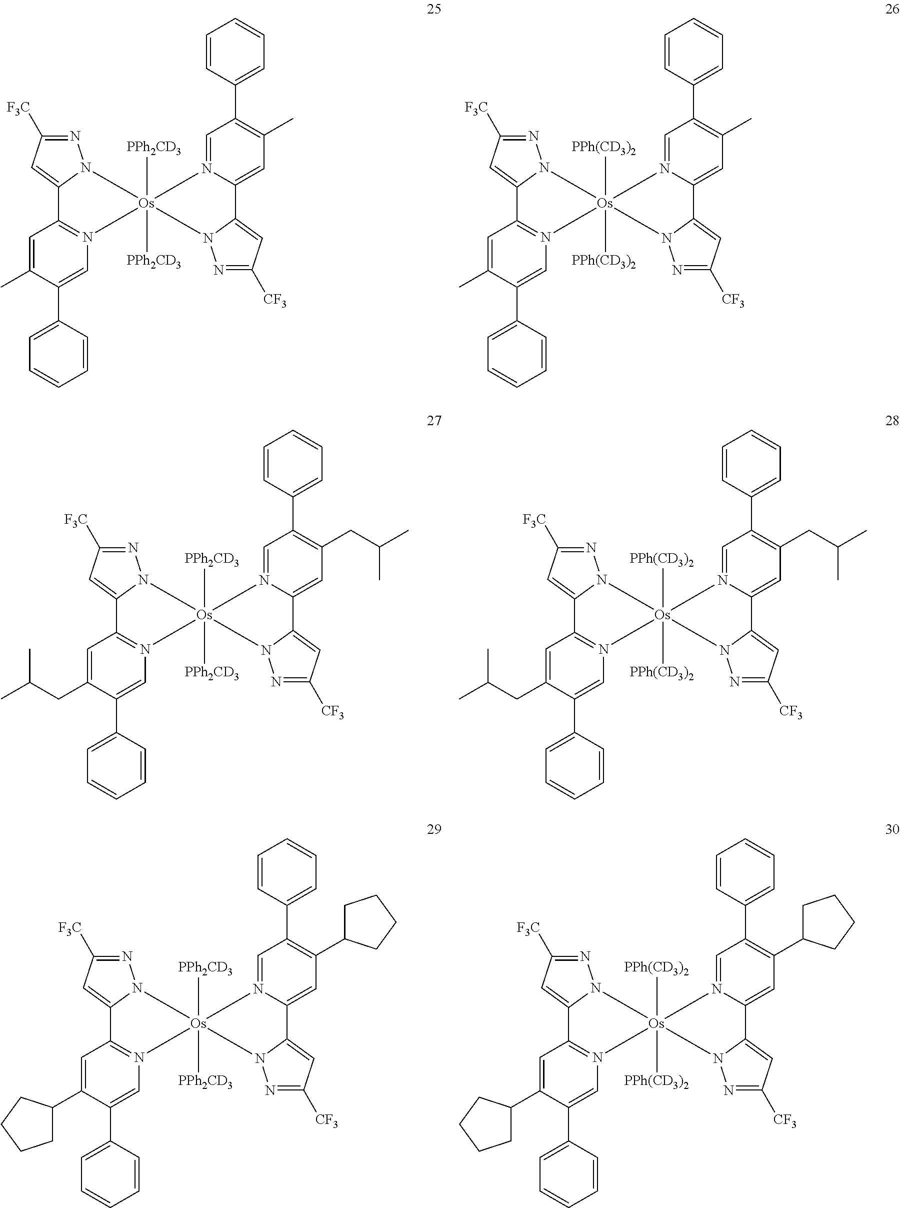

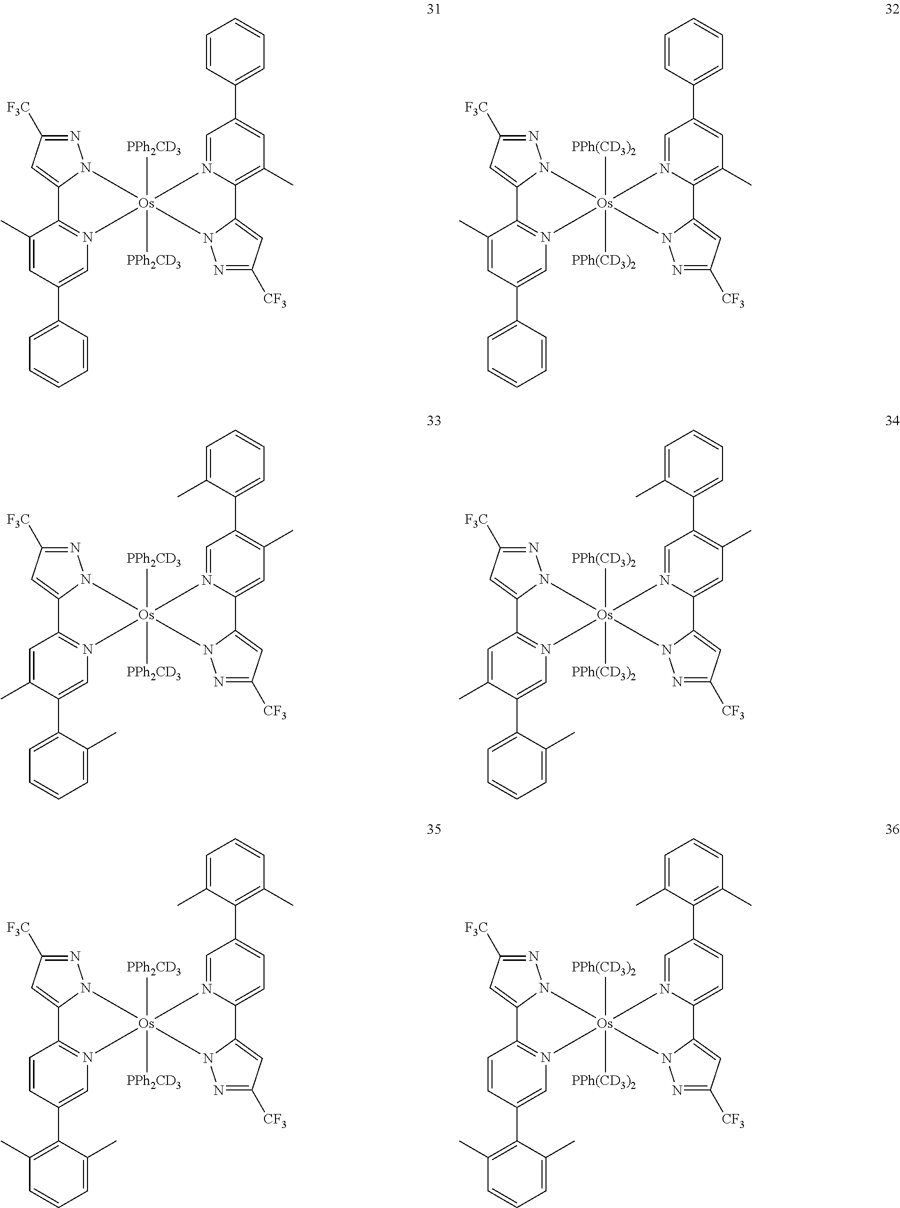

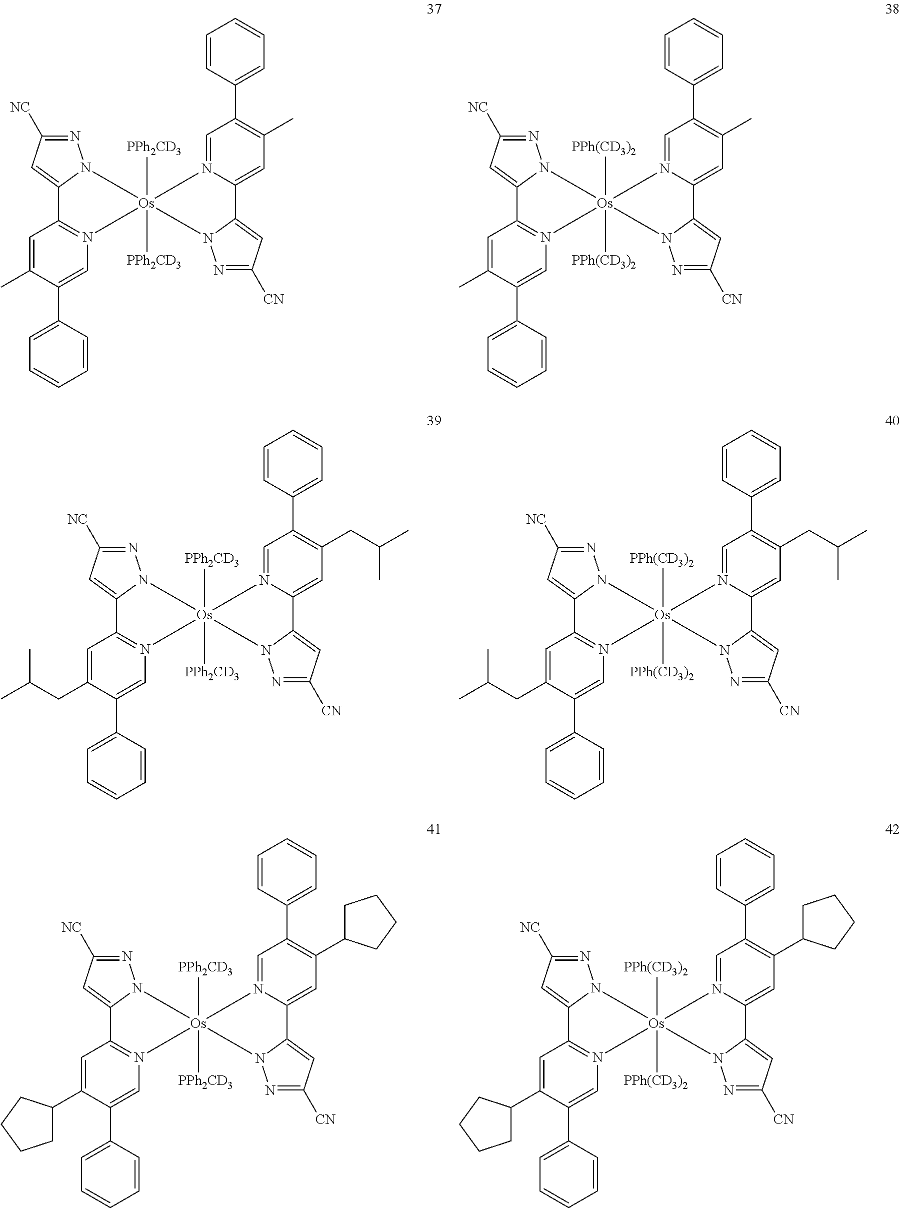

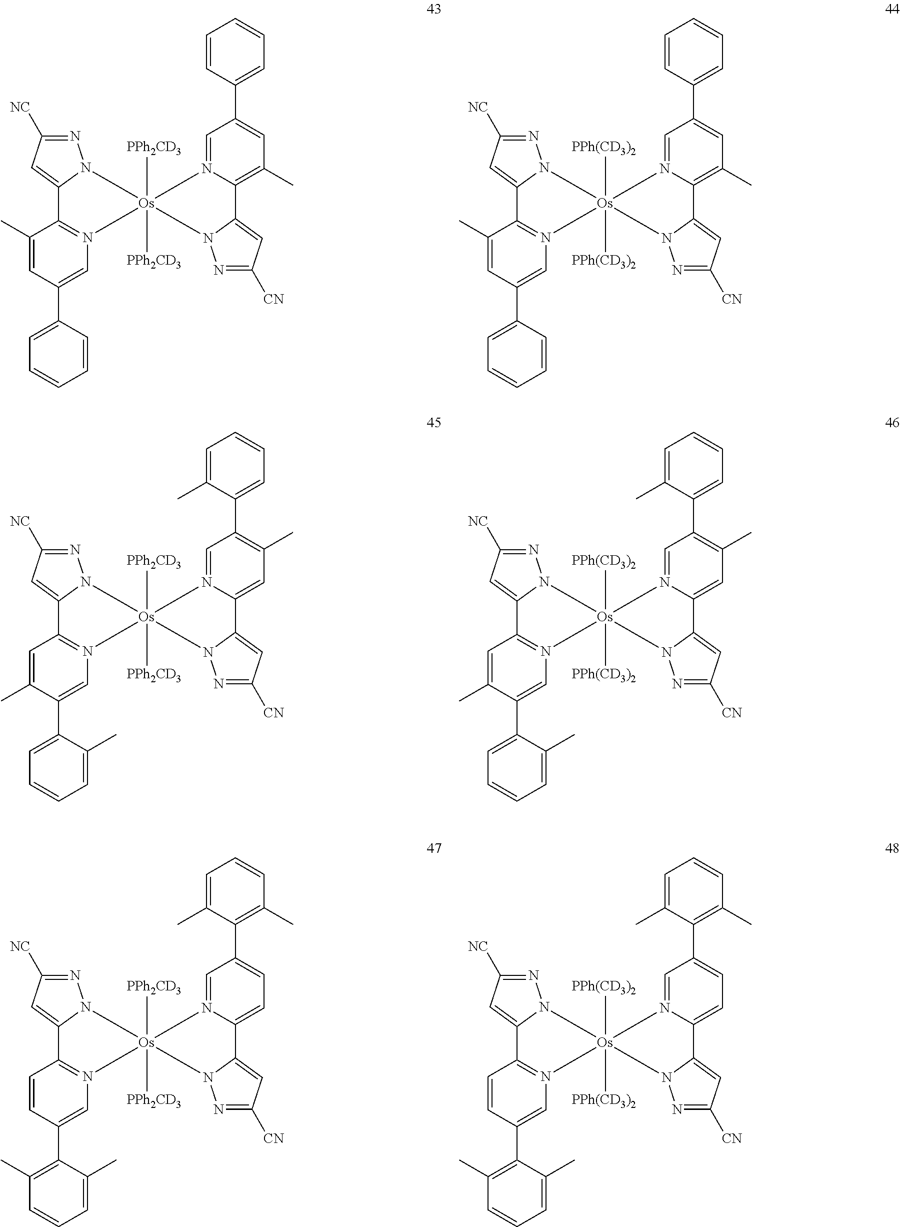

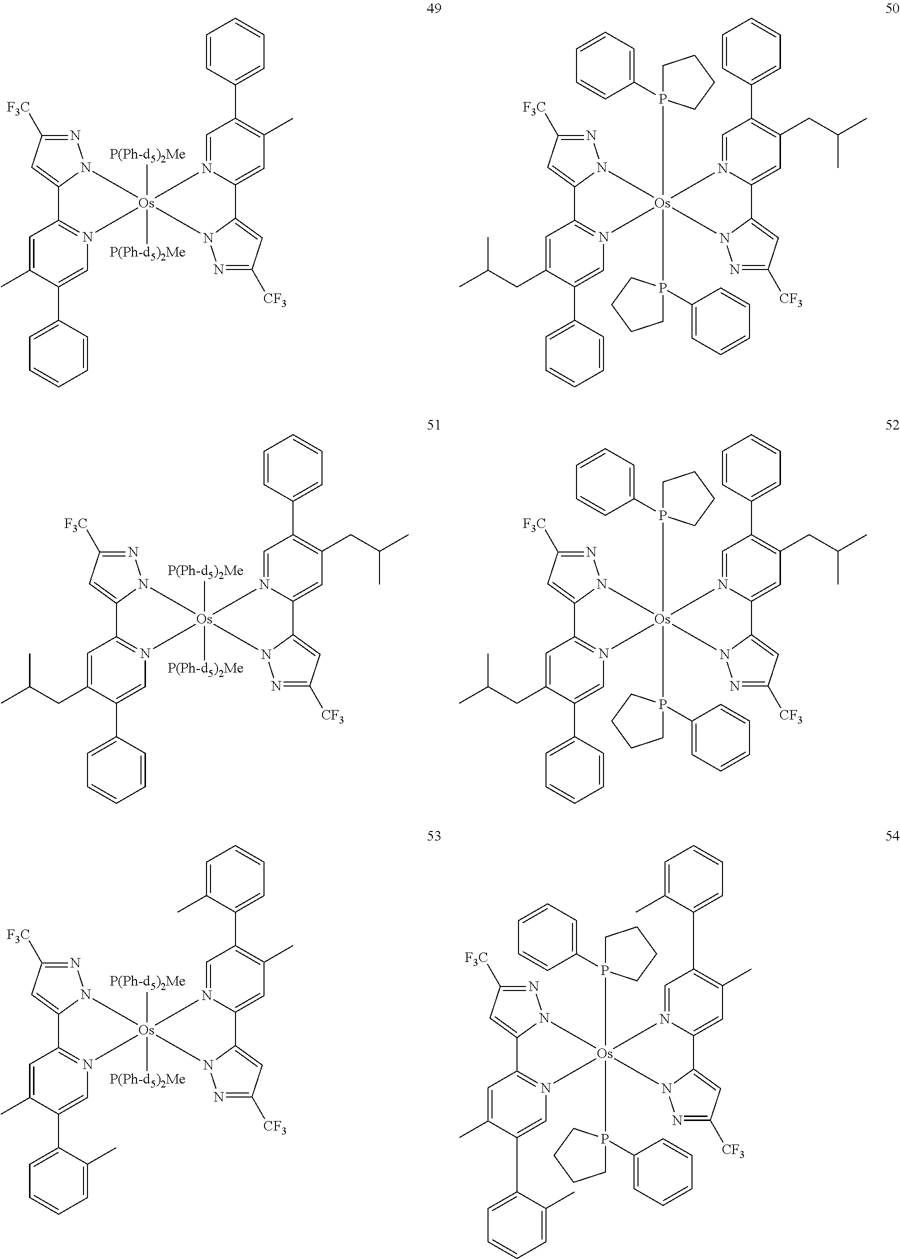

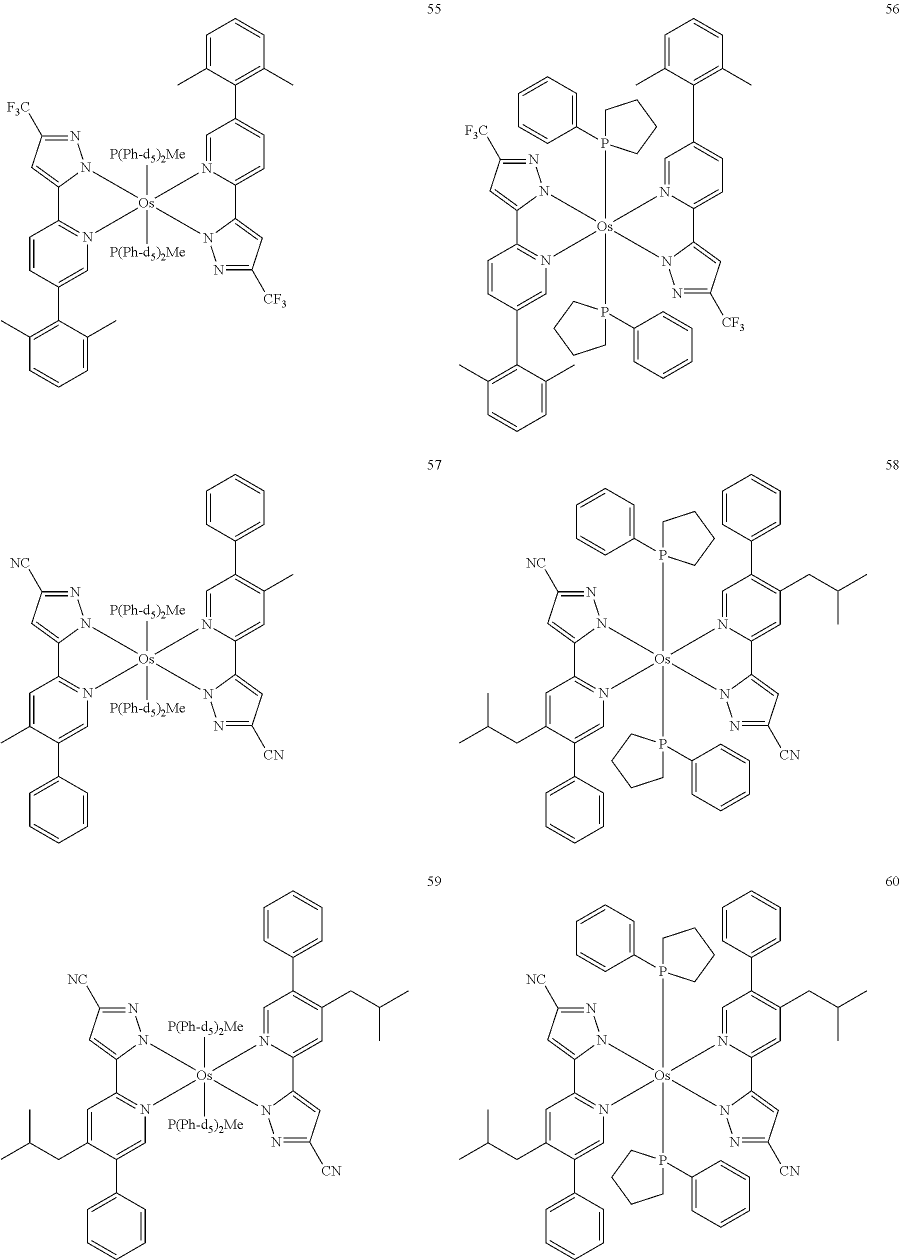

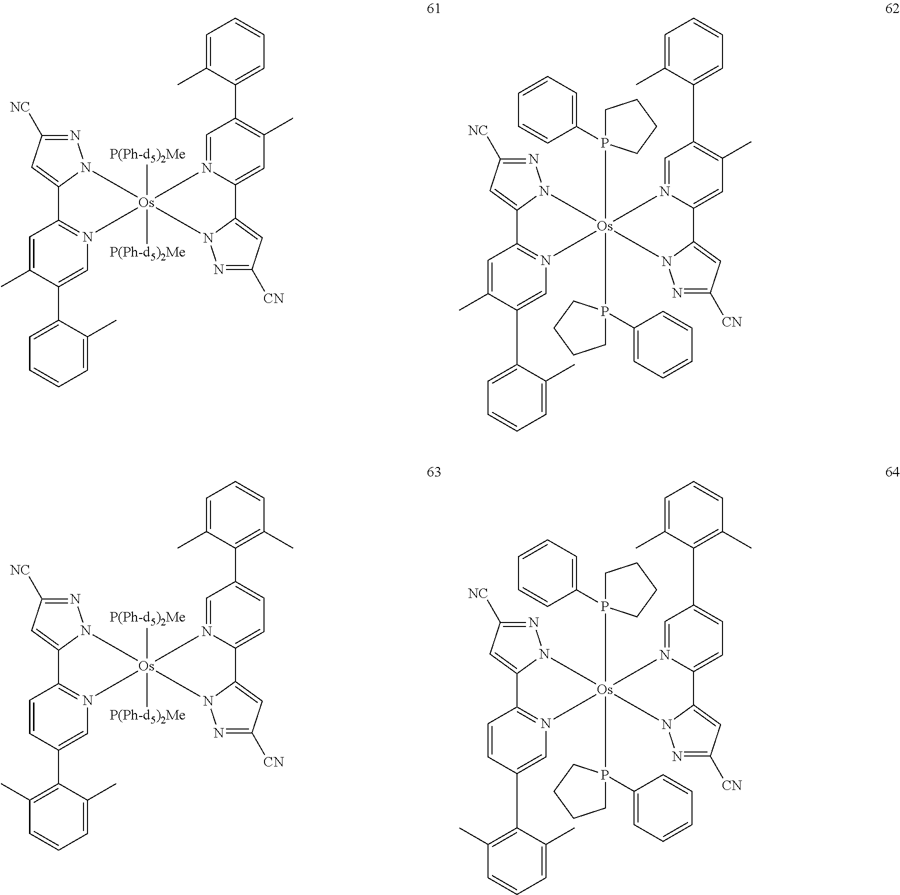

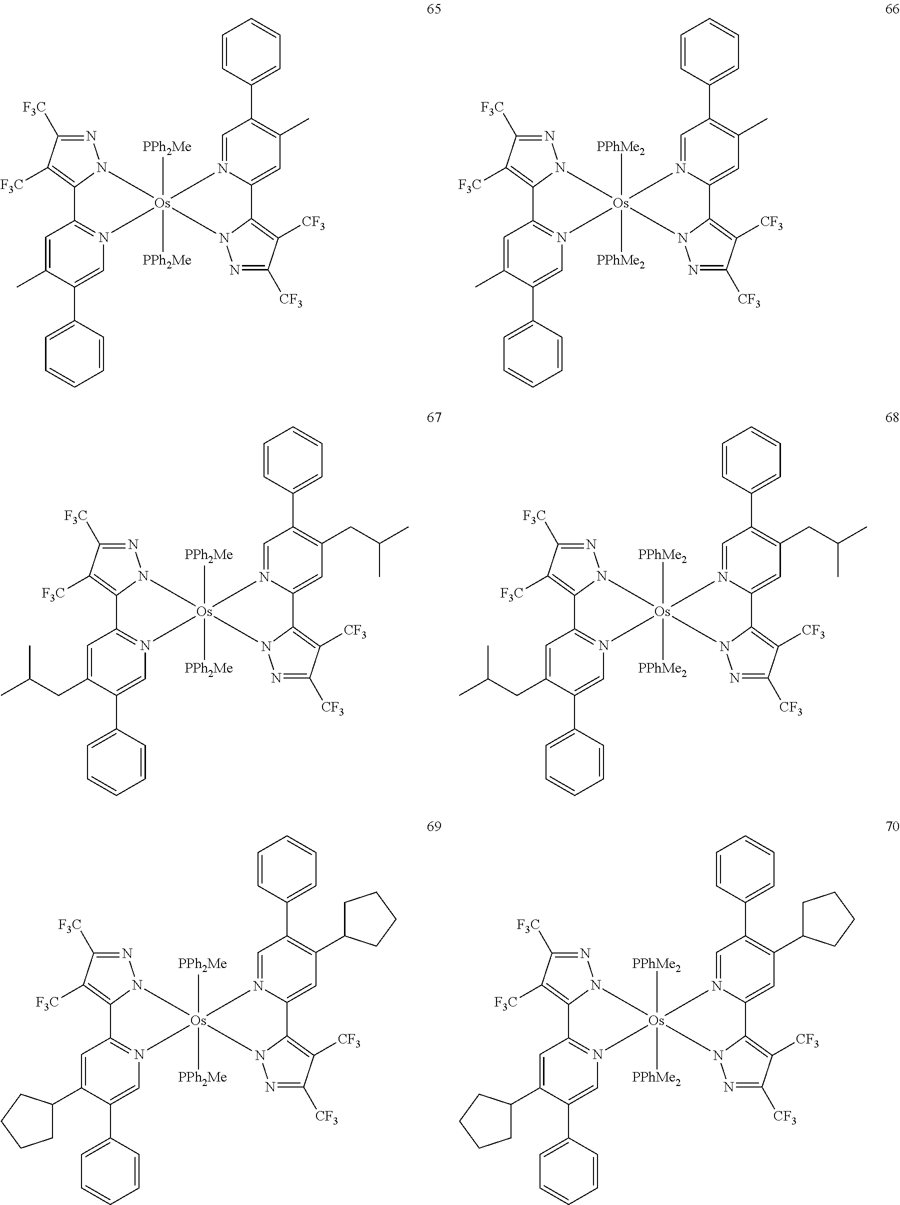

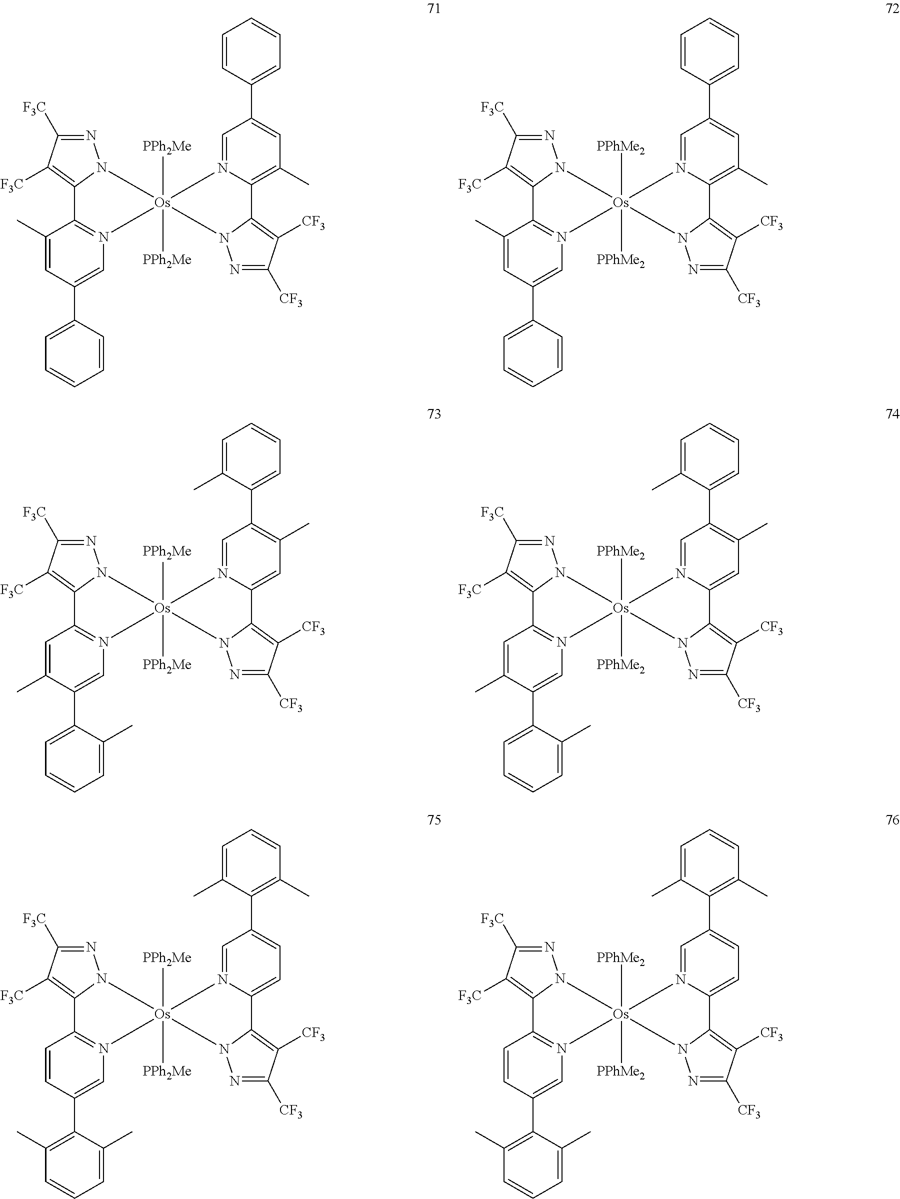

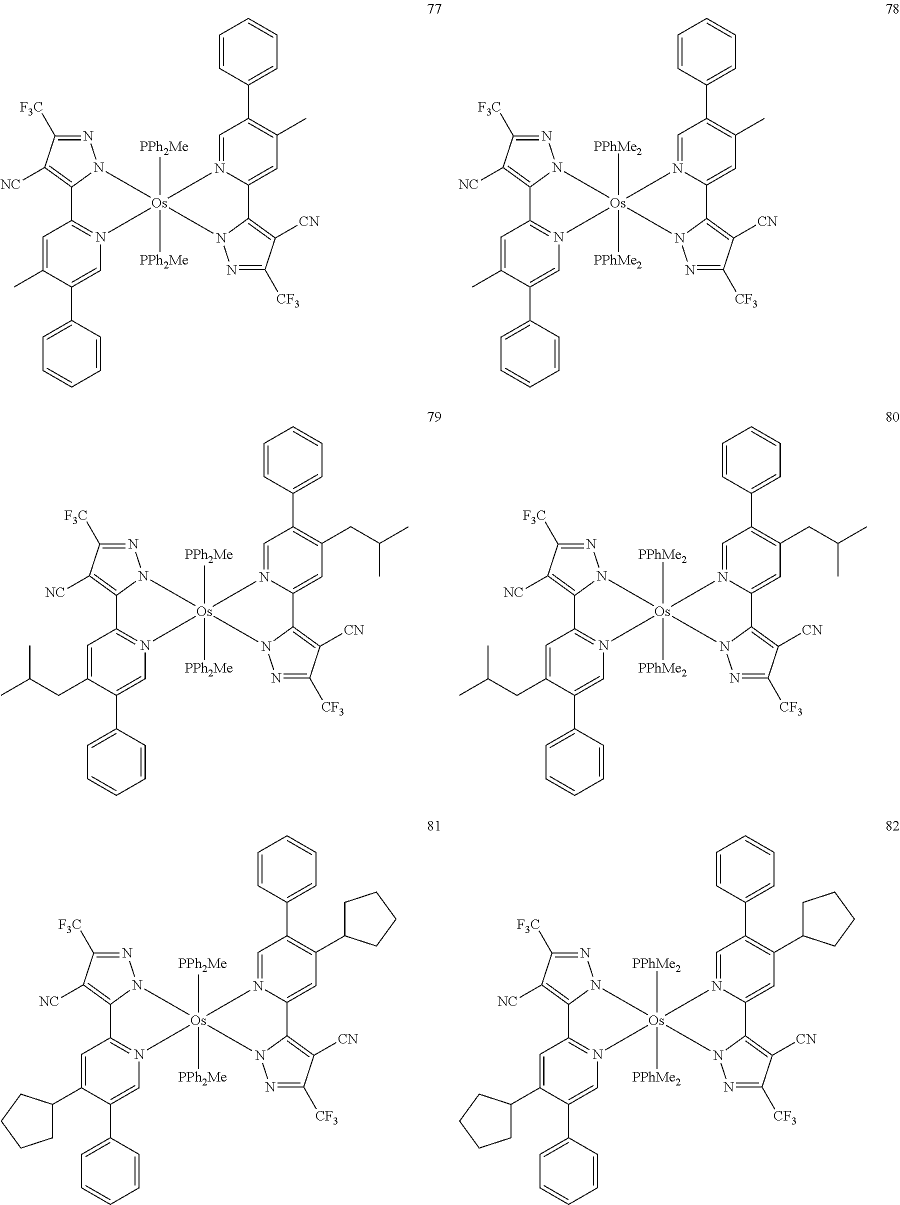

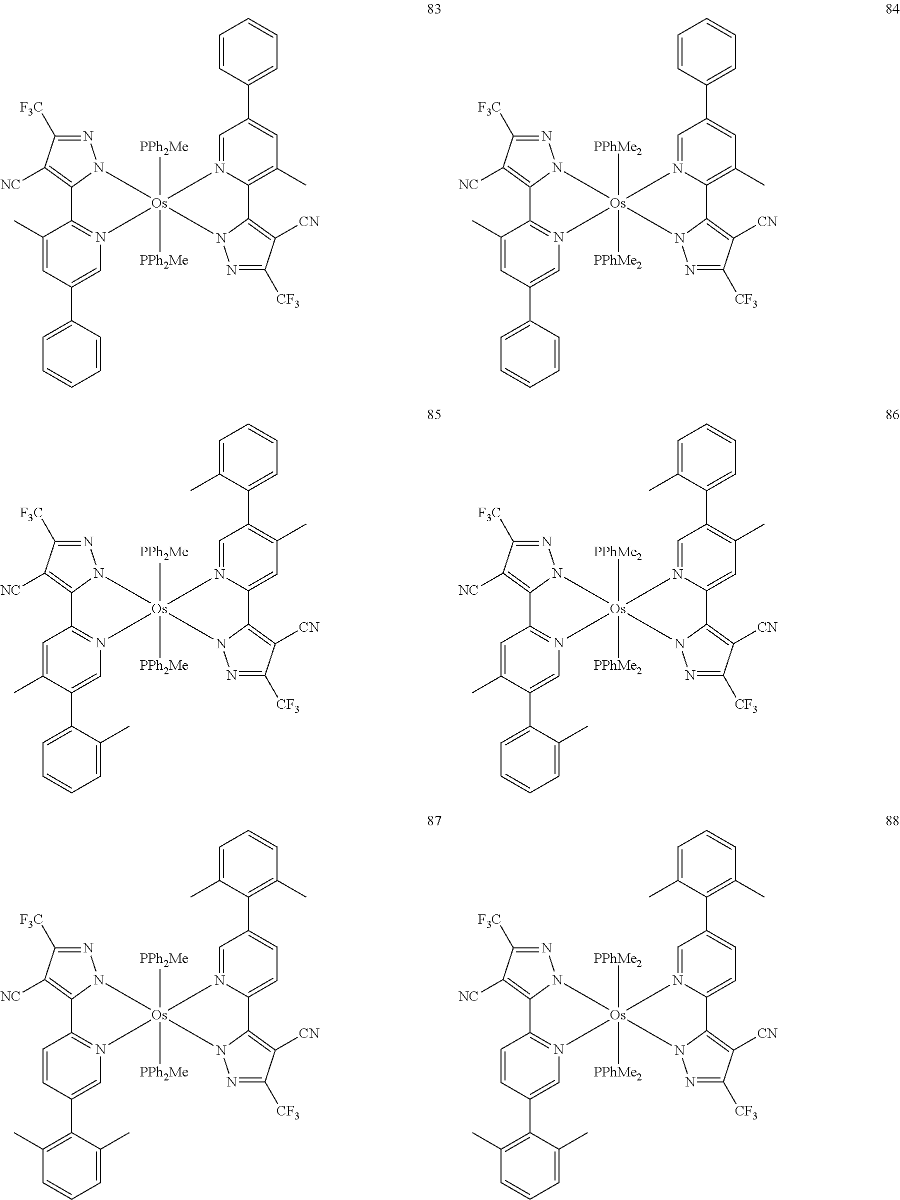

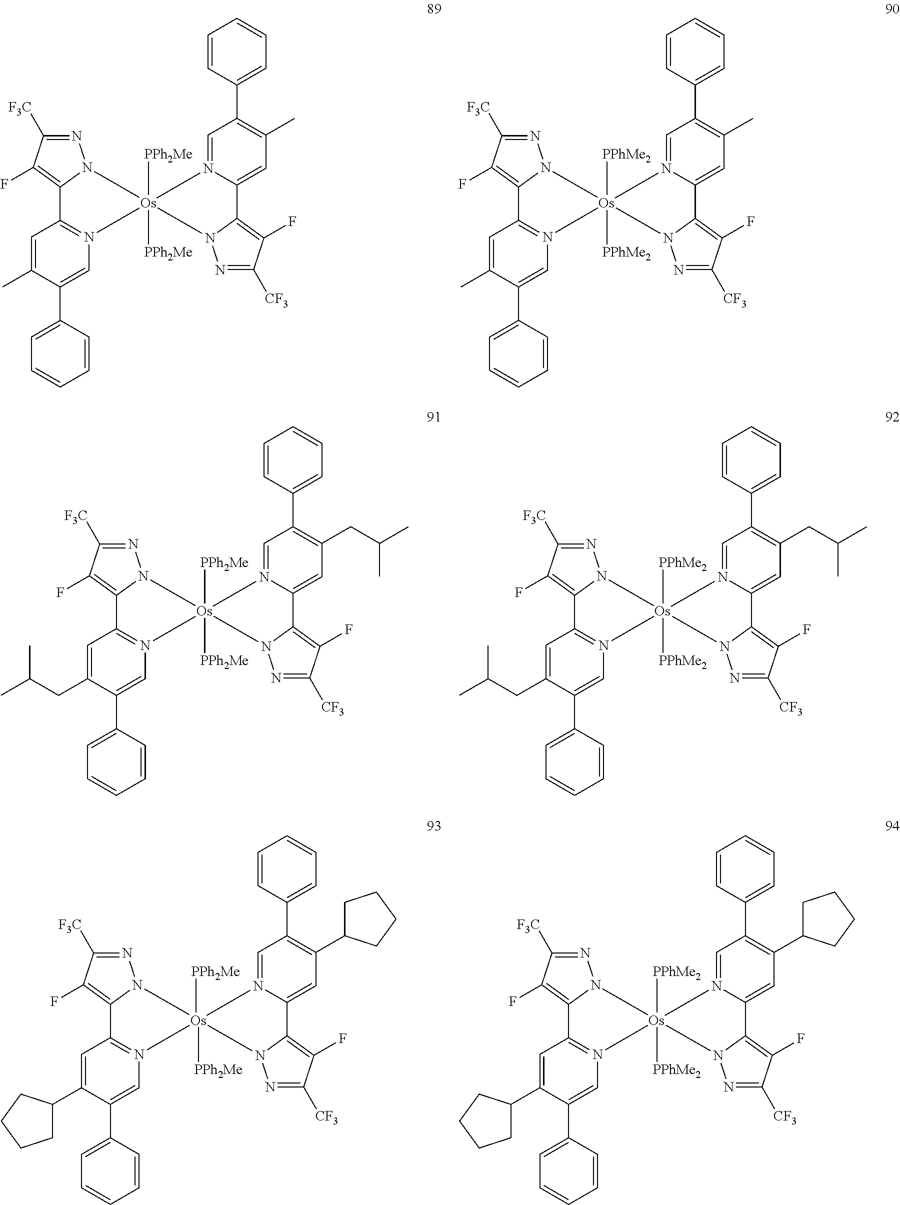

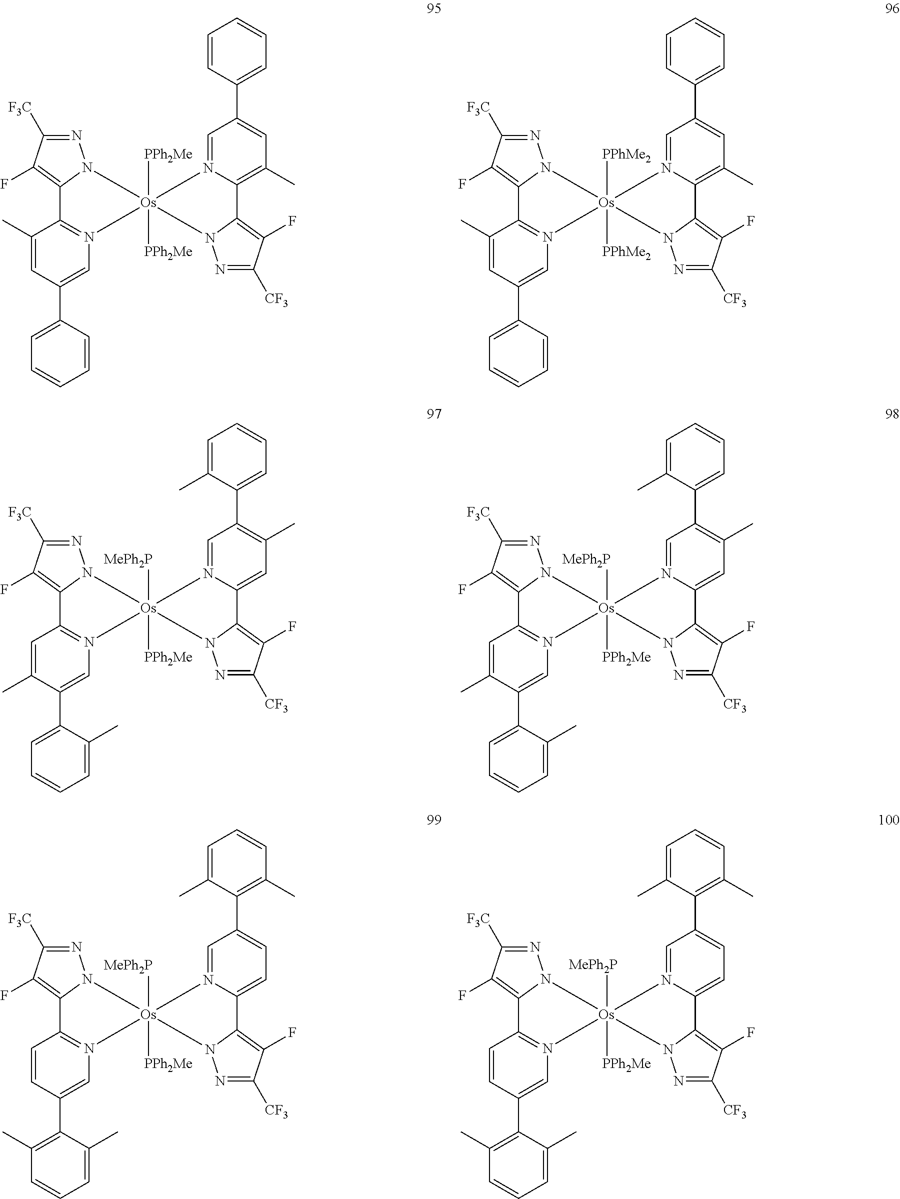

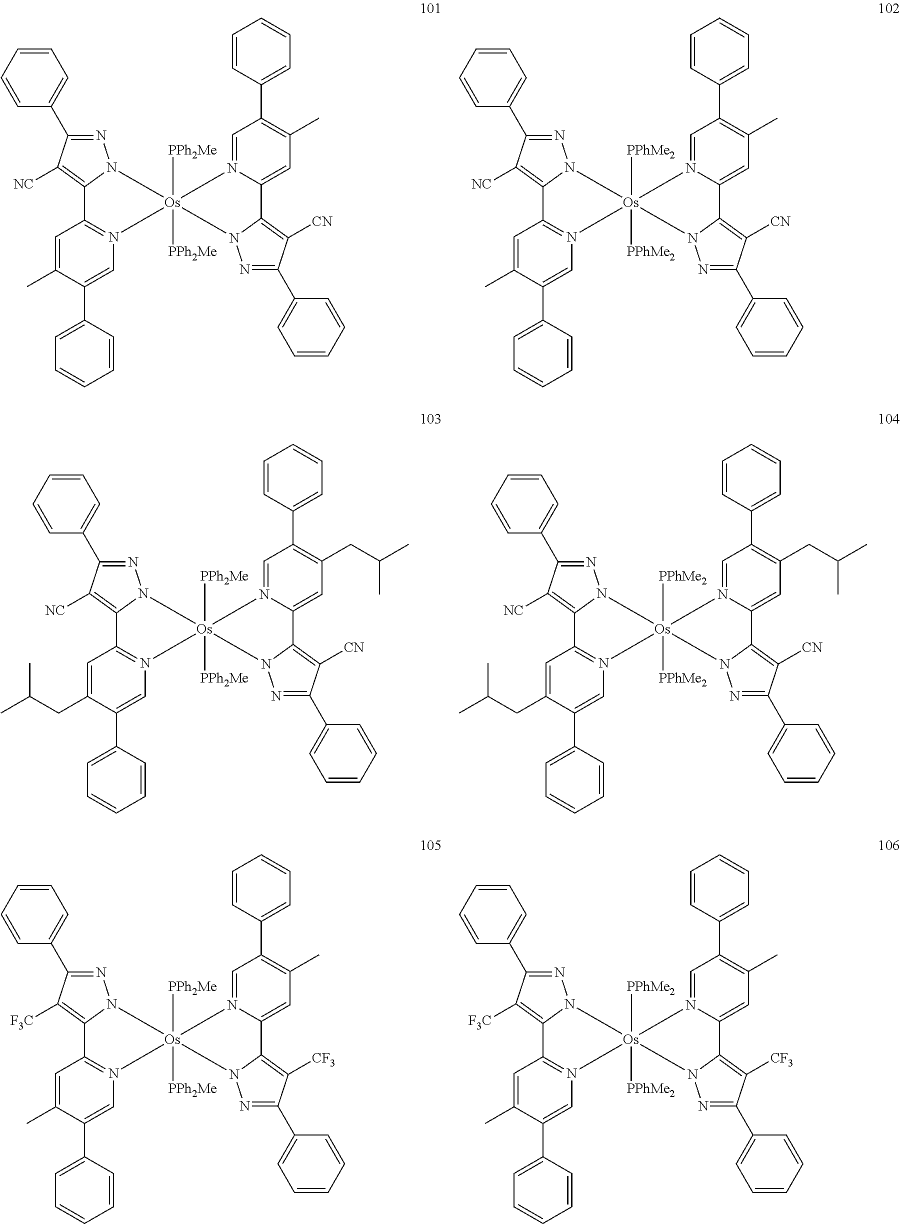

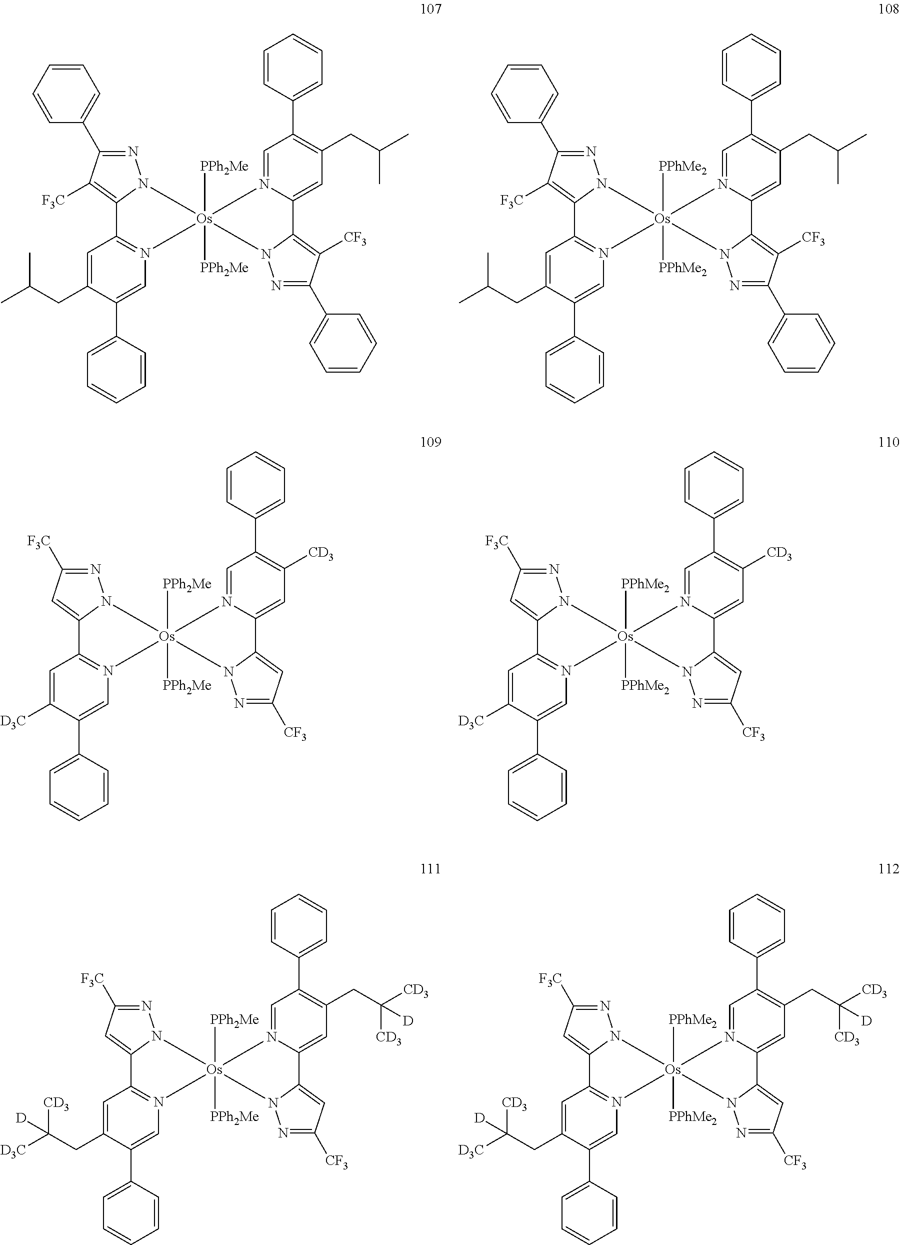

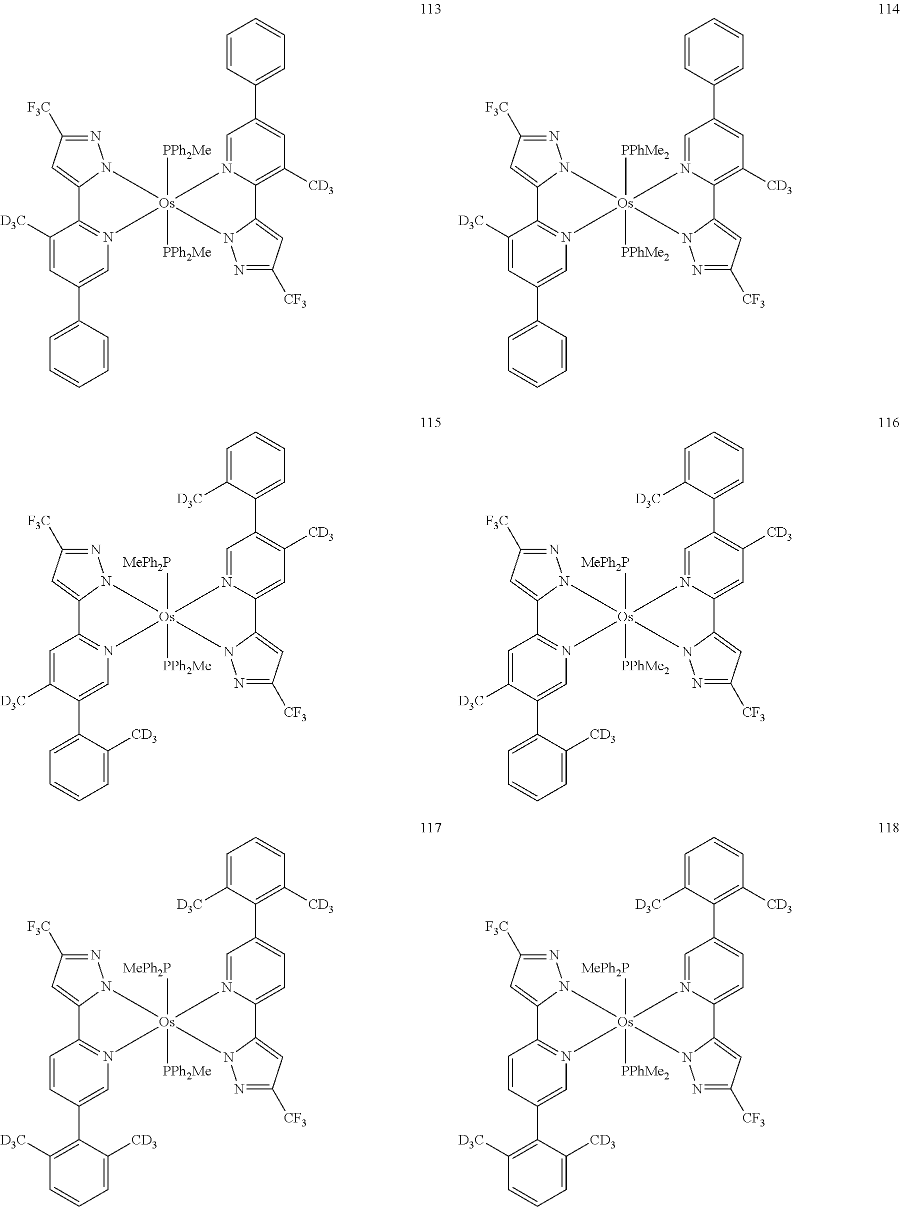

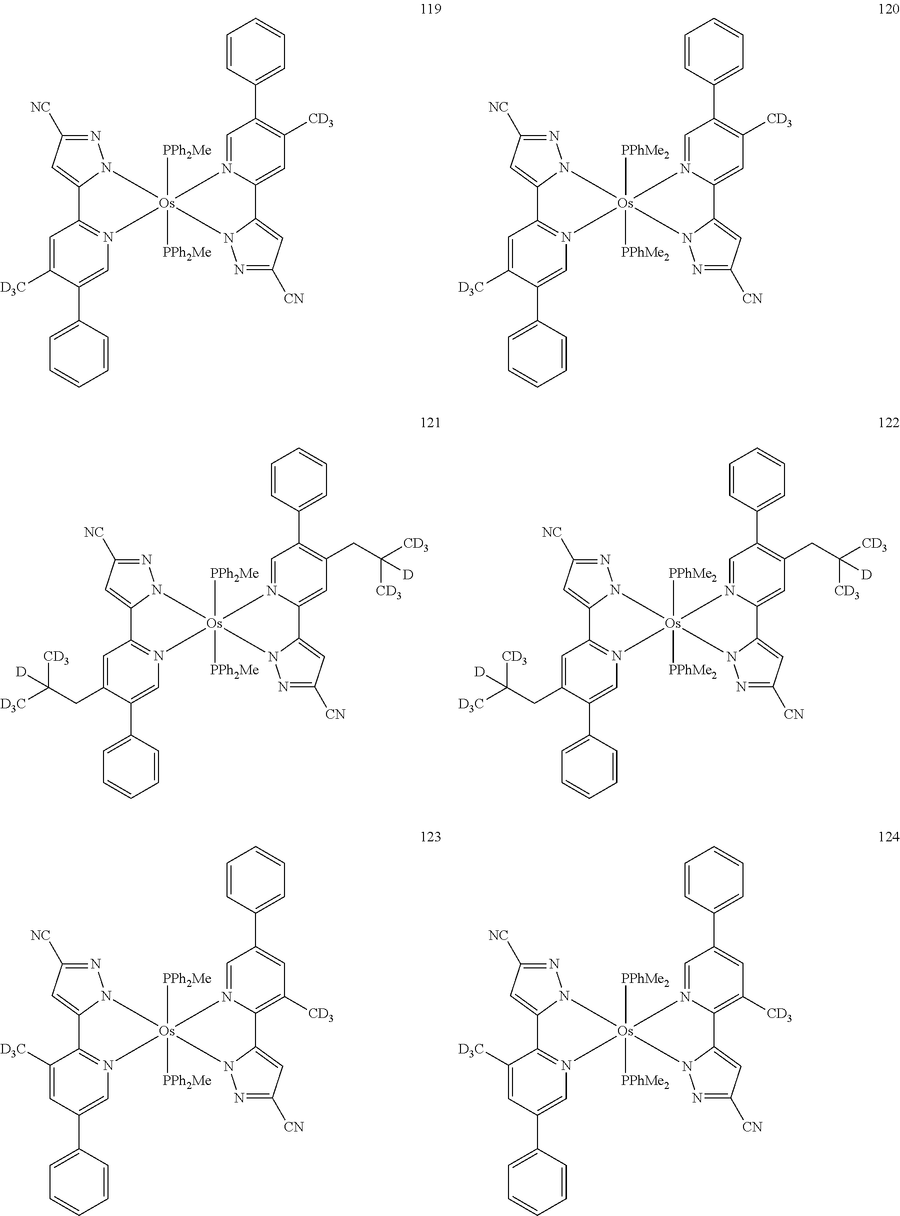

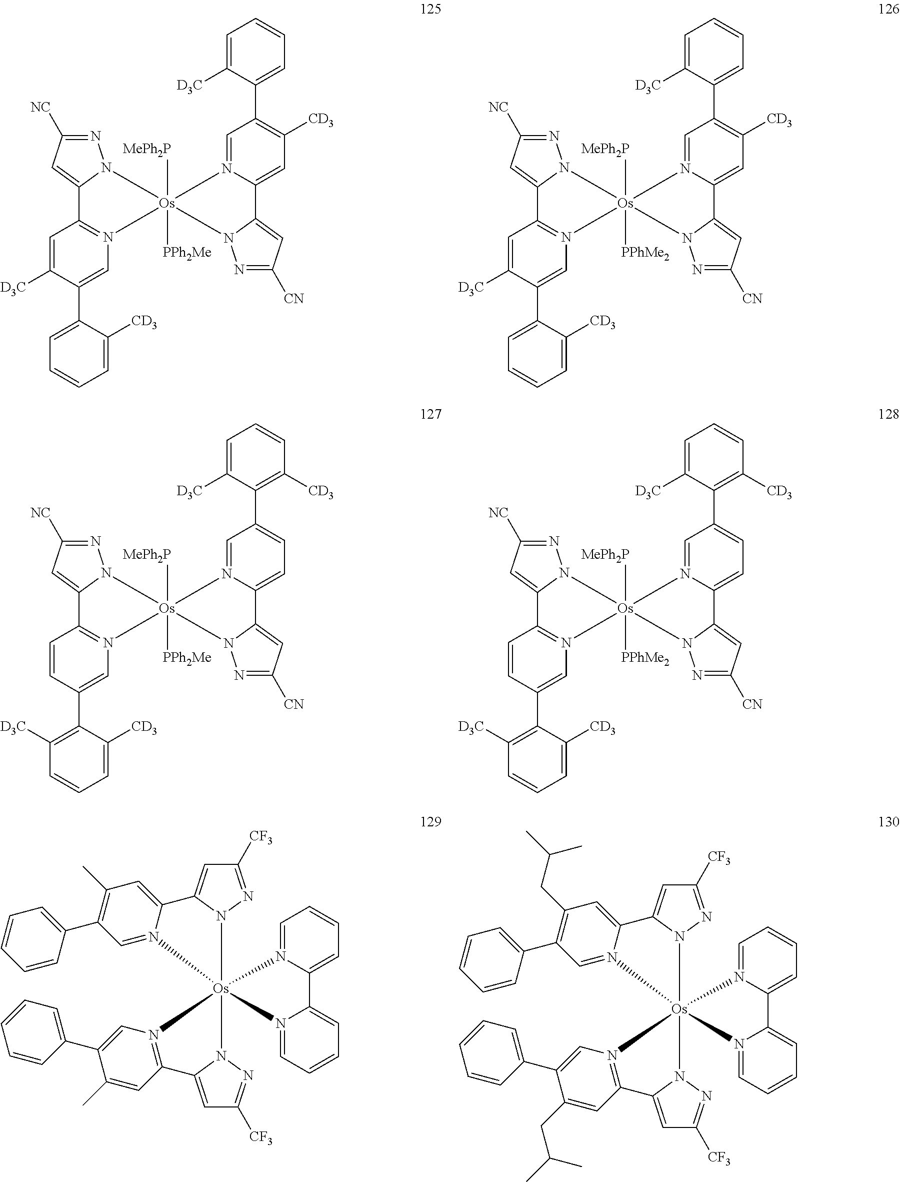

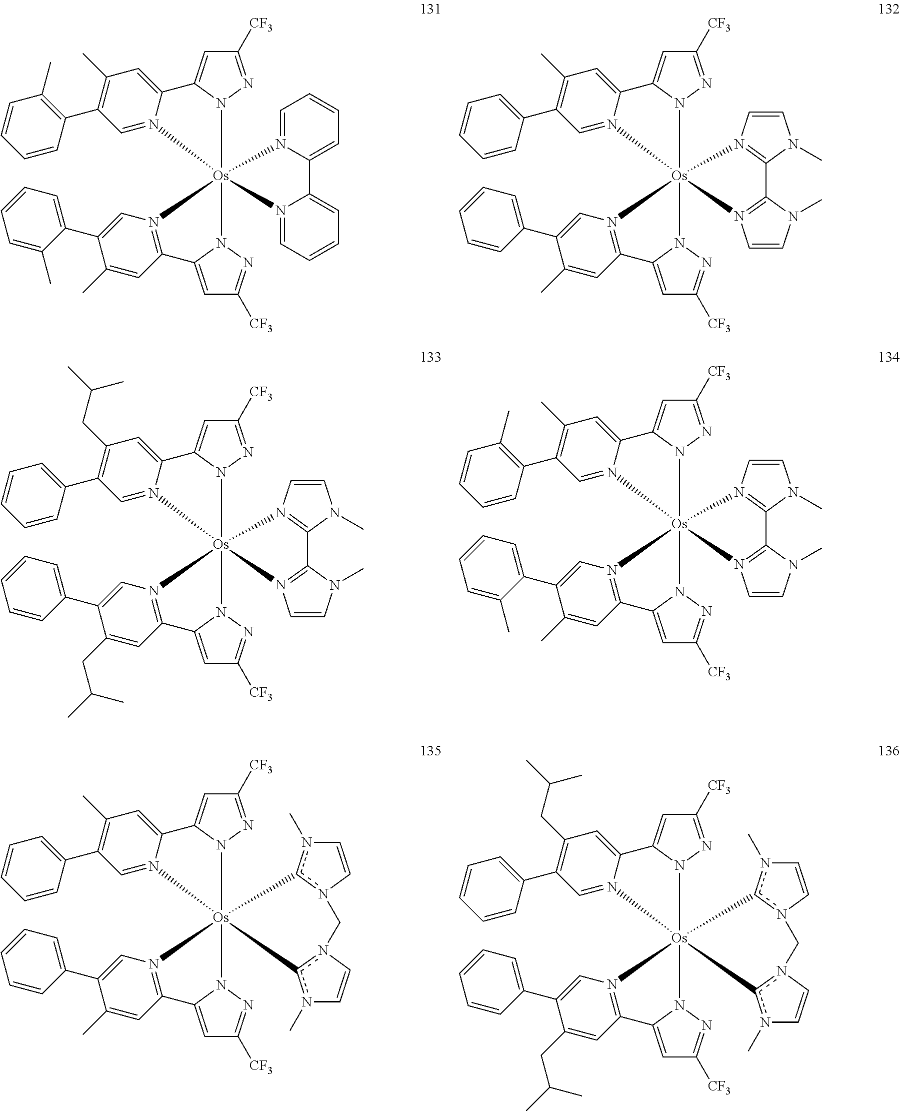

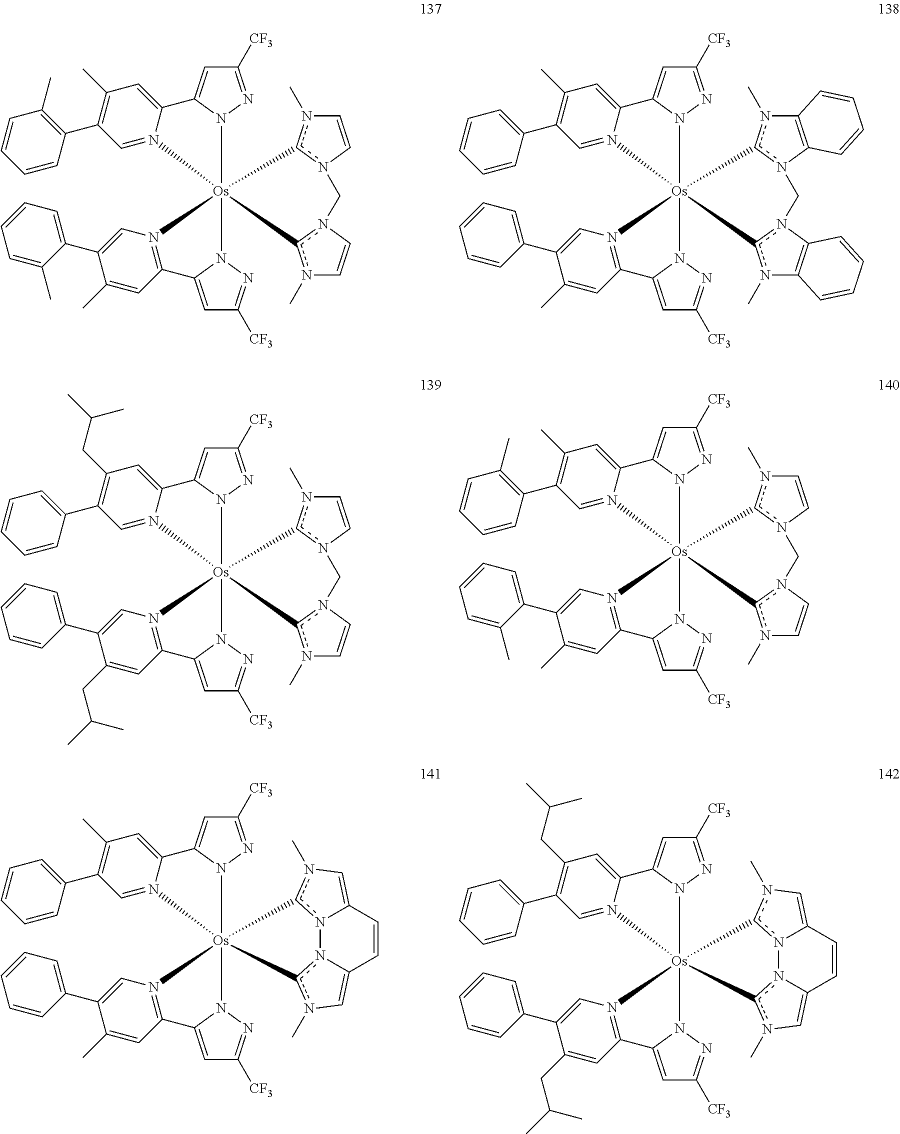

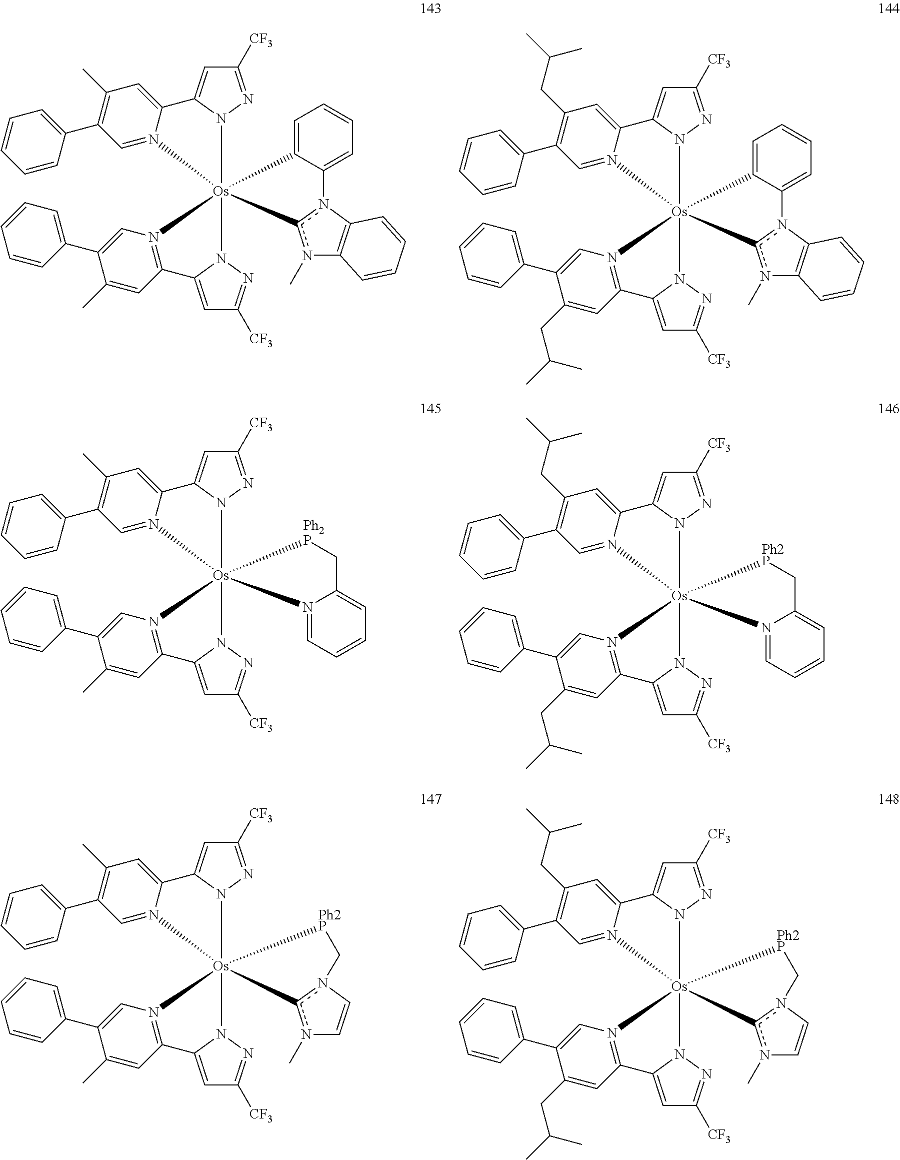

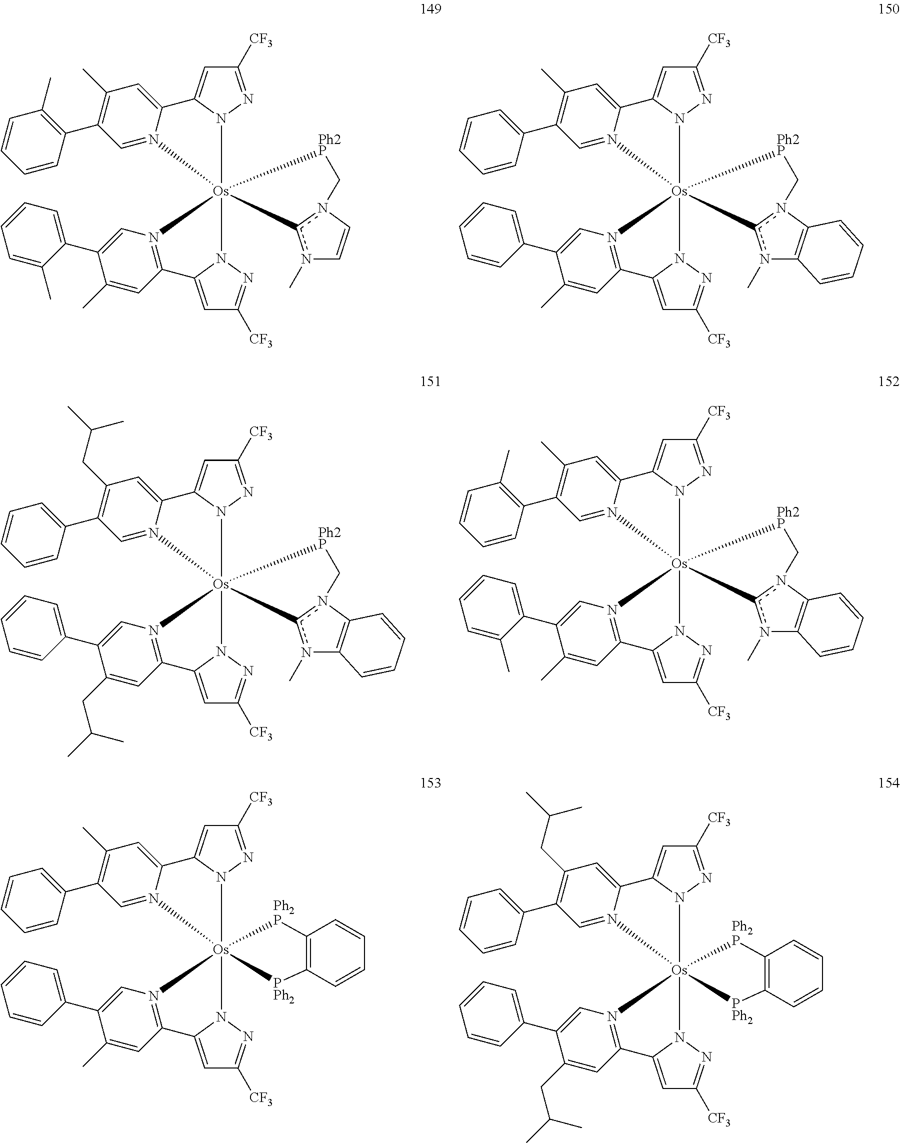

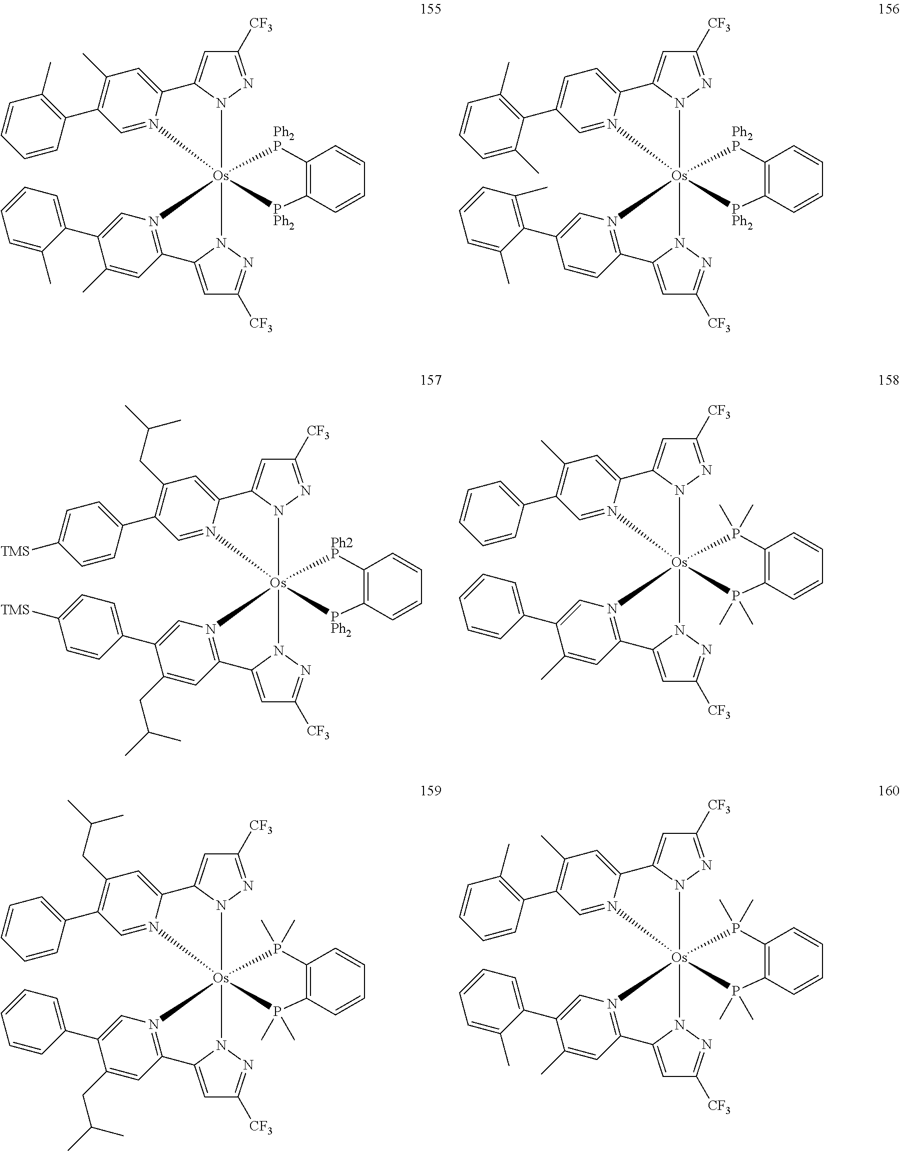

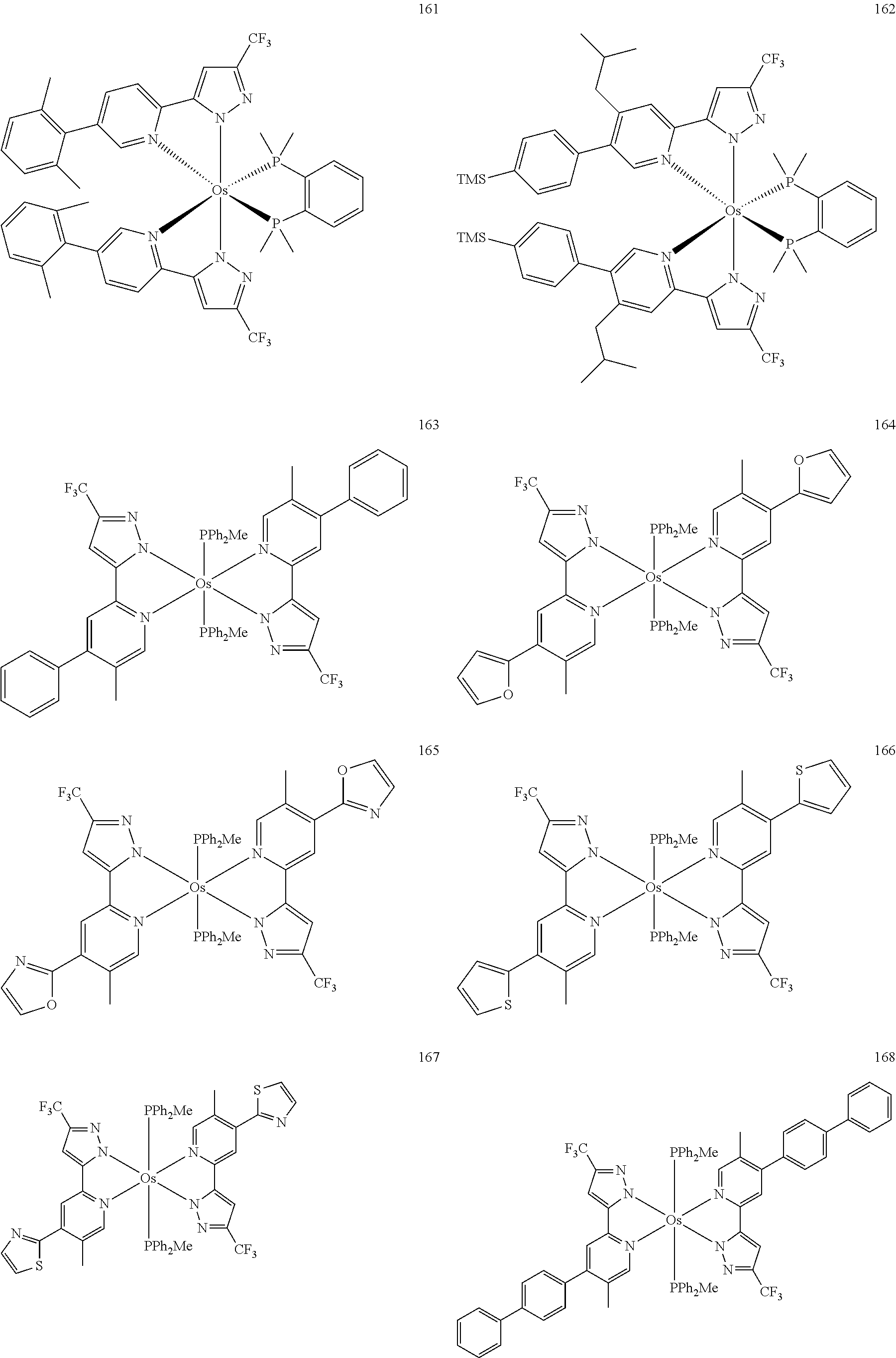

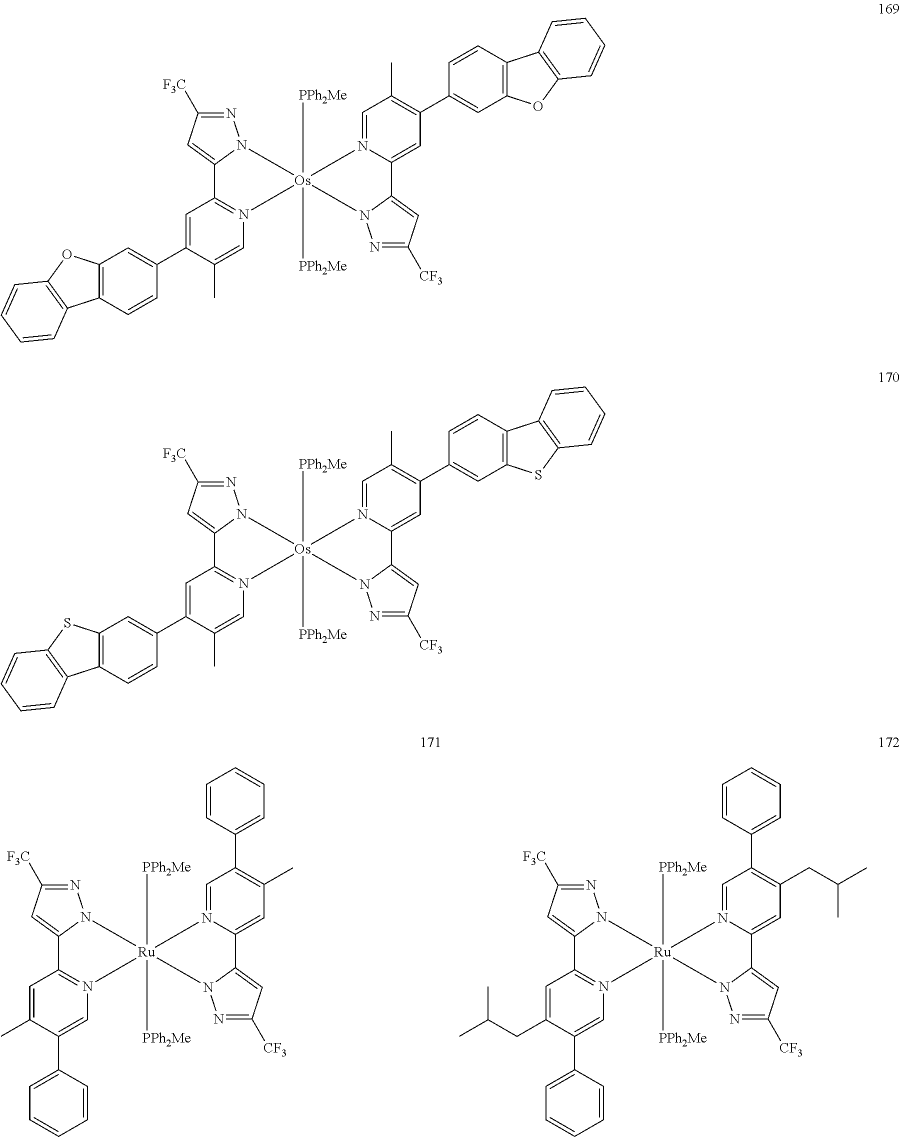

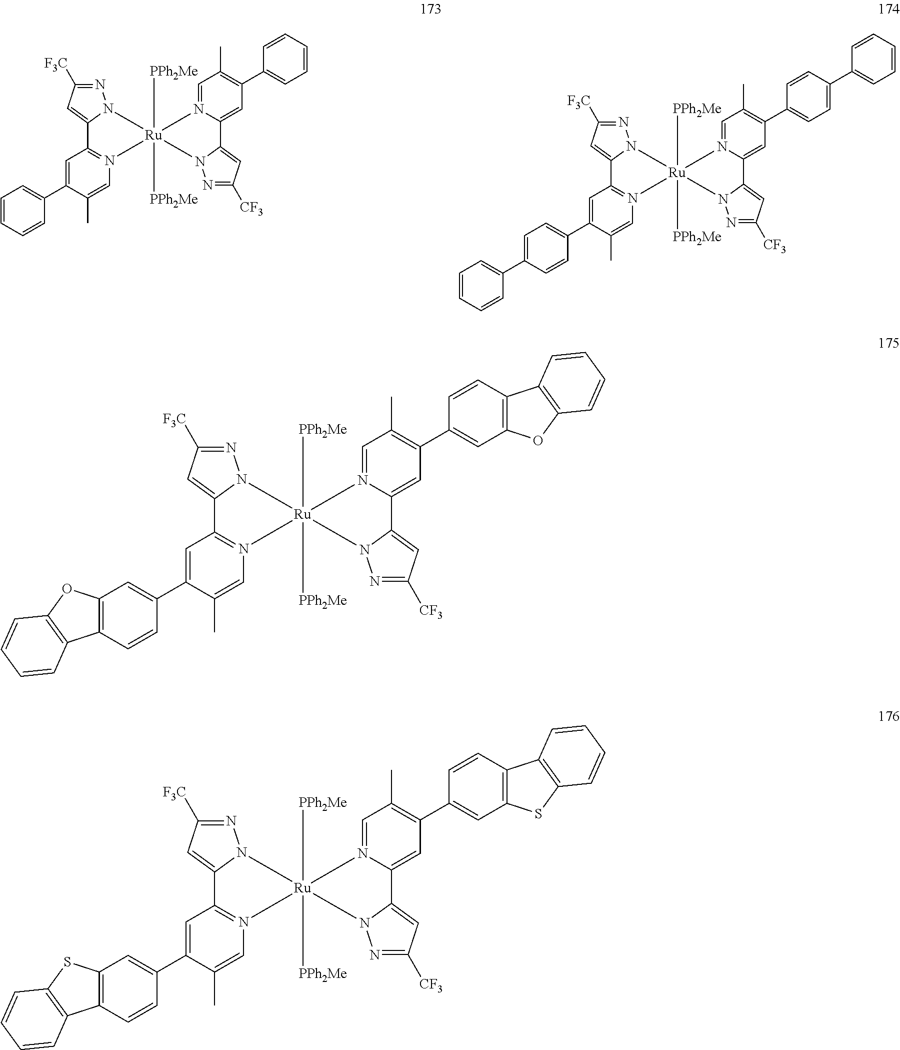

Since the organometallic compound represented by Formula 1 includes a pyridine ring substituted with an aryl group or the like, the pyridine ring may have improved electrical, chemical, and/or physical stability. In addition, since the organometallic compound represented by Formula 1 includes an aryl group or the like, hole mobility is improved. Thus, an organic light-emitting device including the organometallic compound represented by Formula 1 may have improved lifespan and efficiency.

Since the organometallic compound represented by Formula 1 includes a pyridine ring substituted with an aryl group or the like, the organometallic compound represented by Formula 1 may have low planarity. Accordingly, the aggregation of the organometallic compound represented by Formula 1 may decrease, thus improving the efficiency of an organic light-emitting device including the organometallic compound.

Since the organometallic compound represented by Formula 1 includes Os or Ru, the organometallic compound may have an octahedral structure. Compounds having such an octahedral structure may have a short decay time, as compared with compounds having a square planer structure (e.g., an organometallic compound including platinum (Pt)). In addition, the organometallic compound represented by Formula 1 may be less likely to cause exciton quenching and decrease triplet-triplet annihilation, and thus, an organic light-emitting device including the organometallic compound may have improved efficiency and low roll-off.

For example, the highest occupied molecular orbital (HOMO), lowest unoccupied molecular orbital (LUMO), and T₁ energy levels of Compounds 1, 3, 9, and 7 and Compound B were simulated by using the Gaussian. The simulation evaluation results are shown in Table 1:

TABLE 1

| Compound No. | HOMO (eV) | LUMO (eV) | T₁ (eV) |
|---|---|---|---|
| 1 | −4.548 | −1.367 | 2.309 |
| 3 | −4.569 | −1.348 | 2.330 |
| 9 | −4.571 | −1.316 | 2.355 |
| 7 | −4.580 | −1.509 | 2.210 |
| B | −4.522 | −1.317 | 2.304 |

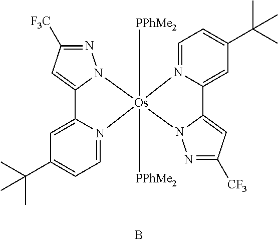

Synthesis methods of the organometallic compound represented by Formula 1 may be recognizable by one of ordinary skill in the art by referring to Synthesis Examples provided below.

The organometallic compound represented by Formula 1 is suitable for use in an organic layer of an organic light-emitting device, for example, for use as a dopant in an emission layer of the organic layer. Thus, another aspect provides an organic light-emitting device that includes:

a first electrode;

a second electrode; and

an organic layer that is disposed between the first electrode and the second electrode,

wherein the organic layer includes an organic layer including an emission layer and at least one organometallic compound represented by Formula 1.

The organometallic compound of Formula 1 may be used between a pair of electrodes of an organic light-emitting device. For example, the organometallic compound represented by Formula 1 may be included in the emission layer. In this regard, the organometallic compound may act as a dopant, and the emission layer may further include a host (that is, the amount of the organometallic compound represented by Formula 1 may be less than the amount of the host).

The expression that “(an organic layer) includes at least one of organometallic compounds” as used herein refers to an embodiment in which “(an organic layer) includes identical organometallic compounds represented by Formula 1 and to an embodiment in which (an organic layer) includes two or more different organometallic compounds represented by Formula 1”.

In some embodiments, the organic layer may include, as the organometallic compound, only Compound 1. In this regard, Compound 1 may be included in an emission layer of the organic light-emitting device. In one or more embodiments, the organic layer may include, as the organometallic compound, Compound 1 and Compound 2. In this regard, Compound 1 and Compound 2 may be included in an identical layer (for example, Compound 1 and Compound 2 both may be in an emission layer).

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

For example, the first electrode may be an anode, and the second electrode may be a cathode, and the organic layer may include: i) a hole transport region that is disposed between the first electrode and the emission layer, wherein the hole transport region may include at least one selected from a hole injection layer, a hole transport layer, and an electron blocking layer, and ii) an electron transport region that is disposed between the emission layer and the second electrode, wherein the electron transport region may include at least one selected from a hole blocking layer, an electron transport layer, and an electron injection layer.

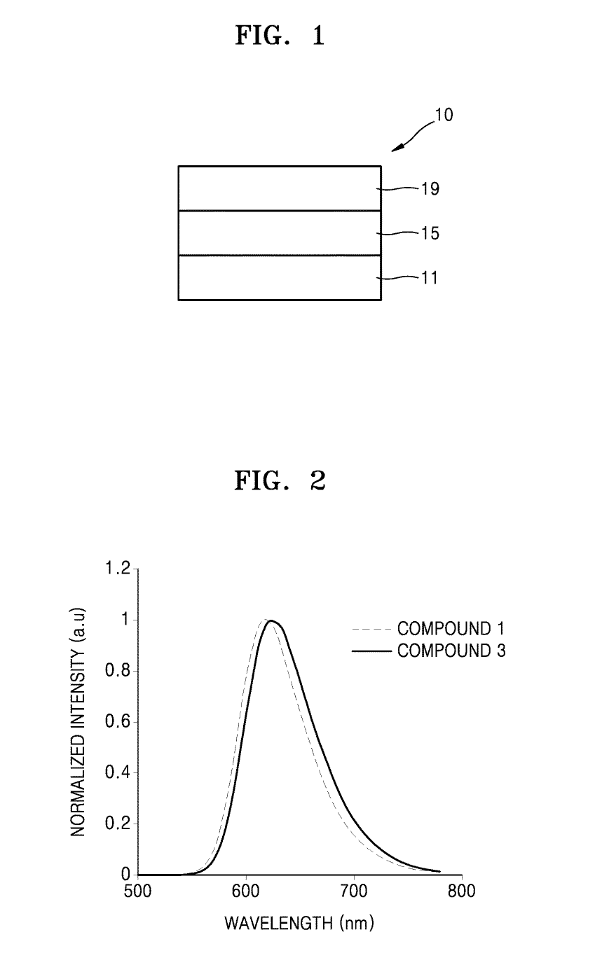

FIG. 1 is a schematic diagram of an organic light-emitting device 10 according to an embodiment. Hereinafter, the structure of an organic light-emitting device according to an embodiment and a method of manufacturing an organic light-emitting device, according to an embodiment, will be described in connection with FIG. 1. The organic light-emitting device 10 includes a first electrode 11, an organic layer 15, and a second electrode 19, which are sequentially stacked in this stated order.

A substrate may be additionally disposed under the first electrode 11 or above the second electrode 19. Any substrate that is used in general organic light-emitting devices may be used as the substrate, and the substrate may be a glass substrate or a transparent plastic substrate, each having excellent mechanical strength, thermal stability, transparency, surface smoothness, ease of handling, and water-resistance.

In one or more embodiments, the first electrode 11 may be formed by depositing or sputtering a material for forming the first electrode 11 on the substrate. The first electrode 11 may be an anode. The material for forming the first electrode 11 may be selected from materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be a metal, such as magnesium (Mg), aluminum (Al), aluminum-lithium (Al—Li), calcium (Ca), magnesium-indium (Mg—In), or magnesium-silver (Mg—Ag).

The first electrode 11 may have a single-layered structure or a multi-layered structure including two or more layers. For example, the first electrode 11 may have a three-layered structure of ITO/Ag/ITO, but embodiments of the structure of the first electrode 110 are not limited thereto.

The organic layer 15 may be disposed on the first electrode 11.

The organic layer 15 may include a hole transport region, an emission layer, and an electron transport region.

The hole transport region may be disposed between the first electrode 11 and the emission layer.

The hole transport region may include at least one selected from a hole injection layer, a hole transport layer, an electron blocking layer, and a buffer layer.

The hole transport region may include either a hole injection layer or a hole transport layer. In various embodiments, the hole transport region may have a hole injection layer/hole transport layer structure or a hole injection layer/hole transport layer/electron blocking layer structure, which are sequentially stacked in this stated order on the first electrode 11.

When the hole transport region includes a hole injection layer, the hole injection layer may be formed on the first electrode 11 by using one or more suitable methods, for example, vacuum deposition, spin coating, casting, and/or Langmuir-Blodgett (LB) deposition.

When a hole injection layer is formed by vacuum deposition, the deposition conditions may vary depending on a material that is used to form the hole injection layer and the structure and thermal properties of the hole injection layer. In some embodiments, the deposition conditions may include a deposition temperature of about 100° C. to about 500° C., a vacuum pressure of about 10⁻⁸ torr to about 10⁻³ torr, and a deposition rate of about 0.01 Angstroms per second (A/sec) to about 100 Å/sec. However, the deposition conditions are not limited thereto.

When the hole injection layer is formed using spin coating, coating conditions may vary depending on the material that is used to form the hole injection layer and the structure and thermal properties of the hole injection layer. For example, a coating speed may be from about 2,000 revolutions per minute (rpm) to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood to be substantially the same as conditions for forming the hole injection layer.

The hole transport region may include at least one selected from m-MTDATA, TDATA, 2-TNATA, NPB, β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, and a compound represented by Formula 202:

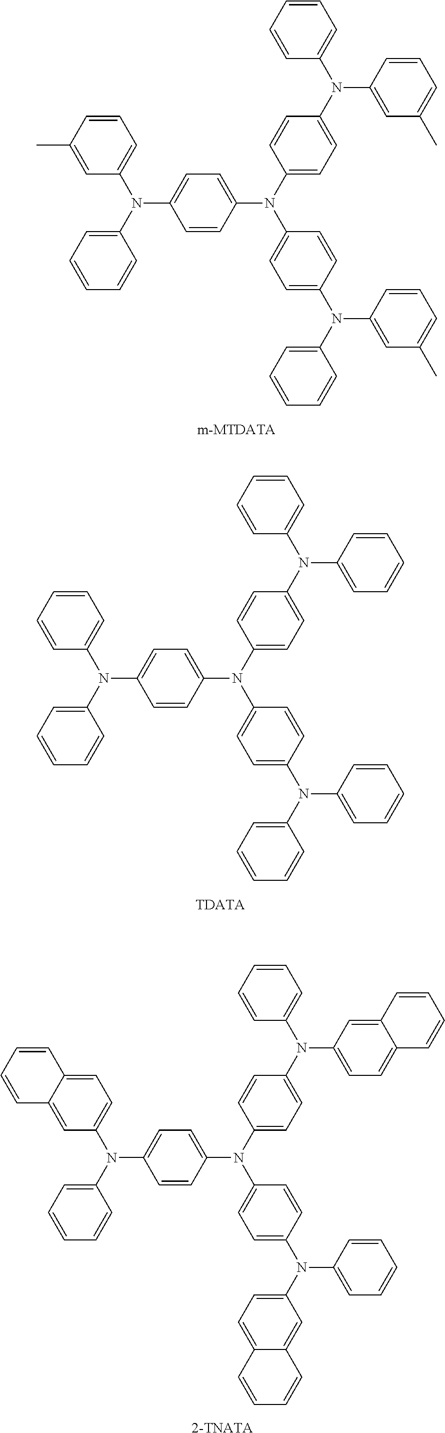

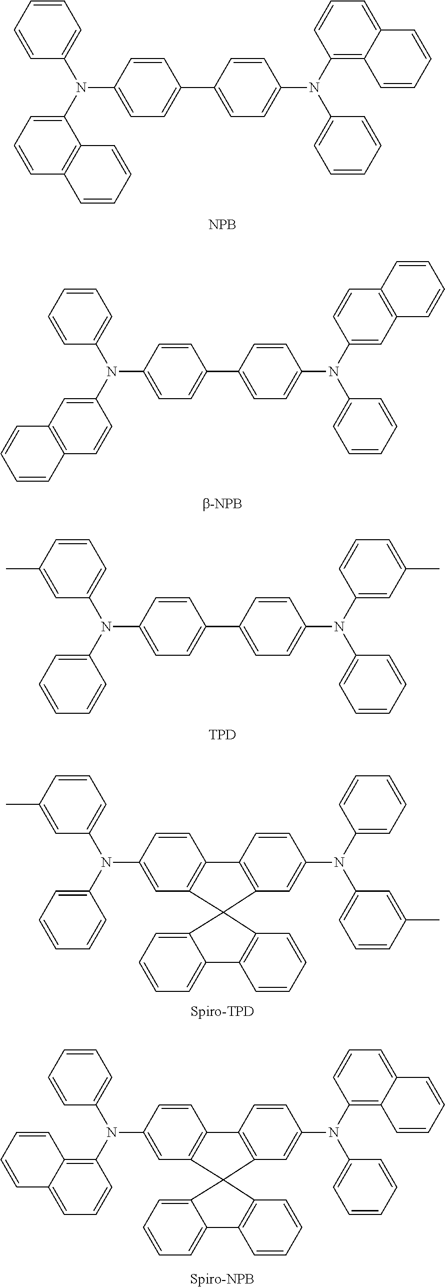

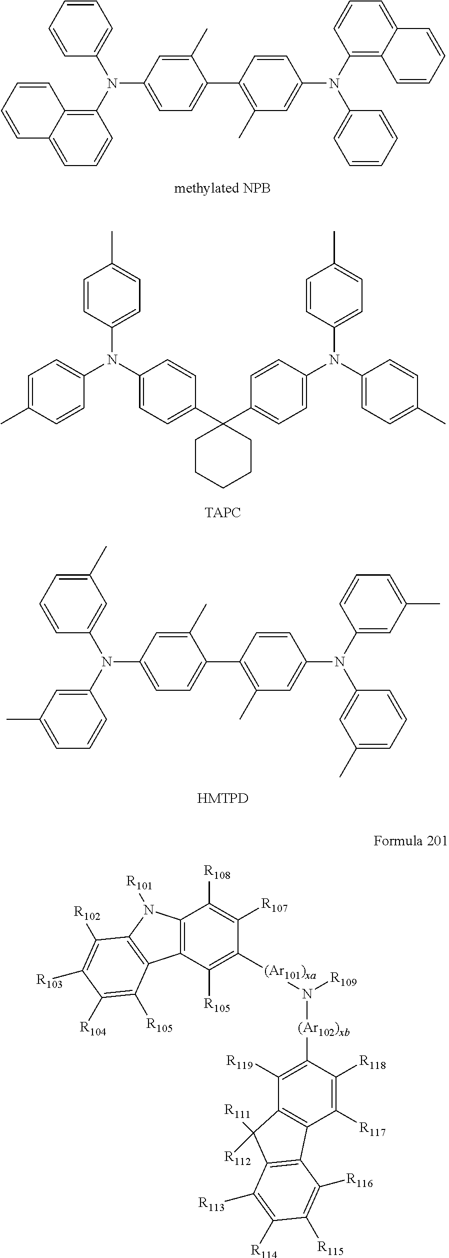

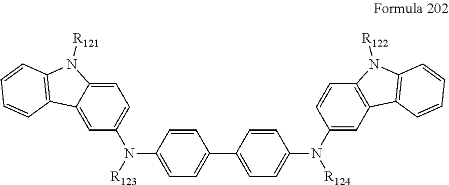

wherein, Ar₁₀₁ and Ar₁₀₂ in Formula 201 may each independently be selected from

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group; and

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group.

xa and xb in Formula 201 may each independently be an integer selected from 0 to 5. Alternatively, xa and xb may each independently be an integer selected from 0, 1, and 2. In some embodiments, xa may be 1 and xb may be 0, but embodiments are not limited thereto.

R₁₀₁ to R₁₀₈, R₁₁₁ to R₁₁₉, and R₁₂₁ to R₁₂₄ in Formulae 201 and 202 may each independently be selected from

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (e.g., a methyl group, an ethyl group, a propyl group, a butyl group, pentyl group, or a hexyl group), and a C₁-C₁₀ alkoxy group (e.g., a methoxy group, an ethoxy group, a propoxy group, a butoxy group, or a pentoxy group);

a C₁-C₁₀ alkyl group and a C₁-C₁₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;

a phenyl group, a naphthyl group, an anthracenyl group, a fluorenyl group, and a pyrenyl group; and

a phenyl group, a naphthyl group, an anthracenyl group, a fluorenyl group, and a pyrenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, and a C₁-C₁₀ alkoxy group, but embodiments are not limited thereto.

R₁₀₉ in Formula 201 may be selected from

a phenyl group, a naphthyl group, an anthracenyl group, and a pyridinyl group; and

a phenyl group, a naphthyl group, an anthracenyl group, and a pyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group and a pyridinyl group.

In some embodiments, the compound represented by Formula 201 may be represented by Formula 201A, but embodiments are not limited thereto:

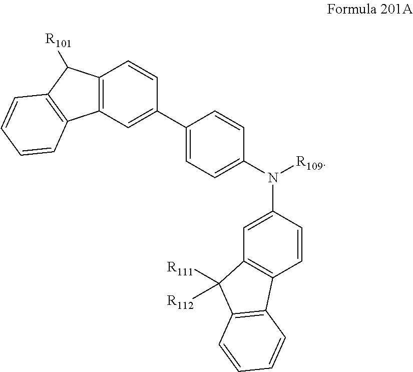

R₁₀₁, R₁₁₁, R₁₁₂, and R₁₀₉ in Formula 201A may be the same as those described above.

In some embodiments, the compound represented by Formula 201 and the compound represented by Formula 202 may include Compounds HT1 to HT20, but embodiments are not limited thereto:

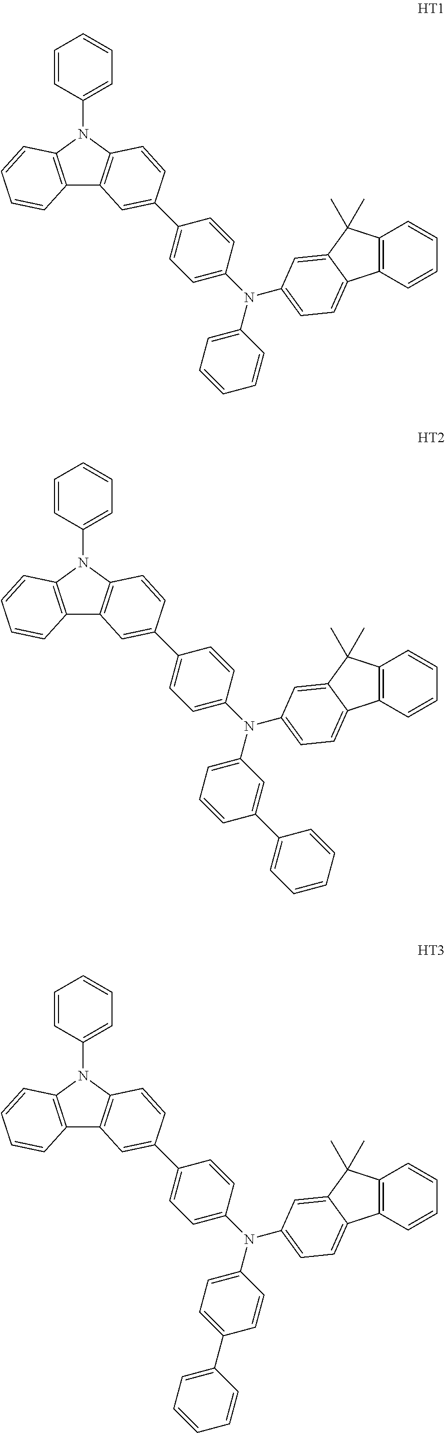 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

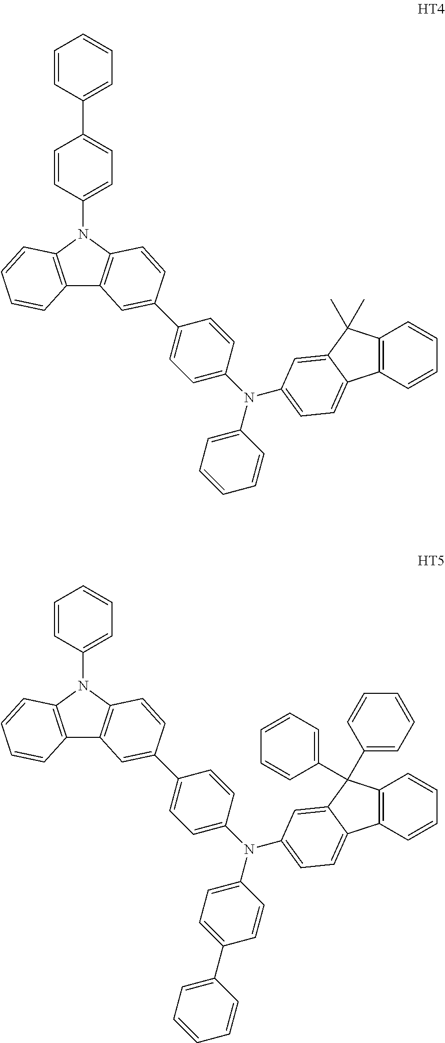 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

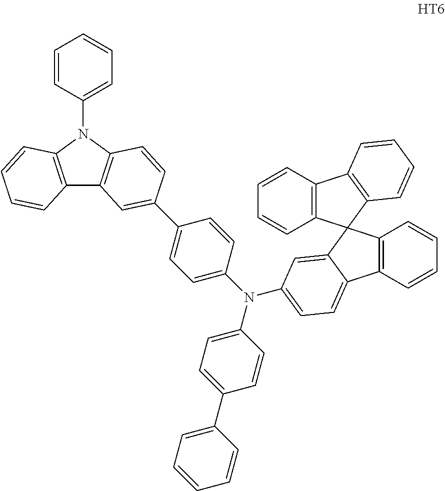 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

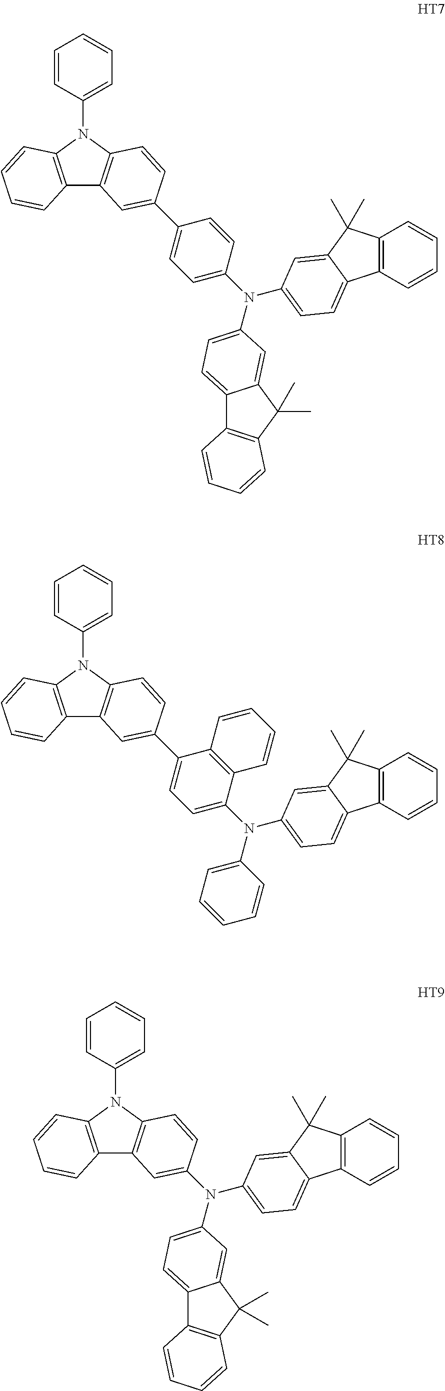 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

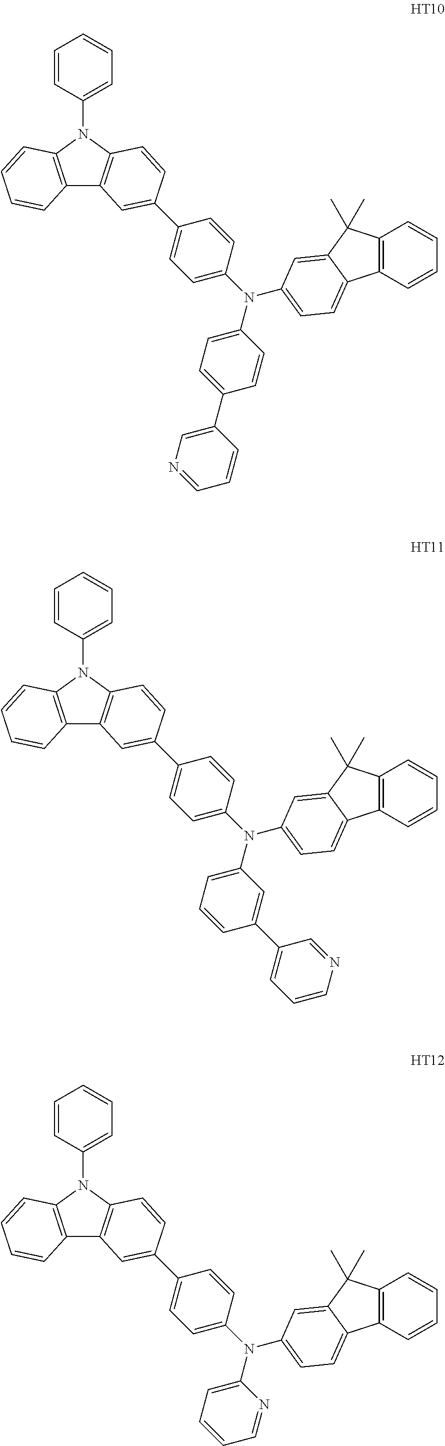 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

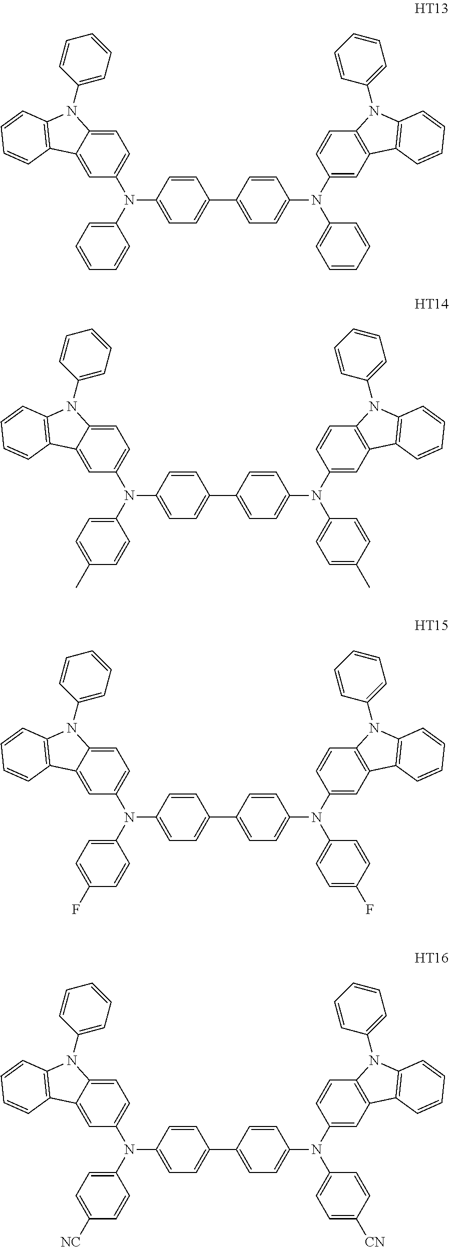 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

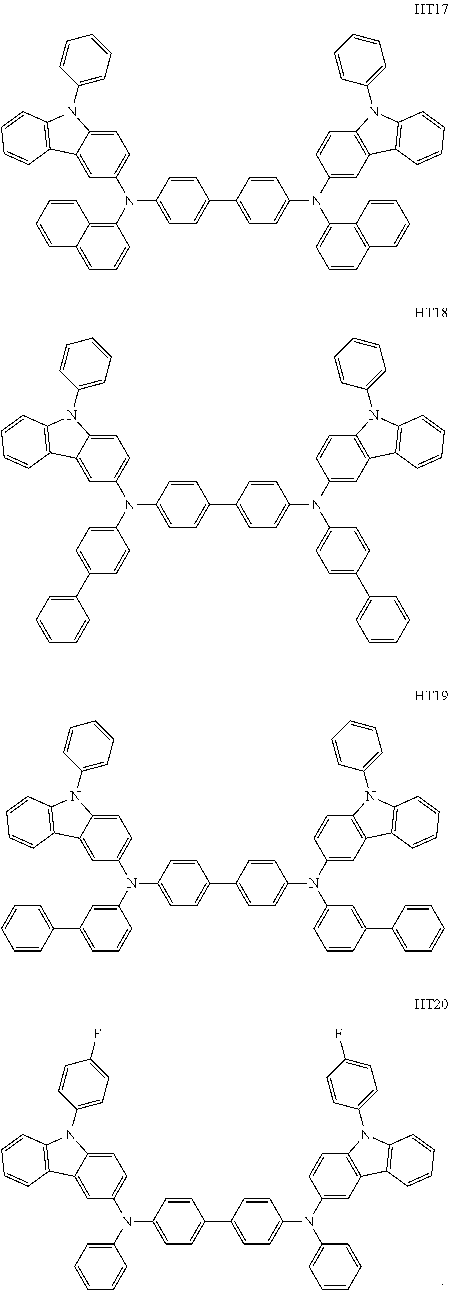 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

The thickness of the hole transport region may be in a range of about 100 Å to about 10,000 Å, for example, about 100 Å to about 1,000 Å. When the hole transport region includes both a hole injection layer and a hole transport layer, the thickness of the hole injection layer may be in a range of about 100 Å to about 10,000 Å, for example, about 100 Å to about 1,000 Å, and the thickness of the hole transport layer may be in a range of about 50 Å to about 2,000 Å, for example about 100 Å to about 1,500 Å. While not wishing to be bound by theory, it is understood that when the thicknesses of the hole transport region, the hole injection layer, and the hole transport layer are within any of these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be one selected from a quinone derivative, a metal oxide, and a cyano group-containing compound, but embodiments are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; and a cyano group-containing compound, such as Compound HT-D1 below, but are not limited thereto:

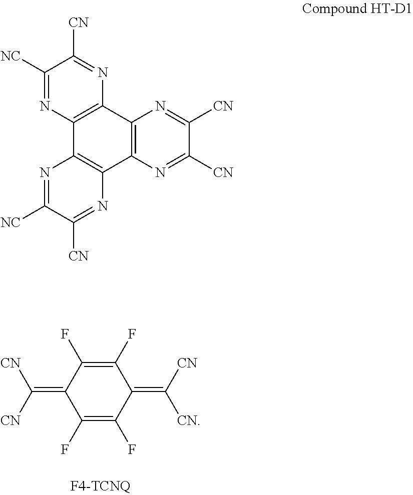

The hole transport region may include a buffer layer.

Also, the buffer layer may compensate for an optical resonance distance depending on a wavelength of light emitted from the emission layer, and thus, the efficiency of a formed organic light-emitting device may improve.

Then, an emission layer may be formed on the hole transport region by vacuum deposition, spin coating, casting, LB deposition, or the like. When the emission layer is formed by vacuum deposition or spin coating, the deposition or coating conditions may be similar to those applied to form the hole injection layer although the deposition or coating conditions may vary depending on the material that is used to form the emission layer.

Meanwhile, when the hole transport region includes an electron blocking layer, a material for the electron blocking layer may be selected from materials for the hole transport region described above and materials for a host described below. However, the material for the electron blocking layer is not limited thereto. For example, when the hole transport region includes an electron blocking layer, a material for the electron blocking layer may be mCP described below.

The emission layer may include a host and a dopant, and the dopant may include the organometallic compound represented by Formula 1.

The host may include at least one selected from TPBi, TBADN, ADN (also referred to as “DNA”), CBP, CDBP, TCP, mCP, Compound H50, and Compound H51:

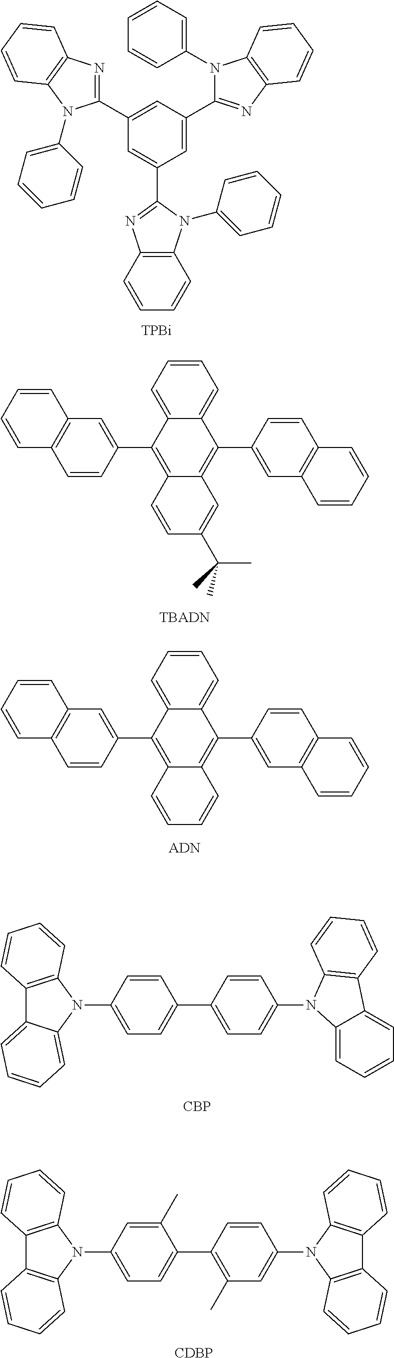

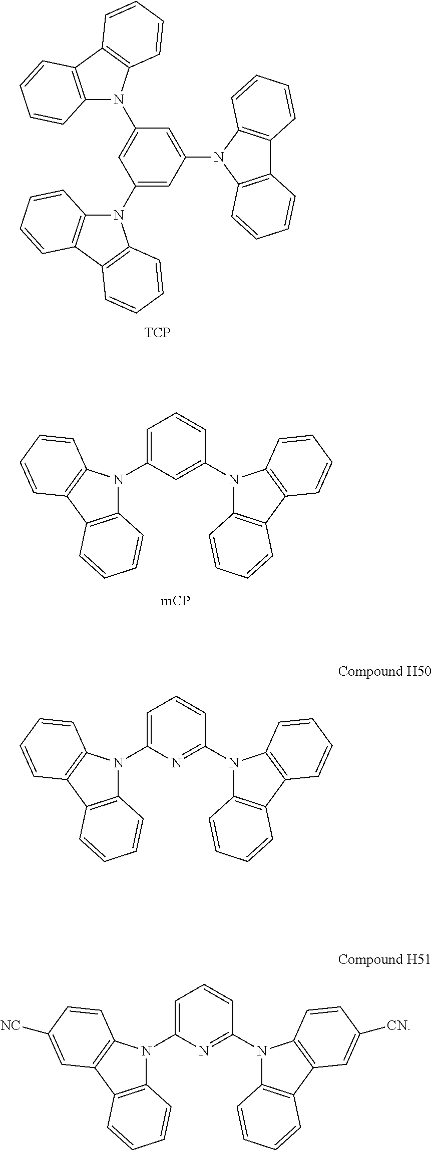

In some embodiments, the host may further include a compound represented by Formula 301:

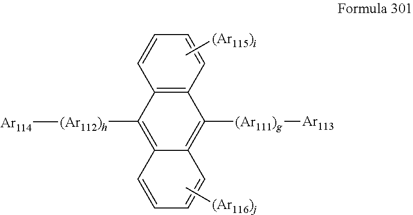

wherein, Ar₁₁₁ and Ar₁₁₂ in Formula 301 may each independently be selected from

a phenylene group, a naphthylene group, a phenanthrenylene group, and a pyrenylene group; and

a phenylene group, a naphthylene group, a phenanthrenylene group, and a pyrenylene group, each substituted with at least one selected from a phenyl group, a naphthyl group, and an anthracenyl group.

Ar₁₁₃ to Ar₁₁₆ in Formula 301 may each independently be selected from

a C₁-C₁₀ alkyl group, a phenyl group, a naphthyl group, a phenanthrenyl group, and a pyrenyl group; and

a phenyl group, a naphthyl group, a phenanthrenyl group, and a pyrenyl group, each substituted with at least one selected from a phenyl group, a naphthyl group, and an anthracenyl group.

g, h, i, and j in Formula 301 may each independently be an integer selected from 0 to 4, for example, 0, 1, or 2.

Ar₁₁₃ to Ar₁₁₆ in Formula 301 may each independently be selected from

a C₁-C₁₀ alkyl group substituted with at least one selected from a phenyl group, a naphthyl group, and an anthracenyl group;

a phenyl group, a naphthyl group, an anthracenyl group, a pyrenyl group, a phenanthrenyl group, and a fluorenyl group;

a phenyl group, a naphthyl group, an anthracenyl group, a pyrenyl group, a phenanthrenyl group, and a fluorenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a pyrenyl group, a phenanthrenyl group, and a fluorenyl group; and

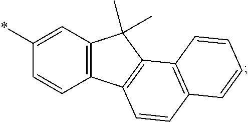 [SMILES: *c1ccc2c(c1)C(C)(C)c1c-2ccc2ccccc12]

but embodiments are not limited thereto.

In some embodiments, the host may include a compound represented by Formula 302:

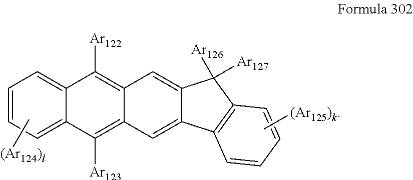

Ar₁₂₂ to Ar₁₂₅ in Formula 302 may be the same as described herein in connection with Ar₁₁₃ in Formula 301.

Ar₁₂₆ and Ar₁₂₇ in Formula 302 may each independently be a C₁-C₁₀ alkyl group, e.g., a methyl group, an ethyl group, or a propyl group.

k and l in Formula 302 may each independently be an integer selected from 0 to 4. In some embodiments, k and l may each be 0, 1, or 2.

In some embodiments, the compound represented by Formula 301 and the compound represented by Formula 302 may include Compounds HT1 to HT42, but embodiments are not limited thereto:

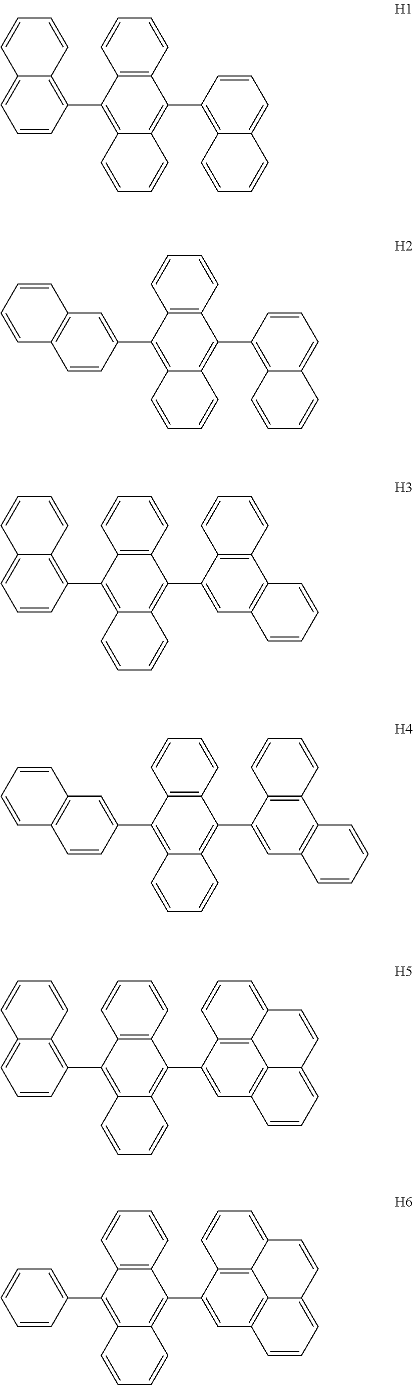

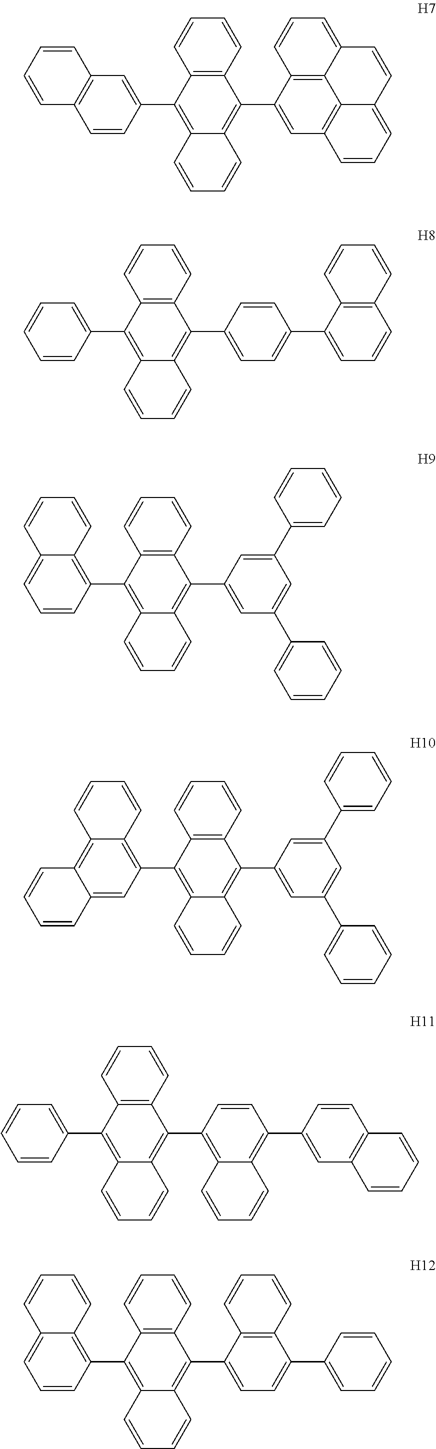

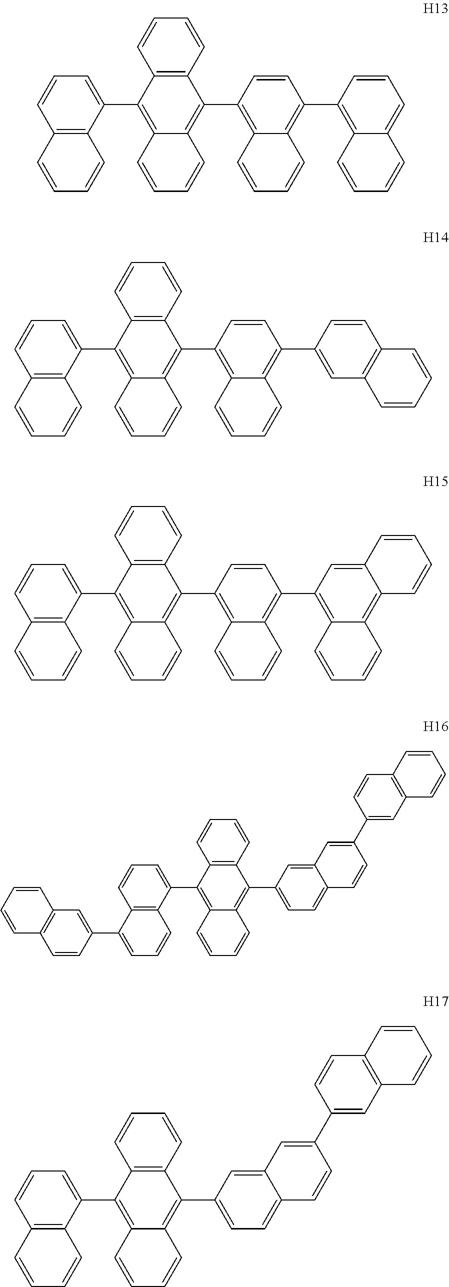

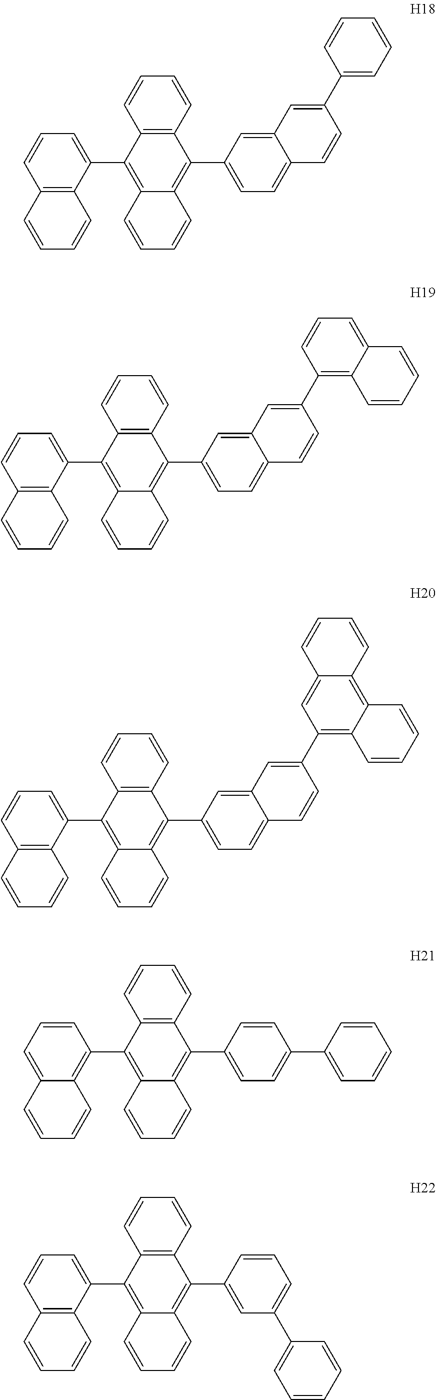

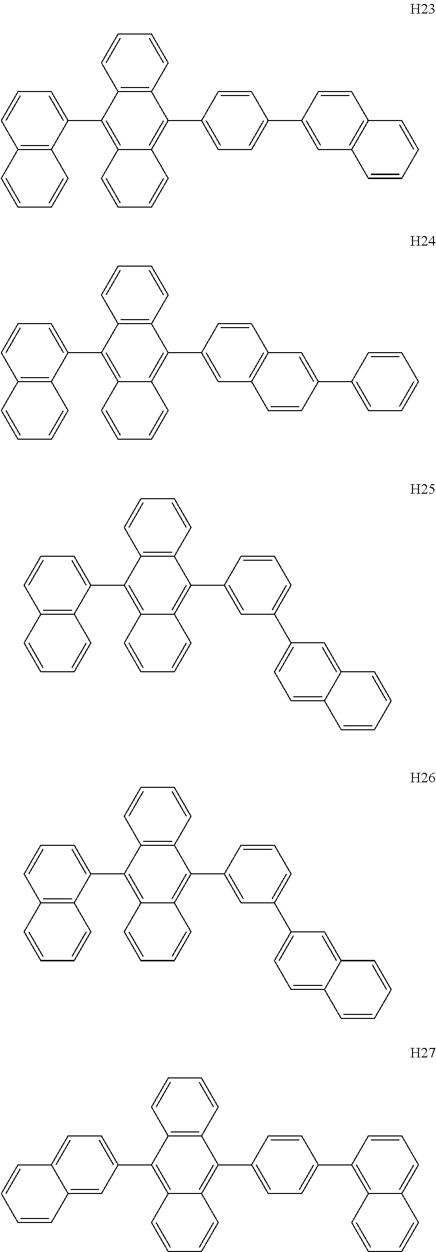

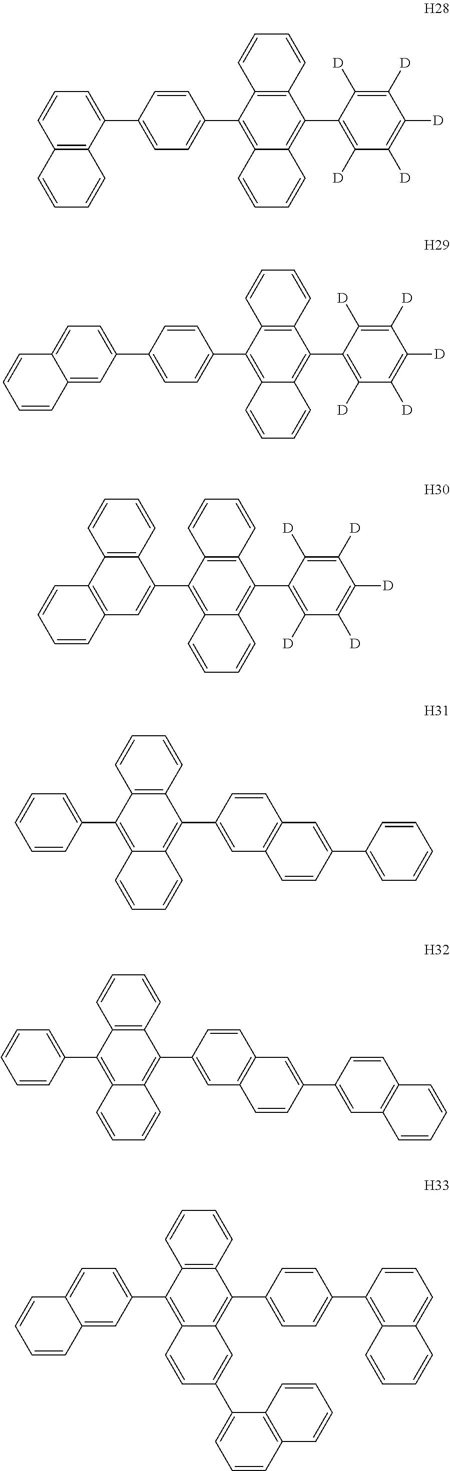

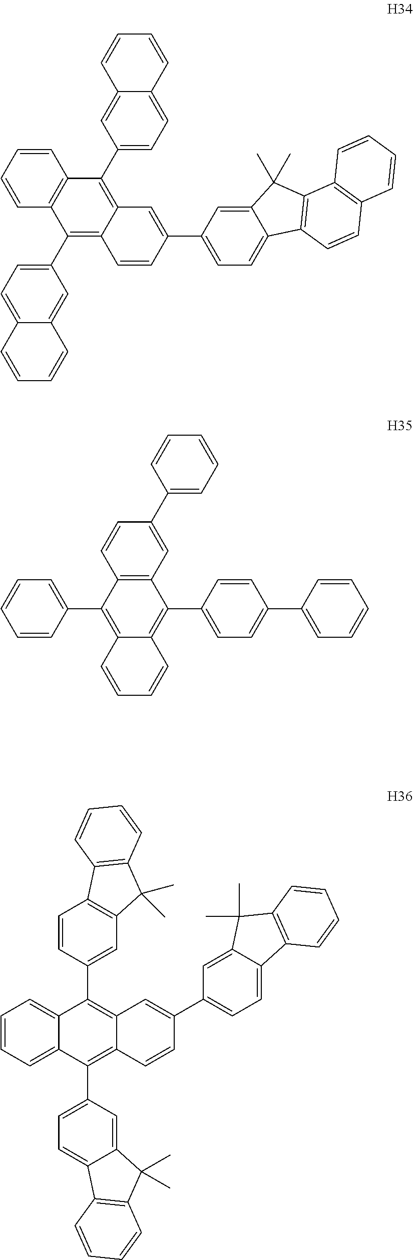

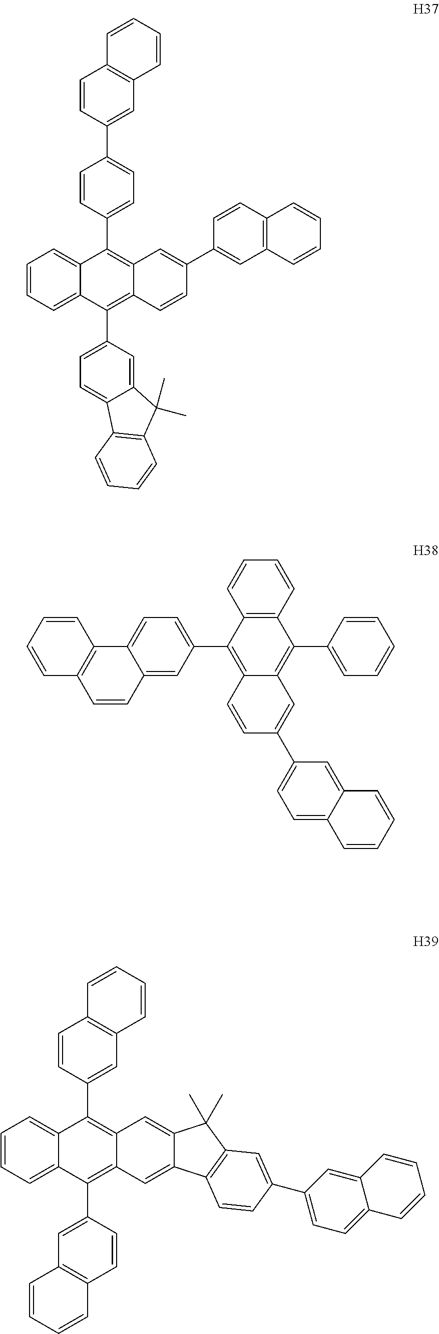

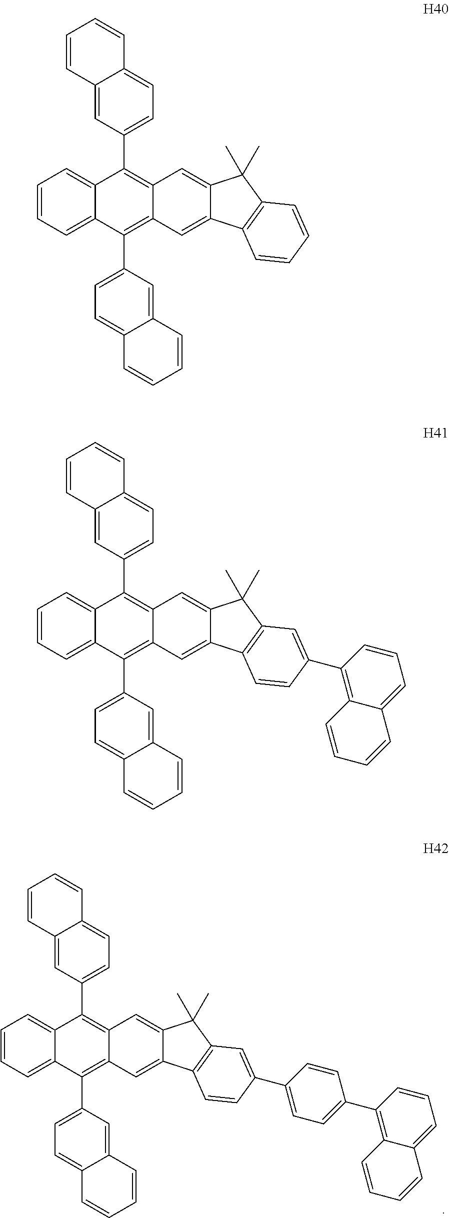

When the organic light-emitting device is a full color organic light-emitting device, the emission layer may be patterned into a red emission layer, a green emission layer, and a blue emission layer. In one or more embodiments, due to a stack structure including a red emission layer, a green emission layer, and/or a blue emission layer, the emission layer may emit white light.

When the emission layer includes a host and a dopant, the amount of the dopant may be in a range of about 0.01 parts by weight to about 15 parts by weight based on 100 parts by weight of the host, but embodiments are not limited thereto.

The thickness of the emission layer may be in a range of about 100 Å to about 1,000 Å, and in some embodiments, about 200 Å to about 600 Å. While not wishing to be bound by theory, it is understood that when the thickness of the emission layer is within any of these ranges, excellent light-emission characteristics may be obtained without a substantial increase in driving voltage.

Then, an electron transport region may be disposed on the emission layer.

The electron transport region may include at least one selected from a hole blocking layer, an electron transport layer, and an electron injection layer.

For example, the electron transport region may have a hole blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole blocking layer, the electron transport layer, and the electron injection layer, which constitute the electron transport region, may be understood to be substantially the same as conditions for forming the hole injection layer.

When the electron transport region includes a hole blocking layer, the hole blocking layer may include, for example, at least one selected from BCP, Bphen, and BAlq but embodiments are not limited thereto:

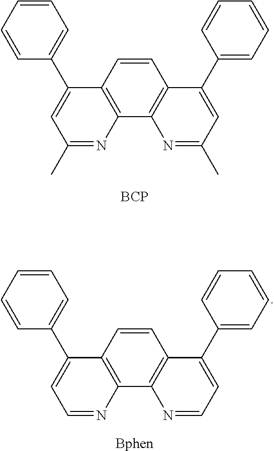

The thickness of the hole blocking layer may be in a range of about 20 Å to about 1,000 Å, for example, about 30 Å to about 300 Å. While not wishing to be bound by theory, it is understood that when the thickness of the hole blocking layer is within any of these ranges, the hole blocking layer may have excellent hole blocking characteristics without a substantial increase in driving voltage.

The electron transport layer may further include at least one selected from BCP, Bphen, Alq₃, BAlq, TAZ, and NTAZ:

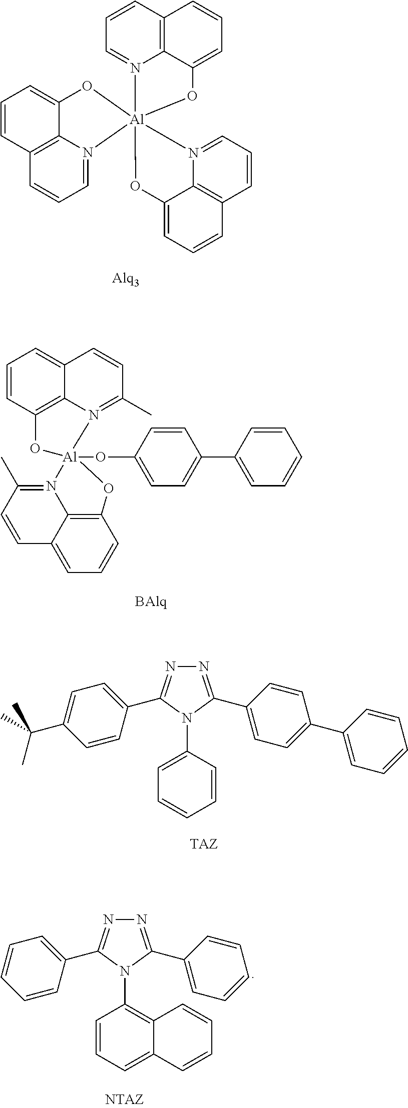

In one or more embodiments, the electron transport layer may include at least one selected from ET1 and ET2, but is not limited thereto:

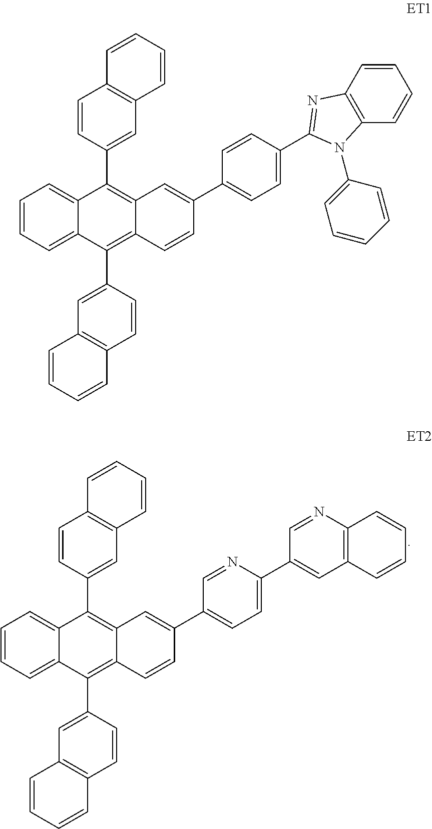 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1]

The thickness of the electron transport layer may be in a range of about 100 Å to about 1,000 Å, and in some embodiments, about 150 Å to about 500 Å. While not wishing to be bound by theory, it is understood that when the thickness of the electron transport layer is within any of these ranges, the electron transport layer may have satisfactory electron transport characteristics without a substantial increase in driving voltage.

Also, the electron transport layer may further include, in addition to the materials described above, a metal-containing material.

The metal-containing material may include a Li complex. The Li complex may include, for example, Compound ET-D1 (lithium quinolate, LiQ) or ET-D2:

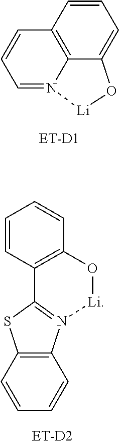

The electron transport region may include an electron injection layer that promotes flow of electrons from the second electrode 19 thereinto.

The electron injection layer may include at least one selected from LiF, NaCl, CsF, Li₂O, BaO, and LiQ.

The thickness of the electron injection layer may be in a range of about 1 Å to about 100 Å, and in some embodiments, about 3 Å to about 90 Å. While not wishing to be bound by theory, it is understood that when the thickness of the electron injection layer is within any of these ranges, the electron injection layer may have satisfactory electron injection characteristics without a substantial increase in driving voltage.

The second electrode 19 may be disposed on the organic layer 15. The second electrode 19 may be a cathode. The material for forming the second electrode 19 may be a metal, an alloy, an electrically conductive compound, and a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be used as the material for forming the second electrode 19. To manufacture a top emission-type light-emitting device, a transmissive electrode formed using ITO or IZO may be used as the second electrode 19.

Hereinbefore, the organic light-emitting device has been described with reference to FIG. 1, but is not limited thereto.

The term “C₁-C₆₀ alkyl group” as used herein refers to a linear or branched aliphatic saturated hydrocarbon monovalent group having 1 to 60 carbon atoms.

Examples thereof may include a methyl group, an ethyl group, a propyl group, an isobutyl group, a sec-butyl group, a tert-butyl group, a pentyl group, an iso-amyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by —OA₁₀₁ (wherein A₁₀₁ is a C₁-C₆₀ alkyl group), and examples thereof may include a methoxy group, an ethoxy group, and an iso-propyloxy (iso-propoxy) group.

The term “C₂-C₃₀ alkenyl group” as used herein refers to a hydrocarbon group having at least one carbon-carbon double bond in the middle or at the terminus of the C₂-C₃₀ alkyl group. Examples thereof may include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₃₀ alkynyl group” as used herein refers to a hydrocarbon group having at least one carbon-carbon triple bond in the middle or at the terminus of the C₂-C₃₀ alkyl group. Examples thereof may include an ethynyl group and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms. Examples thereof may include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent monocyclic group having at least one heteroatom selected from N, O, P, and S as a ring-forming atom, in addition to 1 to 10 carbon atoms. Examples thereof may include a tetrahydrofuranyl group and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms, at least one carbon-carbon double bond in its ring, and which is not aromatic. Examples thereof may include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, and S as a ring-forming atom, 1 to 10 carbon atoms, and at least one carbon-carbon double bond in its ring. Examples of the C₁-C₁₀ heterocycloalkenyl group include a 2,3-dihydrofuranyl group and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆₋₆₀ aryl group” as used herein refers to a monovalent group having a carbocyclic aromatic system having 6 to 60 carbon atoms. The term “C₆-C₆₀ arylene group” as used herein refers to a divalent group having a carbocyclic aromatic system having 6 to 60 carbon atoms. Examples of the C₆-C₆₀ aryl group may include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused.

The term “C₁-C₆₀ heteroaryl group” as used herein refers to a monovalent group having a heterocyclic aromatic system that has at least one heteroatom selected from N, O, P, and S as a ring-forming atom, in addition to 1 to 60 carbon atoms. The term “C₁-C₆₀ heteroarylene group” as used herein refers to a divalent group having a heterocyclic aromatic system that has at least one heteroatom selected from N, O, P, and S as a ring-forming atom, in addition to 1 to 60 carbon atoms. Examples of the C₁-C₆₀ heteroaryl group may include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused.

The term “C₆₋₆₀ aryloxy group” as used herein indicates —OA₁₀₂ (wherein A₁₀₂ is a C₆-C₆₀ aryl group). The term “C₆-C₆₀ arylthio group” as used herein indicates —SA₁₀₃ (wherein A₁₀₃ is a C₆-C₆₀ aryl group). The term “C₇-C₆₀ arylalkyl group” as used herein indicates -A₁₀₄A₁₀₅ (wherein A₁₀₅ is a C₆-C₅₉ aryl group and A₁₀₄ is a C₁-C₅₄ alkylene group).

The term “C₁-C₆₀ heteroaryloxy group” as used herein indicates —OA₁₀₆ (wherein A₁₀₆ is a C₁-C₆₀ heteroaryl group), the term “C₁-C₆₀ heteroarylthio group” as used herein indicates —SA₁₀₇ (wherein A₁₀₇ is a C₁-C₆₀ heteroaryl group), and the term “C₂-C₆₀ heteroarylalkyl group” as used herein indicates -A₁₀₈A₁₀₉ (wherein A₁₀₉ is a C₁-C₅₉ heteroaryl group and A₁₀₈ is a C₁-C₅₉ alkylene group).

The term “monovalent non-aromatic condensed polycyclic group” as used herein refers to a monovalent group (e.g., having 8 to 60 carbon atoms) that has two or more rings condensed, only carbon atoms as ring-forming atoms, and which is non-aromatic in the entire molecular structure. Examples of the monovalent non-aromatic condensed polycyclic group may include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 2 to 60 carbon atoms) that has two or more rings condensed, has heteroatoms selected from N, O, P, and S, other than carbon atoms, as ring-forming atoms, and which is non-aromatic in the entire molecular structure. Examples of the monovalent non-aromatic condensed heteropolycyclic group may include a carbazolyl group. The term “divalent non-aromatic condensed heteropolycyclic group” as used herein refers to a divalent group having the same structure as the monovalent non-aromatic condensed heteropolycyclic group.

In the presented specification, at least one substituent of the substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₁-C₆₀ heteroaryloxy group, substituted C₁-C₆₀ heteroarylthio group, substituted C₂-C₆₀ heteroarylalkyl group, substituted monovalent non-aromatic condensed polycyclic group, and substituted monovalent non-aromatic condensed heteropolycyclic group may be selected from:

deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group; and

—C(═O)(Q₁₁),—Si(Q₁₁)(Q₁₂)(Q₁₃), and —N(Q₁₁)(Q₁₂),

wherein Q₁₁ to Q₁₃ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, and a substituted or unsubstituted monovalent non-aromatic condensed heteropolycyclic group.

When a group containing a specified number of carbon atoms is substituted with any of the groups listed in the preceding paragraphs, the number of carbon atoms in the resulting “substituted” group is defined as the sum of the carbon atoms contained in the original (unsubstituted) group and the carbon atoms (if any) contained in the substituent. For example, when the term “substituted C₁-C₆₀ alkyl” refers to a C₁-C₆₀ alkyl group substituted with C₆-C₆₀ aryl group, the total number of carbon atoms in the resulting aryl substituted alkyl group is C₇-C₁₂₀.

Hereinafter, a compound and an organic light-emitting device according to an embodiment will be described in detail with reference to Synthesis Examples and Examples, however, the present disclosure is not limited thereto. The wording “B was used instead of A” used in describing Synthesis Examples means that an amount of B used was identical to an amount of A used in terms of molar equivalents.

### EXAMPLES

### Synthesis Example 1

### Synthesis of Compound 1

1) Synthesis of Compound A3

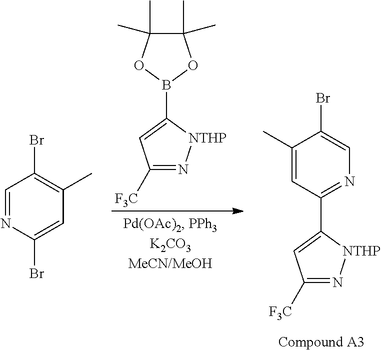

6.56 grams (g) (26.14 millimoles (mmol)) of 2,5-dibromo-4-methylpyridine, 10.9 g (31.37 mmol) of pyrazole pinacol boronate (wherein “THP” is 2-tetrahydropyranyl), 0.29 g (1.31 mmol) of Pd(OAc)₂, 0.69 g (2.61 mmol) of triphenylphosphine, and 7.23 g (52.28 mmol) of K₂CO₃ were mixed with 90 milliliters (mL) of acetonitrile and 45 mL of methanol. Then, the mixture was stirred at a temperature of 50° C. for about 18 hours, cooled to room temperature, and filtered. An organic layer was extracted therefrom by using dichloromethane, and anhydrous magnesium sulfate (MgSO₄) was added thereto to dry the organic layer. The resultant was filtered and a solvent in the obtained filtrate was removed under reduced pressure. The residual was purified by column chromatography using ethyl acetate and hexane at a ratio of 1:25 (volume to volume, v/v) to obtain 2.43 g (24%) of Compound A3. The identity of the obtained compound was confirmed by using LCMS and ¹H NMR.

1H-NMR (CDCl₃) δ 8.61 (s, 1H), 7.36 (s, 1H), 6.79 (s, 1H), 6.30 (dd, 1H), 4.02 (d, 1H), 3.60 (t, 1H), 2.51 (s, 3H), 2.09 (m, 2H), 1.71 (m, 2H), 1.54 (m, 2H).

MS: m/z 391.04 [(M+1)⁺].

2) Synthesis of Compound A2

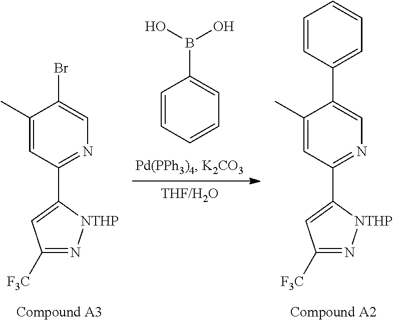

2.43 g (6.23 mmol) of Compound A3 (wherein “THP” is 2-tetrahydropyranyl), 0.91 g (7.47 mmol) of phenylboronic acid, 0.50 g (0.44 mmol) of Pd(PPh₃)₄, and 1.29 g (9.34 mmol) of K₂CO₃ were mixed with 20 mL of tetrahydrofuran (THF) and 10 mL of distilled water. Then, the mixture was stirred at a temperature of 75° C. for about 12 hours, and cooled to room temperature. An organic layer was extracted therefrom by using ethyl acetate, and anhydrous MgSO₄ was added thereto to dry the organic layer.

The resultant was filtered and a solvent in the obtained filtrate was removed under reduced pressure. The residual was purified by column chromatography using ethyl acetate and hexane at a ratio of 1:10 (v/v) to obtain 2.08 g (86%) of Compound A2. The identity of the obtained compound was confirmed by using LCMS and ¹H NMR.

1H-NMR (CDCl₃) δ 8.50 (s, 1H), 7.61 (s, 1H), 7.53 (m, 3H), 7.39 (m, 2H), 7.03 (s, 1H), 6.30 (dd, 1H), 4.02 (d, 1H), 3.60 (t, 1H), 2.42 (s, 3H), 2.09 (m, 2H), 1.71 (m, 2H), 1.54 (m, 2H).

MS: m/z 388.16 [(M+1)⁺].

3) Synthesis of Compound A1

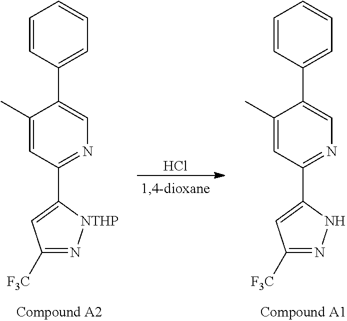

0.99 g (2.58 mmol) of Compound A2 (wherein “THP” is 2-tetrahydropyranyl) was dissolved in 15 mL of 1,4-dioxane. The solution was slowly added to 6.44 mL (12.88 mmol) of hydrochloric acid dissolved in diethyl ether at a concentration of 2.0 normal (N) and stirred at a temperature of 65° C. for 2 hours. Once the reaction was completed, the mixture was cooled to room temperature, and the obtained precipitate was filtered under reduced pressure, and washed with diethyl ether. The obtained solid was neutralized by using a sodium hydrogen carbonate aqueous solution. Subsequently, an organic layer was extracted therefrom by using ethyl acetate, and anhydrous MgSO₄ was added thereto to dry the organic layer. The resultant was filtered and a solvent in the obtained filtrate was removed under reduced pressure. The residual was purified by column chromatography using ethyl acetate and hexane at a ratio of 1:5 (v/v) to obtain 0.55 g (71%) of Compound A1. The identity of the obtained compound was confirmed by using LCMS and ¹H NMR.

1H-NMR (CDCl₃) δ 12.1 (br. s, 1H), 8.49 (s, 1H), 7.59 (s, 1H), 7.51 (m, 3H), 7.37 (m, 3H), 7.00 (s, 1H), 2.41 (s, 3H).

MS: m/z 304.10 [(M+1)⁺].

4) Synthesis of Compound 1

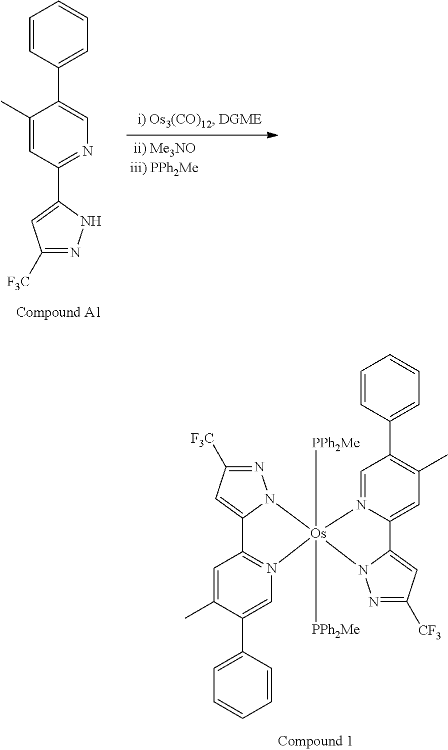

0.55 g (1.82 mmol) of Compound A1 and 0.27 g (0.29 mmol) of triosmium dodecacarbonyl were dissolved in 15 mL of diethylene glycol monoethyl ether (DGME), and the solution was refluxed at a temperature of 180° C. for 18 hours. The solution was cooled to a temperature of 110° C., and 0.16 g (2.11 mmol) of trimethyl amine N-oxide dissolved in 5 mL of diethylene glycol monoethyl ether was slowly added thereto.

Subsequently, the reaction solution was stirred at a temperature of 110° C. for 10 minutes to carry out a reaction, 0.79 mL (4.25 mmol) of diphenylmethyl phosphine was added thereto, the temperature was raised to 180° C., and then the resulting mixture was stirred for 18 hours. Once the reaction was completed, the resultant was cooled to room temperature, and the obtained solid was filtered under reduced pressure, and washed with methanol. The identity of the obtained compound was confirmed by using LCMS and ¹H NMR.

1H-NMR (CDCl₃) (9.85 (br. s, 2H), 7.52 (t, 4H), 7.43 (t, 2H), 7.31 (d, 4H), 6.98 (m, 12H), 6.80 (t, 4H), 6.69 (s, 2H), 6.58 (d, 4H), 6.36 (br. s, 2H), 2.14 (s, 6H), 0.993 (s, 6H).

MS: m/z 1197.29 [(M+1)⁺].

### Synthesis Example 2

### Synthesis of Compound 3

1) Synthesis of Compound B2

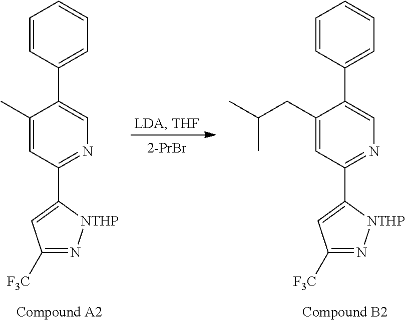

2.08 g (5.37 mmol) of Compound A2 was mixed with 30 mL of THF, and the mixture was cooled up to a temperature of −78° C. 13.42 mmol of lithium diisopropylamide (LDA) was slowly added thereto. The mixture was stirred at a temperature of −78° C. for 1 hour to carry out a reaction. The temperature was then raised to room temperature, and the reaction was additionally carried out for 1.5 hours. The temperature was subsequently reduced to −78° C., and 1.26 mL (13.42 mmol) of 2-bromopropane was slowly added to the reaction mixture. Then, the temperature was raised to room temperature, and the reaction was carried out for 12 hours. An organic layer was extracted therefrom by using dichloromethane, and MgSO₄ was added thereto to dry the organic layer. The resultant was filtered, and a solvent in the obtained filtrate was removed under reduced pressure. The residual was purified by column chromatography using ethyl acetate and hexane at a ratio of 1:8 (v/v) to obtain 0.92 g (40%) of Compound B2. The identity of the obtained compound was confirmed by using LCMS and ¹H NMR.

1H-NMR (CDCl₃) δ 8.50 (s, 1H), 7.61 (s, 1H), 7.53 (m, 3H), 7.39 (m, 2H), 7.03 (s, 1H), 6.30 (dd, 1H), 4.02 (d, 1H), 3.60 (t, 1H), 2.41 (d, 2H), 2.09 (m, 2H), 1.99 (m, 1H), 1.71 (m, 2H), 1.54 (m, 2H), 1.07 (d, 6H).

MS: m/z 430.20 [(M+1)⁺].

2) Synthesis of Compound B1

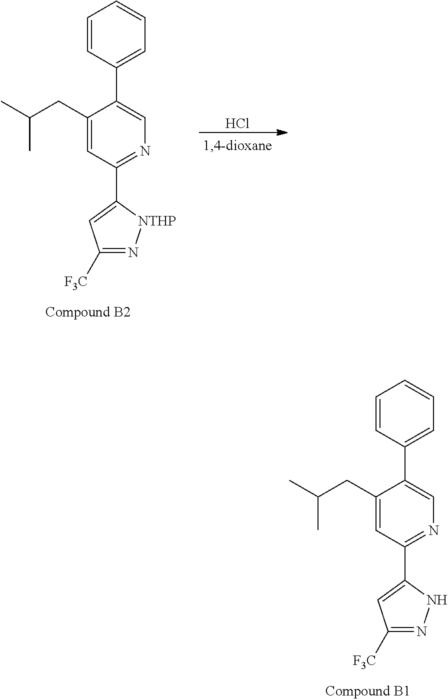

0.92 g (2.37 mmol) of Compound B2 was dissolved in 15 mL of 1,4-dioxane. The solution was slowly added to 5.94 mL (11.87 mmol) of hydrochloric acid dissolved in diethyl ether at a concentration of 2.0 N and stirred at a temperature of 65° C. for 2 hours. Once the reaction was completed, the mixture was cooled to room temperature, and the obtained precipitate was filtered under reduced pressure, and washed with diethyl ether. The obtained solid was neutralized by using a sodium hydrogen carbonate aqueous solution. Subsequently, an organic layer was extracted therefrom by using ethyl acetate, and anhydrous MgSO₄ was added thereto to dry the organic layer. The resultant was filtered and a solvent in the obtained filtrate was removed under reduced pressure. The residual was purified by column chromatography using ethyl acetate and hexane at a ratio of 1:5 (v/v) to obtain 0.83 g (71%) of Compound B1.

The identity of the obtained compound was confirmed by using LCMS and ¹H NMR.

1H-NMR (CDCl₃) δ 12.1 (br. s, 1H), 8.43 (s, 1H), 7.53 (s, 1H), 7.46 (m, 3H), 7.31 (m, 2H), 6.99 (s, 1H), 2.57 (d, 2H), 1.78 (m, 1H), 0.79 (d, 6H).

MS: m/z 346.15 [(M+1)⁺].

3) Synthesis of Compound 3

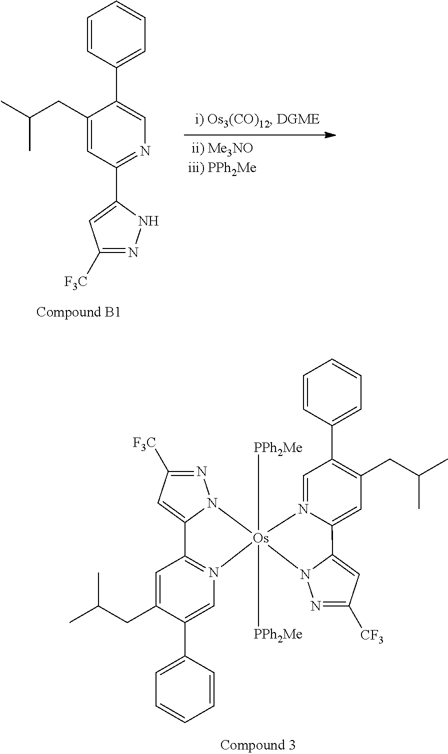

0.82 g (2.38 mmol) of Compound B1 and 0.35 g (0.39 mmol) of triosmium dodecacarbonyl were dissolved in 20 mL of diethylene glycol monoethyl ether, and the solution was refluxed at a temperature of 180° C. for 18 hours. The solution was cooled to a temperature of 110° C., and 0.21 g (2.81 mmol) of trimethyl amine N-oxide dissolved in 5 mL of diethylene glycol monoethyl ether was slowly added thereto. Subsequently, the reaction solution was stirred at a temperature of 110° C. for 10 minutes to carry out a reaction, 1.05 mL (5.67 mmol) of diphenylmethyl phosphine was added thereto, the temperature was raised to 180° C., and the resulting mixture was stirred for 18 hours. Once the reaction was completed, the resultant was cooled to room temperature, and the obtained solid was filtered under reduced pressure, and washed with methanol. The identity of the obtained compound was confirmed by using LCMS and ¹H NMR.

1H-NMR (CDCl₃) δ 7.50 (m, 7H), 7.18 (m, 1H), 7.03 (m, 7H), 6.97 (m, 7H), 6.83 (t, 5H), 6.63 (m, 7H), 6.39 (m, 2H), 2.36 (d, 4H), 1.90 (m, 2H), 0.65 (d, 12H), 0.60 (d, 3H), 0.55 (d, 3H).

MS: m/z 1281.39 [(M+1)⁺].

### Evaluation Example 1

### Photoluminescence (PL) Spectrum Evaluation

Compounds 1 and 3 were dissolved at a concentration of 0.1 millimolar (mM) in toluene, and an ISC PC1 spectrofluorometer, in which a Xenon lamp was mounted, was used to measure PL spectra of Compounds 1 and 3 at room temperature. The results thereof are shown in Table 2 and FIG. 2.

TABLE 2

| | λₘₐₓ |
|---|---|
| Compound No. | (nm) |
| Compound 1 | 622 |
| Compound 3 | 623 |

Referring to Table 2, it was found that Compounds 1 and 3 emitted red light.

### Evaluation Example 2

### Thermal Characteristics Evaluation

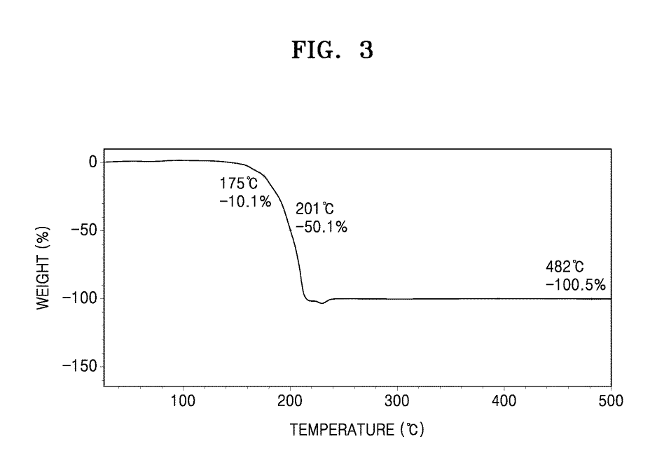

Thermal analysis (N₂ atmosphere, temperature range: room temperature to 800° C. (10 degrees Centigrade per minute, ° C./min)-TGA, and Pan Type: Pt Pan in disposable Al Pan (TGA)) was performed on Compound 3 by using thermogravimetric analysis (TGA). The results thereof are shown in FIG. 3. Referring to FIG. 3, Compound 3 was found to have excellent thermal stability.

### Example 1

A glass substrate, on which an anode having an ITO/Ag/ITO (70 Å/1,000 Å/70 Å) structure was deposited, was cut to a size of 50 millimeters (mm)×50 mm×0.5 mm, sonicated in iso-propyl alcohol and water for 5 minutes, respectively, and cleaned by exposure to ultraviolet rays for 30 minutes, and then—to ozone. The glass substrate was mounted on a vacuum-deposition device.

2-TNATA was deposited on the anode to form a hole injection layer having a thickness of 600 Å. 4,4′-bis[N-(1-naphthyl)-N-phenylamino]biphenyl (hereinafter, referred as “NPB”) was deposited on the hole injection layer to form a hole transport layer having a thickness of 1,350 Å.

CBP (as a host) and Compound 1 (as a dopant) were co-deposited on the hole transport layer at a weight ratio of 94:6 to form an emission layer having a thickness of 400 Å. BCP was deposited on the emission layer to form a hole blocking layer having a thickness of 50 Å. Subsequently, Alq₃ was deposited on the hole blocking layer to form an electron transport layer having a thickness of 350 Å. LiF was deposited on the electron transport layer to form an electron injection layer having a thickness of 10 Å. Mg:Ag was deposited on the electron injection layer at a weight ratio of 90:10 to form a cathode having a thickness of 120 Å, thereby completing the manufacture of an organic light-emitting device (red light-emitting organic light-emitting device).

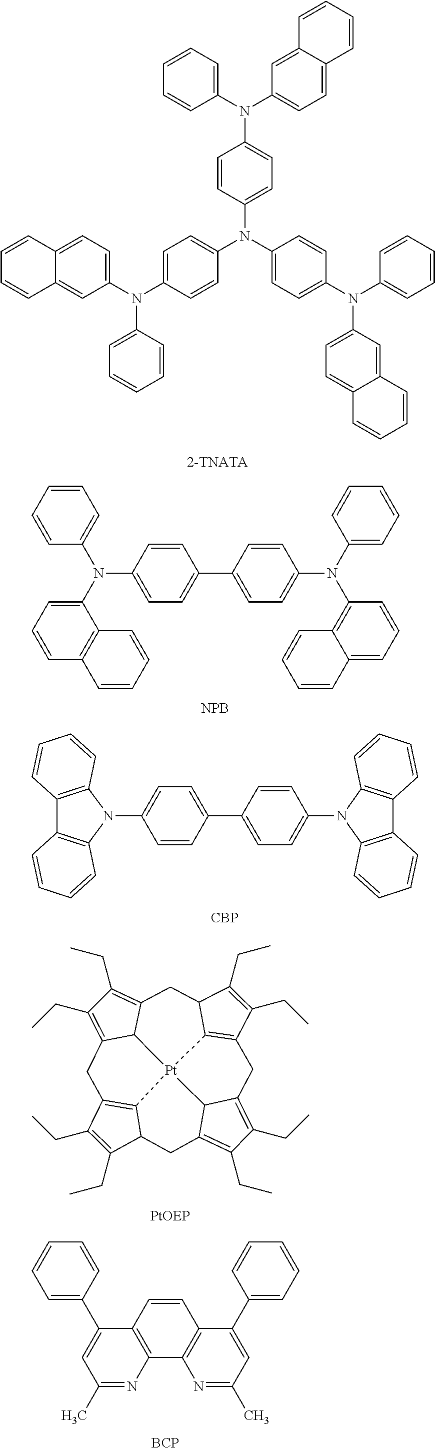

### Example 2

An organic light-emitting device (emitting red light) was manufactured in the same manner as in Example 1, except that Compound 3 was used in place of Compound 1 to form the emission layer.

### Comparative Example 1

An organic light-emitting device was manufactured in the same manner as in Example 1, except that Compound B was used in place of Compound 1 to form the emission layer:

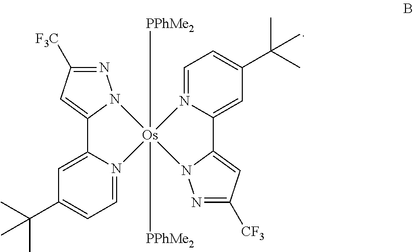

### Comparative Example 2

An organic light-emitting device was manufactured in the same manner as in Example 1, except that PtOEP was used in place of Compound 1 to form the emission layer:

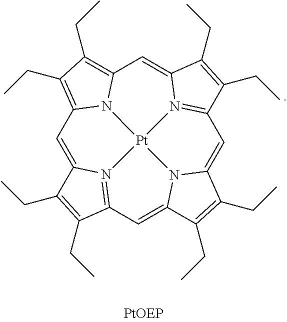

### Evaluation Example 3

### Evaluation of Characteristics of Organic Light-Emitting Device

The driving voltage, current density, luminance, efficiency, external quantum efficiency, PL decay time, roll-off, color-coordinate, and lifespan (T₉₇) of the organic light-emitting devices manufactured in Examples 1 to 3 and Comparative Examples 1 and 2 were evaluated. The results thereof are shown in Table 3. A Keithley 2400 current voltmeter and a luminance meter (Minolta Cs-1000A) were used in the evaluation. The lifespan (T₉₇) refers to time required for the initial luminance of the organic light-emitting device to reduce by 97%.

TABLE 3

| | | | | | External | | | | | |
|---|---|---|---|---|---|---|---|---|---|---|
| | | Driving | Current | | quantum | Decay | | | | |
| | | voltage | density | Efficiency | efficiency | time | Roll-off | λₘₐₓ | | LT₉₇ |
| | Dopant | (V) | (mA/cm²) | (cd/A) | (%) | (μs) | (%) | (nm) | CIEx | (hr) |
| Example 1 | Compound 1 | 4.7 | 7.9 | 19.1 | 18.7 | 0.89 | 11 | 622 | 0.66 | 125 |
| Example 2 | Compound 3 | 4.5 | 6.5 | 23.1 | 23.3 | 0.79 | 9 | 623 | 0.67 | 200 |
| Comparative | B | 4.9 | 8.0 | 18.9 | 15.1 | 0.87 | 15 | 616 | 0.64 | 65 |
| Example 1 | | | | | | | | | | |
| Comparative | PtOEP | 7.3 | 10.1 | 4.5 | 4.0 | 24 | 43 | 645 | 0.69 | 40 |
| Example 2 | | | | | | | | | | |

Referring to Table 3, the organic light-emitting devices manufactured in Examples 1 and 2 were found to have excellent efficiency, as compared with the organic light-emitting devices manufactured in Comparative Examples 1 and 2.

In addition, since the organometallic compound represented by Formula 1 includes a pyridine ring substituted with an aryl group, such as a phenyl group, at a certain position, an organic light-emitting device including the organometallic compound may have improved lifespan and efficiency as seen by Examples 1 and 2 and Comparative Examples 1 and 2.

In addition, by introducing a bulky substituent at an α-position of an aryl group of a pyridine ring, triplet-triplet annihilation may decrease, thus improving the efficiency of an organic light-emitting device as seen by Examples 1 and 2.

Since the compounds included in the organic light-emitting devices of Examples 1 and 2 may have relatively short decay time, the organic light-emitting devices of Examples 1 and 2 may each have low roll-off and high efficiency.

As described above, an organometallic compound, according to one or more embodiments, has excellent electric characteristics and thermal stability. Accordingly, an organic light-emitting device using the organometallic compound has excellent efficiency, excellent external quantum efficiency, low driving voltage, high luminance, long lifespan characteristics, and low roll-off characteristics.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present disclosure as defined by the following claims.

What is claimed is:

1. An organometallic compound represented by Formula 1: 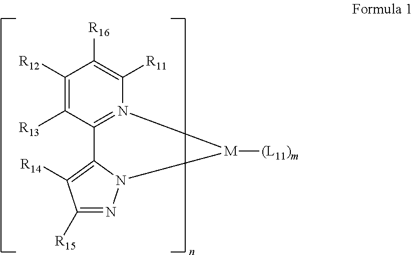
wherein, in Formula 1,
M is selected from osmium (Os) and ruthenium (Ru),
R₁₁ to R₁₃ and R₁₆ are each independently selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, and a substituted or unsubstituted monovalent non-aromatic condensed heteropolycyclic group, provided that at least one selected from R₁₁ to R₁₃ and R₁₆ is selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group,
R₁₄ and R₁₅ are each independently selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, and a substituted or unsubstituted C₆-C₆₀ aryl group,
n is selected from 1, 2, and 3,
L₁₁ is selected from a monodentate ligand and a bidentate ligand, and
m is selected from 0, 1, 2, 3, and 4.

2. The organometallic compound of claim 1, wherein
R₁₁, R₁₂, R₁₃, or R₁₆ is selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group;
two substituents of among R₁₁, R₁₂, R₁₃, and R₁₆ are each independently selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group;
three substituents of among R₁₁, R₁₂, R₁₃, and R₁₆ are each independently selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group; or
R₁₁, R₁₂, R₁₃, and R₁₆ are each independently selected from a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

3. The organometallic compound of claim 1, wherein
R₁₁ to R₁₃ and R₁₆ are each independently selected from hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a neo-pentyl group, a cyclopentyl group, a cyclohexyl group, and a cycloheptyl group;
a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, and a neo-pentyl group, each substituted with at least one selected from deuterium, —F, —Cl, —Br, —I, and a cyano group;
a cyclopentyl group, a cyclohexyl group, and a cycloheptyl group, each substituted with at least one selected from deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, and a neo-pentyl group;
a phenyl group, a naphthyl group, a phenanthrenyl group, an anthracenyl group, a pyrenyl group, a chrysenyl group, a pyrrolyl group, a thiophenyl group, a furanyl group, an imidazolyl group, a thiazolyl group, an oxazolyl group, a pyridinyl group, a pyrazinyl group, a pyrimidinyl group, a quinolinyl group, an isoquinolinyl group, a benzoquinolinyl group, a quinoxalinyl group, a quinazolinyl group, a naphthyridinyl group, a benzofuranyl group, a benzothiophenyl group, a triazinyl group, a dibenzofuranyl group, and a dibenzothiophenyl group; and
a phenyl group, a naphthyl group, a phenanthrenyl group, an anthracenyl group, a pyrenyl group, a chrysenyl group, a pyrrolyl group, a thiophenyl group, a furanyl group, an imidazolyl group, a thiazolyl group, an oxazolyl group, a pyridinyl group, a pyrazinyl group, a pyrimidinyl group, a quinolinyl group, an isoquinolinyl group, a benzoquinolinyl group, a quinoxalinyl group, a quinazolinyl group, a naphthyridinyl group, a benzofuranyl group, a benzothiophenyl group, a triazinyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a pyridinyl group, a pyrazinyl group, a pyrimidinyl group, a triazinyl group, and —Si(Q₁)(Q₂)(Q₃),
provided that at least one selected from R₁₁ to R₁₃ and R₁₆ is selected from a phenyl group, a naphthyl group, a phenanthrenyl group, an anthracenyl group, a pyrenyl group, a chrysenyl group, a pyrrolyl group, a thiophenyl group, a furanyl group, an imidazolyl group, a thiazolyl group, an oxazolyl group, a pyridinyl group, a pyrazinyl group, a pyrimidinyl group, a quinolinyl group, an isoquinolinyl group, a benzoquinolinyl group, a quinoxalinyl group, a quinazolinyl group, a naphthyridinyl group, a benzofuranyl group, a benzothiophenyl group, a triazinyl group, a dibenzofuranyl group, and a dibenzothiophenyl group; and
a phenyl group, a naphthyl group, a phenanthrenyl group, an anthracenyl group, a pyrenyl group, a chrysenyl group, a pyrrolyl group, a thiophenyl group, a furanyl group, an imidazolyl group, a thiazolyl group, an oxazolyl group, a pyridinyl group, a pyrazinyl group, a pyrimidinyl group, a quinolinyl group, an isoquinolinyl group, a benzoquinolinyl group, a quinoxalinyl group, a quinazolinyl group, a naphthyridinyl group, a benzofuranyl group, a benzothiophenyl group, a triazinyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a pyridinyl group, a pyrazinyl group, a pyrimidinyl group, a triazinyl group, and —Si(Q₁)(Q₂)(Q₃),
wherein Q₁ to Q₃ are each independently selected from a C₁-C₂₀ alkyl group and a C₆-C₆₀ aryl group.

4. The organometallic compound of claim 1, wherein
R₁₁ to R₁₃ and R₁₆ are each independently selected from hydrogen, a methyl group, an ethyl group, an n-propyl group, an iso-propyl group, an n-butyl group, an iso-butyl group, a sec-butyl group, a tert-butyl group, a cyclopentyl group, and a cyclohexyl group;
a methyl group, an ethyl group, an n-propyl group, an iso-propyl group, an n-butyl group, an iso-butyl group, a sec-butyl group, and a tert-butyl group, each substituted with at least one selected from deuterium, —F, —Cl, —Br, —I, and a cyano group;
a cyclopentyl group and a cyclohexyl group, each substituted with at least one selected from deuterium, —F, —Cl, —Br, —I, a cyano group, a methyl group, and an ethyl group;
a phenyl group, a thiophenyl group, a furanyl group, a thiazolyl group, an oxazolyl group, a dibenzofuranyl group, and a dibenzothiophenyl group; and
a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃,
provided that at least one selected from R₁₁ to R₁₃ and R₁₆ is selected from a phenyl group, a thiophenyl group, a furanyl group, a thiazolyl group, an oxazolyl group, a dibenzofuranyl group, and a dibenzothiophenyl group; and
a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃.

5. The organometallic compound of claim 1, wherein
R₁₁ to R₁₃ are each independently selected from hydrogen, a methyl group, an ethyl group, an n-propyl group, an iso-propyl group, an n-butyl group, an iso-butyl group, a sec-butyl group, a tert-butyl group, a cyclopentyl group, and a cyclohexyl group;
a methyl group, an ethyl group, an n-propyl group, an iso-propyl group, an n-butyl group, an iso-butyl group, a sec-butyl group, and a tert-butyl group, each substituted with at least one selected from deuterium, —F, —Cl, —Br, —I, and a cyano group;
a cyclopentyl group and a cyclohexyl group, each substituted with at least one selected from deuterium, —F, —Cl, —Br, —I, a cyano group, a methyl group, and an ethyl group;
a phenyl group, a thiophenyl group, a furanyl group, a thiazolyl group, an oxazolyl group, a dibenzofuranyl group, and a dibenzothiophenyl group; and
a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃, and
R₁₆ is selected from a phenyl group, a thiophenyl group, a furanyl group, a thiazolyl group, an oxazolyl group, a dibenzofuranyl group, and a dibenzothiophenyl group; and
a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃.

6. The organometallic compound of claim 1, wherein
R₁₁, R₁₃, and R₁₆ are each independently selected from hydrogen, a methyl group, an ethyl group, an n-propyl group, an iso-propyl group, an n-butyl group, an iso-butyl group, a sec-butyl group, a tert-butyl group, a cyclopentyl group, and a cyclohexyl group;
a methyl group, an ethyl group, an n-propyl group, an iso-propyl group, an n-butyl group, an iso-butyl group, a sec-butyl group, and a tert-butyl group, each substituted with at least one selected from deuterium, —F, —Cl, —Br, —I, and a cyano group;
a cyclopentyl group and a cyclohexyl group, each substituted with at least one selected from deuterium, —F, —Cl, —Br, —I, a cyano group, a methyl group, and an ethyl group;
a phenyl group, a thiophenyl group, a furanyl group, a thiazolyl group, an oxazolyl group, a dibenzofuranyl group, and a dibenzothiophenyl group; and
a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃, and
R₁₂ is selected from a phenyl group, a thiophenyl group, a furanyl group, a thiazolyl group, an oxazolyl group, a dibenzofuranyl group, and a dibenzothiophenyl group; and
a phenyl group, a thiophenyl group, a furanyl group, a thiazolyl group, an oxazolyl group, a dibenzofuranyl group, and a dibenzothiophenyl group, each substituted with at least one selected from deuterium, —F, —Cl, —Br, —I, —CD₃, —CD₂H, —CDH₂, —CF₃, —CF₂H, —CFH₂, a cyano group, a methyl group, an ethyl group, an n-propyl group, an iso-propyl group, an n-butyl group, an iso-butyl group, a sec-butyl group, a tert-butyl group, a methoxy group, an ethoxy group, an n-propoxy group, an iso-propoxy group, an n-butoxy group, a tert-butoxy group, a phenyl group, and —Si(CH₃)₃.

7. The organometallic compound of claim 1, wherein
R₁₄ and R₁₅ are each independently selected from hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a neo-pentyl group, a cyclopentyl group, a cyclohexyl group, a cycloheptyl group, a phenyl group, a naphthyl group, a phenanthrenyl group, an anthracenyl group, a pyrenyl group, and a chrysenyl group;
a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, and a neo-pentyl group, each substituted with at least one selected from deuterium, —F, —Cl, —Br, and —I; and
a cyclopentyl group, a cyclohexyl group, a cycloheptyl group, a phenyl group, a naphthyl group, a phenanthrenyl group, an anthracenyl group, a pyrenyl group, and a chrysenyl group, each substituted with at least one selected from deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, and a neo-pentyl group.

8. The organometallic compound of claim 1, wherein
R₁₄ and R₁₅ are each independently selected from hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, a cyclopentyl group, a cyclohexyl group, a phenyl group, and a naphthyl group; and
a methyl group, an ethyl group, an n-propyl group, an iso-propyl group, an n-butyl group, an iso-butyl group, a sec-butyl group, and a tert-butyl group, each substituted with at least one selected from deuterium and —F.

9. The organometallic compound of claim 1, wherein R₁₄ and R₁₅ are each independently selected from hydrogen, deuterium, —F, a cyano group, a methyl group, an ethyl group, an n-propyl group, an iso-propyl group, an n-butyl group, an iso-butyl group, a sec-butyl group, a tert-butyl group, —CD₃, —CD₂H, —CDH₂, —CF₃, —CF₂H, —CFH₂, and a phenyl group.

10. The organometallic compound of claim 1, wherein n is 2.

11. The organometallic compound of claim 1, wherein L₁₁ is a ligand represented by one of Formulae 2-1 to 2-12: 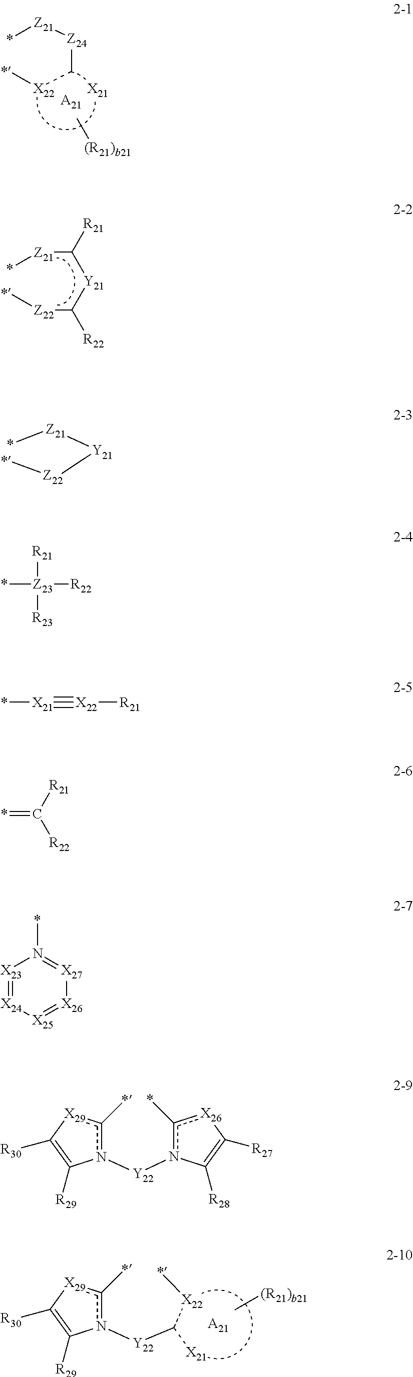 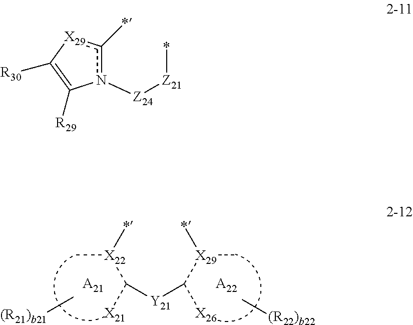
wherein, in Formulae 2-1 to 2-12,
A₂₁ and A₂₂ are each independently selected from a C₅-C₂₀ carbocyclic group and a C₁-C₂₀ heterocyclic group,
X₂₁, X₂₂, X₂₈, and X₂₉ are each independently selected from C and N,
X₂₃ is N or C(Q₂₃), X₂₄ is N or C(Q₂₄), X₂₅ is N or C(Q₂₅), X₂₆ is N or C(Q₂₆), X₂₇ is N or C(Q₂₇),
X₂₈ is O, S, or N(Q₂₈), X₂₉ is O, S, or N(Q₂₉), Y₂₁ and Y₂₂ are each independently selected from a single bond, a double bond, a substituted or unsubstituted C₁-C₅ alkylene group, a substituted or unsubstituted C₂-C₅ alkenylene group, and a substituted or unsubstituted C₆-C₁₀ arylene group, Z₂₁ and Z₂₂ are each independently selected from N, O, N(R₂₅), P(R₂₅)(R₂₆), and As(R₂₅)(R₂₆),
Z₂₃ is selected from phosphorus (P) and arsenic (As),
Z₂₄ is selected from CO and CH₂,
R₂₁ to R₃₀ and Q₂₃ to Q₂₉ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, R₂₁ and R₂₂ are optionally bound to form a ring, R₂₇ and R₂₈ are optionally bound to form a ring, R₂₈ and R₂₉ are optionally bound to form a ring, R₂₉ and R₃₀ are optionally bound to form a ring,
b21 and b22 are each independently selected from 1, 2, and 3, and
* and *′ each independently indicate a binding site to an adjacent atom.

12. The organometallic compound of claim 1, wherein L₁₁ is a ligand represented by one of Formulae 3-1 to 3-25: 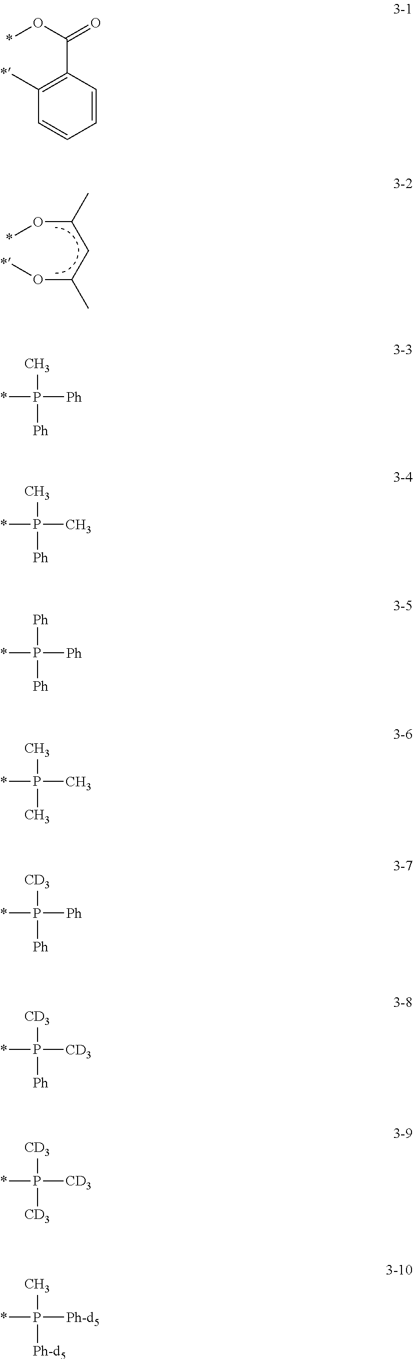 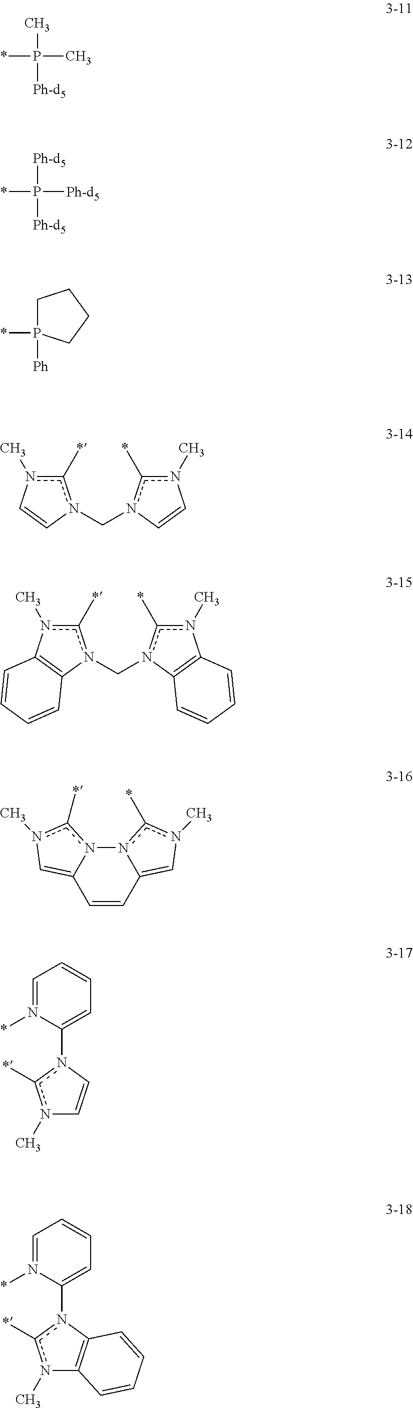 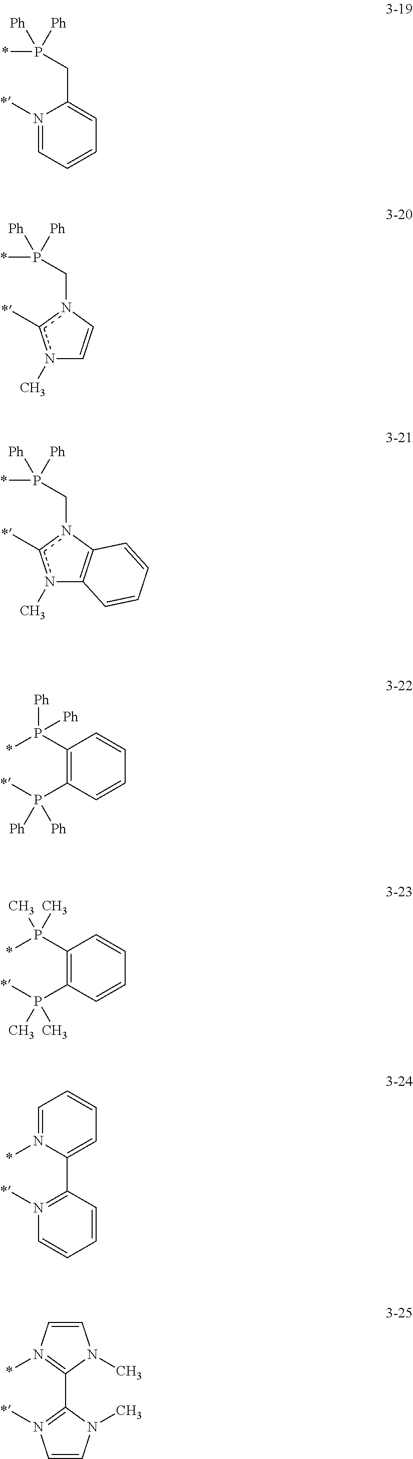
wherein, in Formulae 3-1 to 3-25,
“Ph” represents a phenyl group,
“Ph-d₅” represents a phenyl group of which all hydrogen atoms are substituted with deuterium atoms, and
* and *′ each indicate a binding site to an adjacent atom.

13. The organometallic compound of claim 1, wherein m is selected from 1 and 2.

14. The organometallic compound of claim 1, wherein n is 2 and m is 2, or n is 2 and m is 1.

15. The organometallic compound of claim 1, wherein
M is selected from Os and Ru,
R₁₁ to R₁₃ are each independently selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted divalent non-aromatic condensed polycyclic group, and a substituted or unsubstituted divalent non-aromatic condensed heteropolycyclic group,
R₁₆ is selected from a substituted or unsubstituted C₆-C₆₀ aryl group, a substituted or unsubstituted C₁-C₆₀ heteroaryl group, a substituted or unsubstituted divalent non-aromatic condensed polycyclic group, and a substituted or unsubstituted divalent non-aromatic condensed heteropolycyclic group,
R₁₄ and R₁₅ are each independently selected from hydrogen, deuterium, —F, —Cl, —Br, —I, a cyano group, a substituted or unsubstituted C₁-C₆₀ alkyl group, a substituted or unsubstituted C₃-C₁₀ cycloalkyl group, and a substituted or unsubstituted C₆-C₆₀ aryl group,
n is selected from 1, 2, and 3,
L₁₁ is selected from a monodentate ligand and a bidentate ligand, and
m is selected from 0, 1, 2, 3, and 4.

16. The organometallic compound of claim 1, wherein the organometallic compound represented by Formula 1 is represented by one of Formulae 1-1 to 1-9: 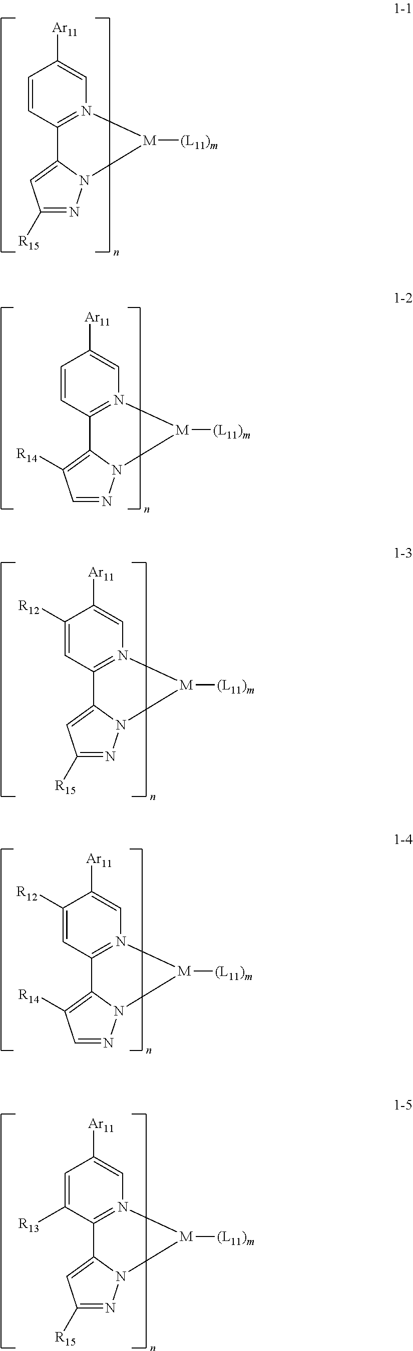 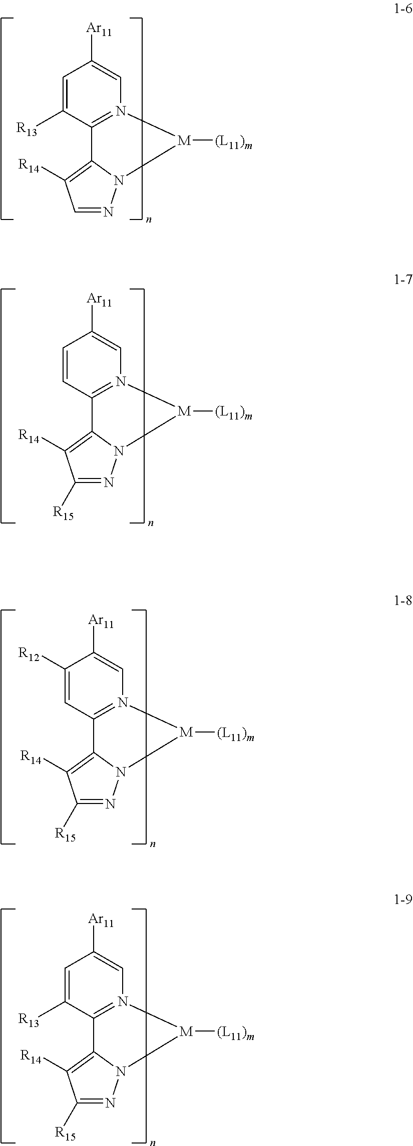
wherein, in Formulae 1-1 to 1-9,
M, R₁₂ to R₁₅, n, L₁₁, and m are the same as those defined above in connection with Formula 1, and
Ar₁₁ is selected from a substituted or unsubstituted C₆-C₆₀ aryl group, a substituted or unsubstituted C₁-C₆₀ heteroaryl group, a substituted or unsubstituted divalent non-aromatic condensed polycyclic group, and a substituted or unsubstituted divalent non-aromatic condensed heteropolycyclic group,
provided that each of R₁₂ to R₁₅ is not hydrogen.

17. The organometallic compound of claim 1, wherein the organometallic compound represented by Formula 1 is represented by one of Formulae 1-11 to 1-19 and 1-21 to 1-29: 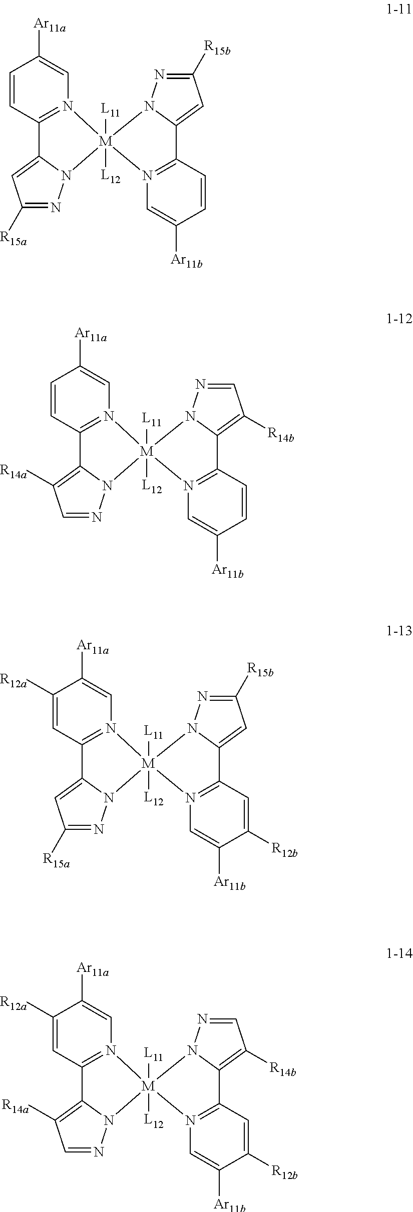 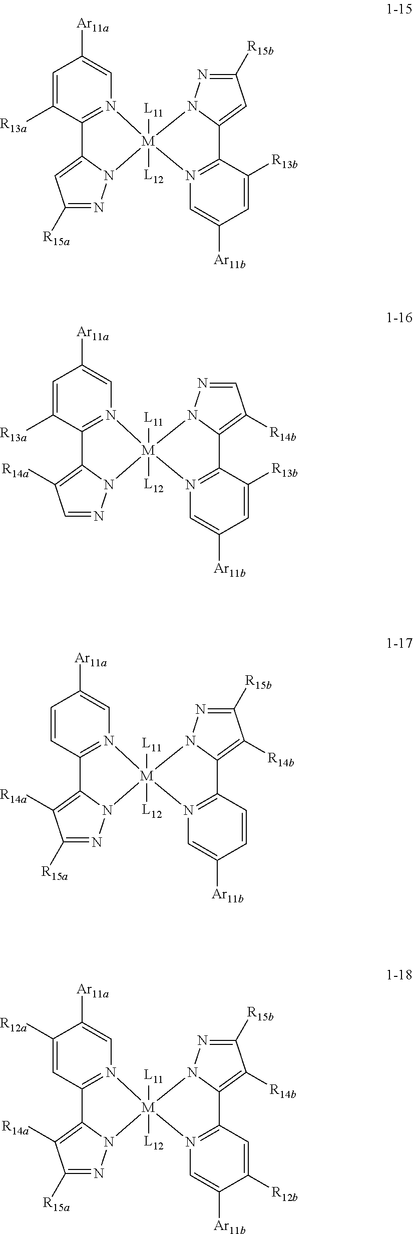 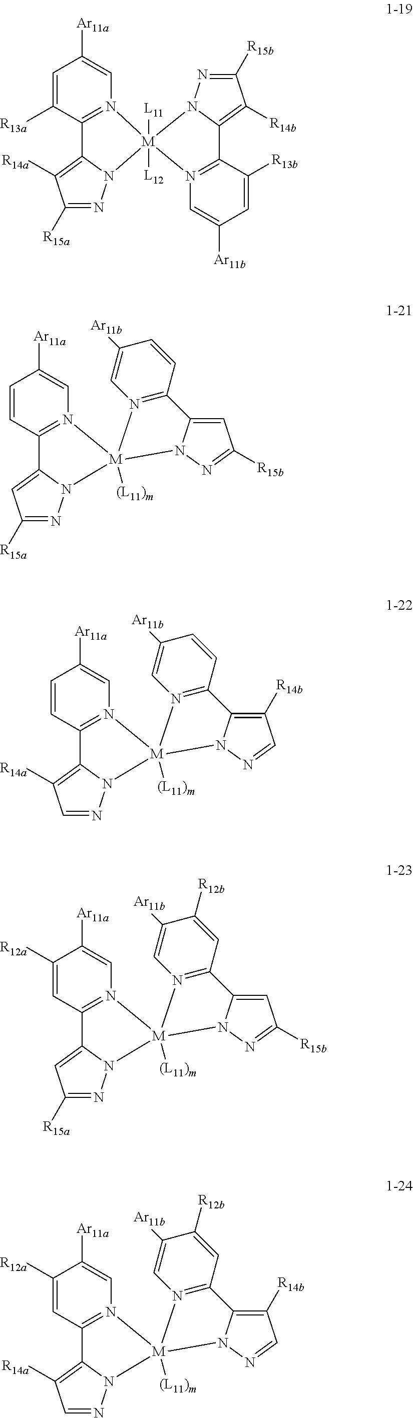 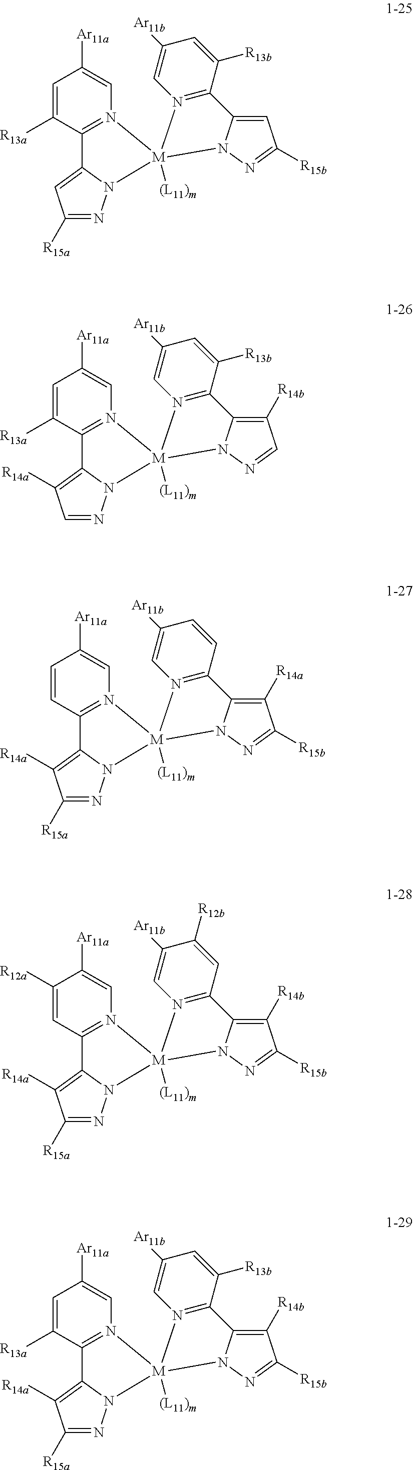
wherein, in Formulae 1-11 to 1-19 and 1-21 to 1-29,
L₁₁ and m are the same as those defined above in connection with Formula 1,
Ar₁₁ₐ and Ar_{11b} are each independently selected from a substituted or unsubstituted C₆-C₆₀ aryl group, a substituted or unsubstituted C₁-C₆₀ heteroaryl group, a substituted or unsubstituted divalent non-aromatic condensed polycyclic group, and a substituted or unsubstituted divalent non-aromatic condensed heteropolycyclic group,
R₁₂ₐ and R_{12b} are each independently the same as those defined in Formula 1 in connection with R₁₂,
R₁₃ₐ and R_{13b} are each independently the same as those defined in Formula 1 in connection with R₁₃,
R₁₄ₐ and R_{14b} are each independently the same as those defined in Formula 1 in connection with R₁₄,
R₁₅ₐ and R_{15b} are each independently the same as those defined in Formula 1 in connection with R₁₅, and
L₁₂ is the same as L₁₁ defined in Formula 1,
provided that each of R₁₂ to R₁₅ is not hydrogen.

18. The organometallic compound of claim 1, wherein the organometallic compound represented by Formula 1 is selected from Compounds 1 to 176:

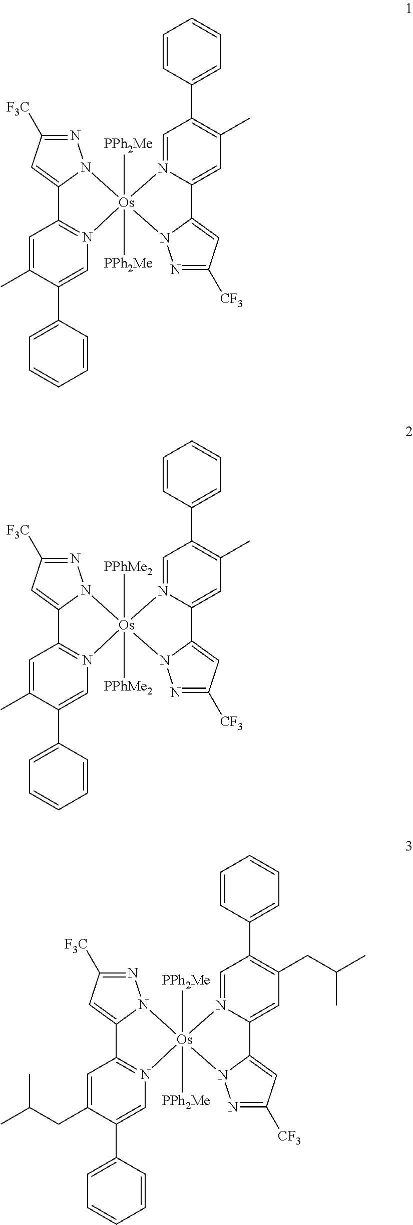

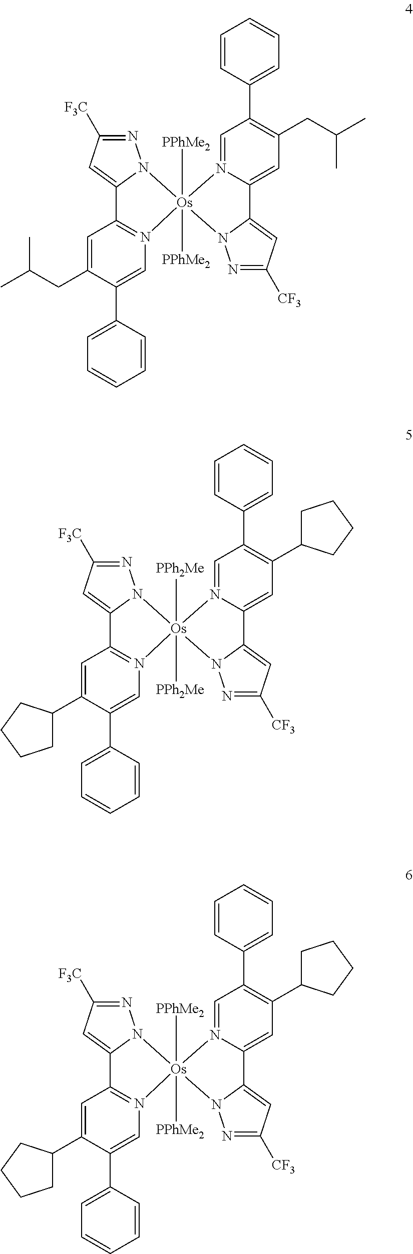

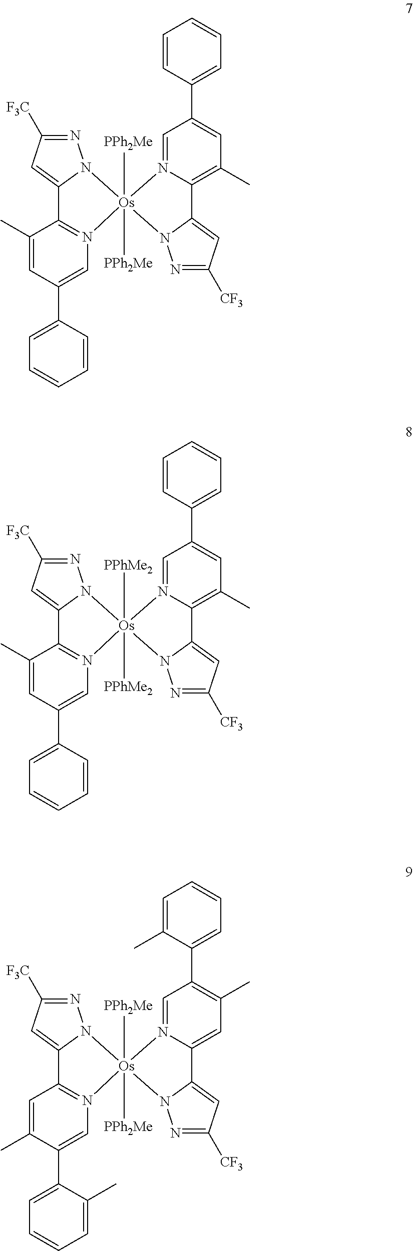

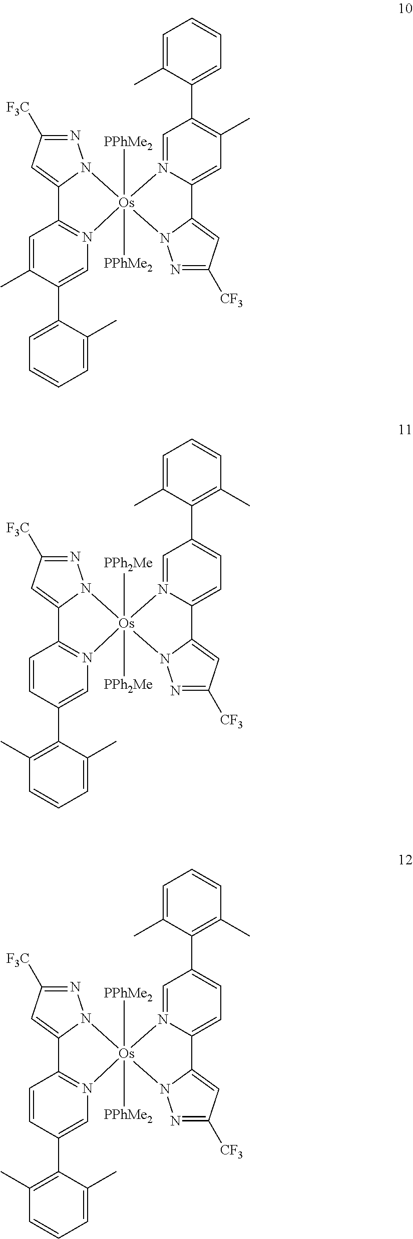

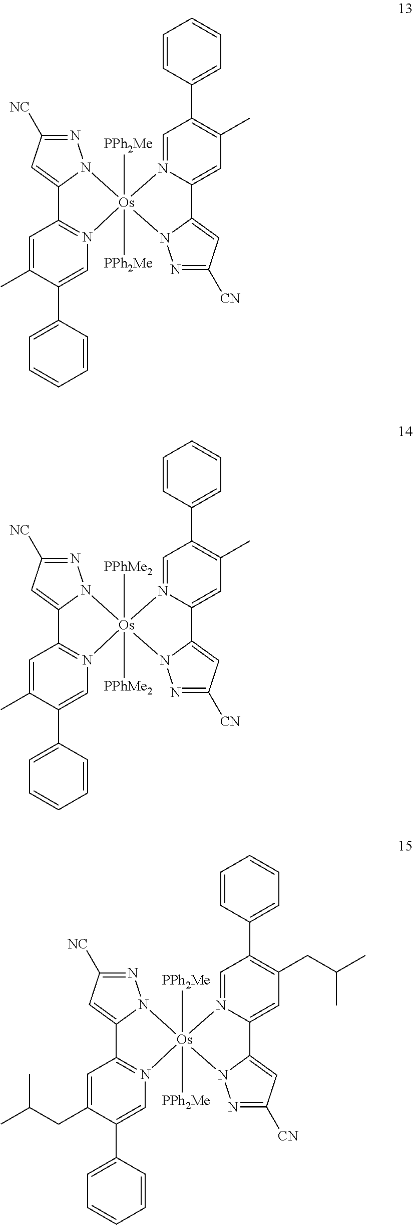

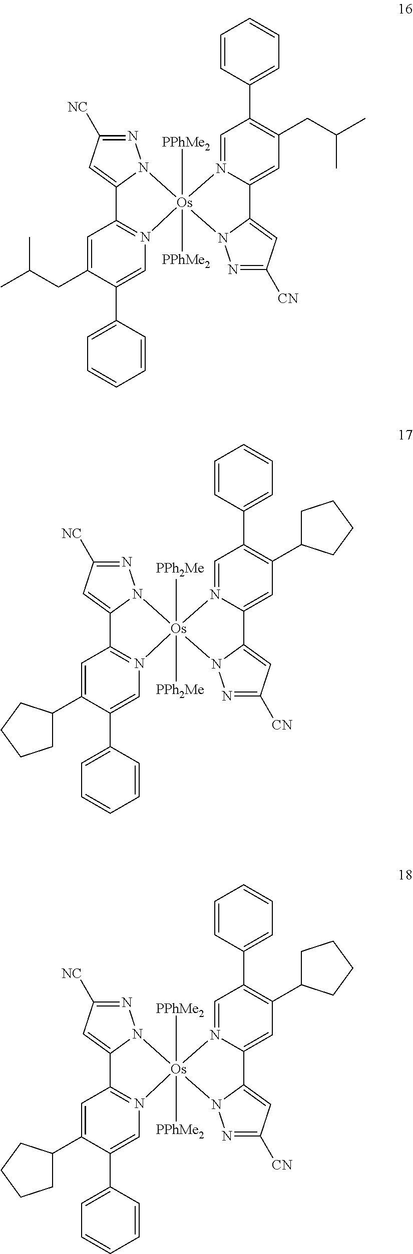

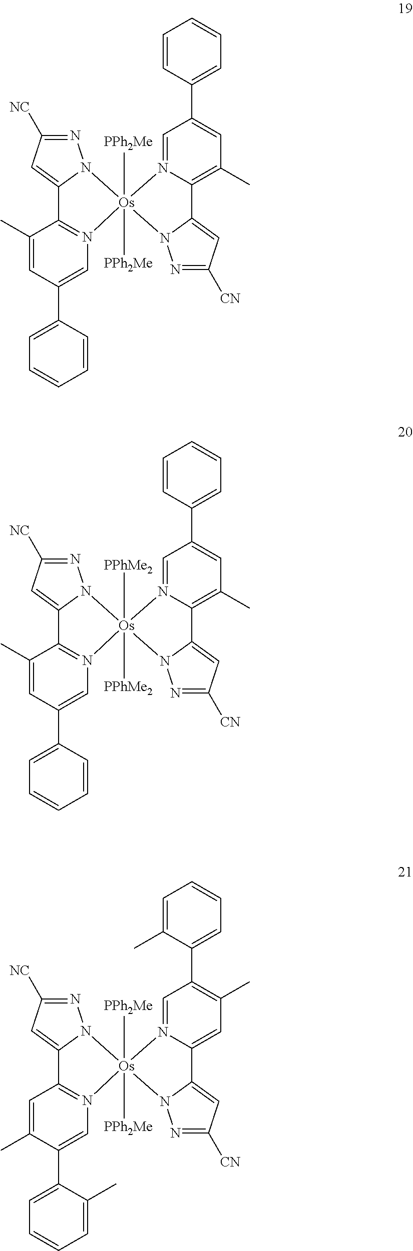

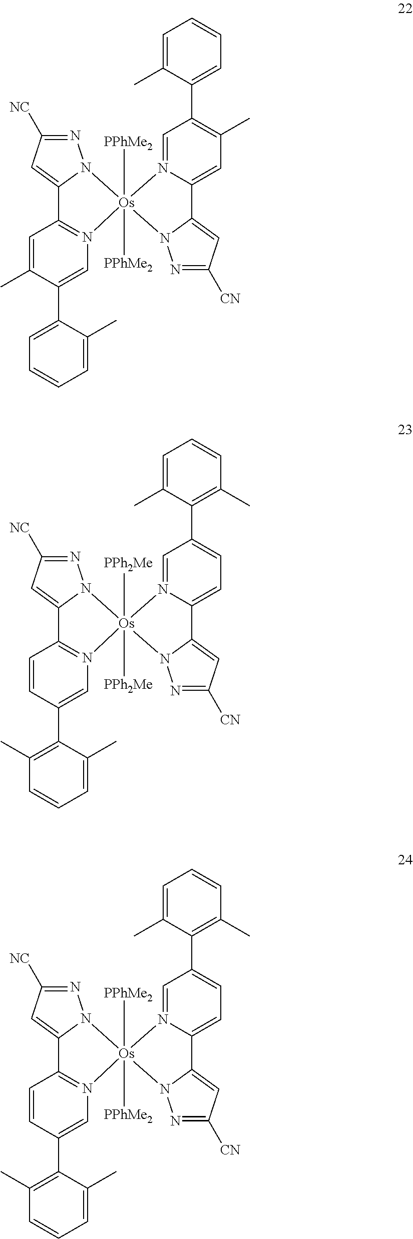

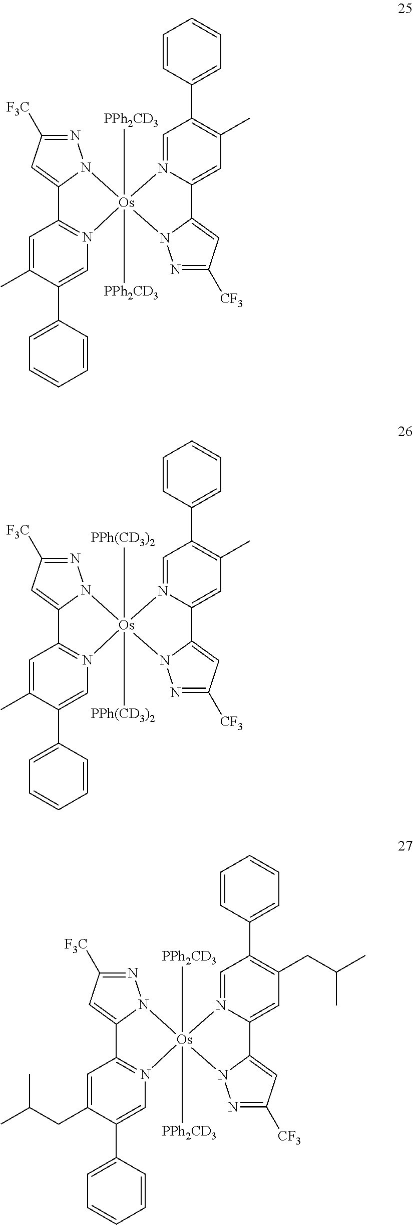

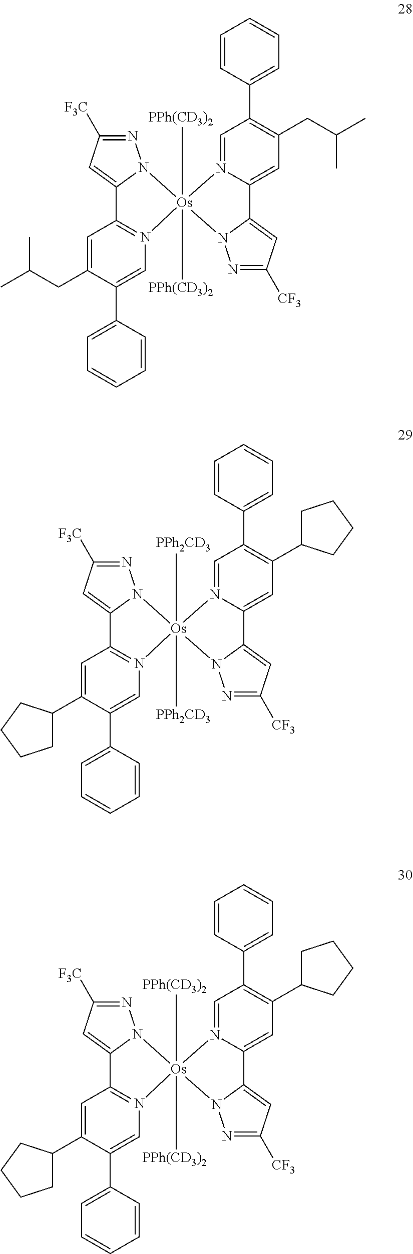

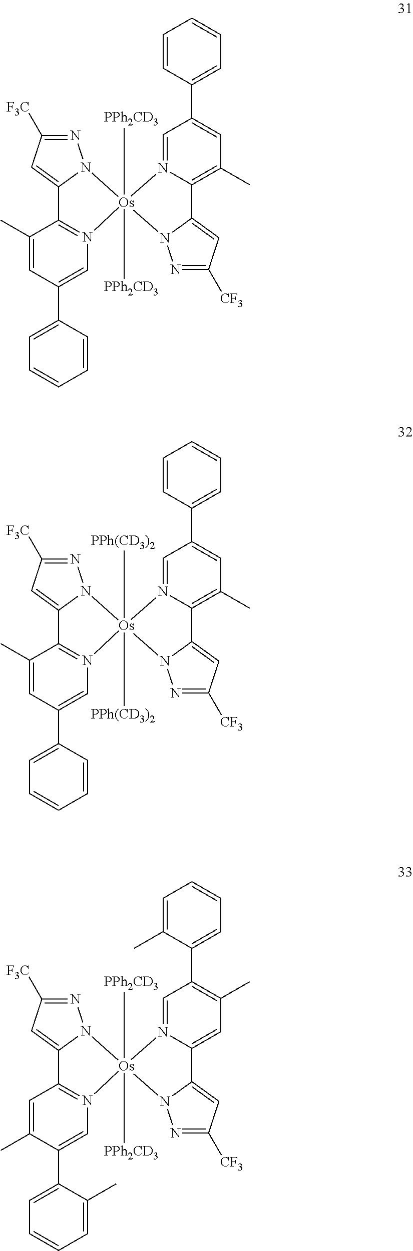

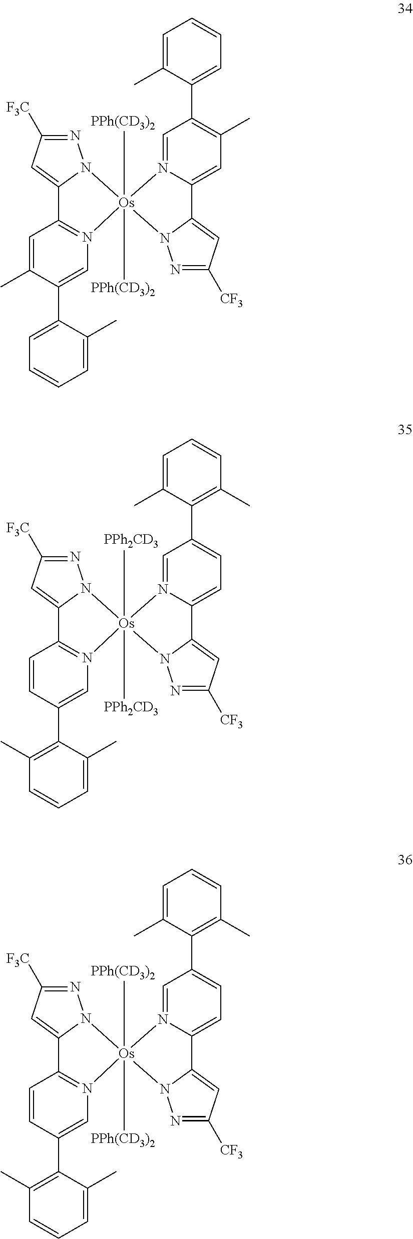

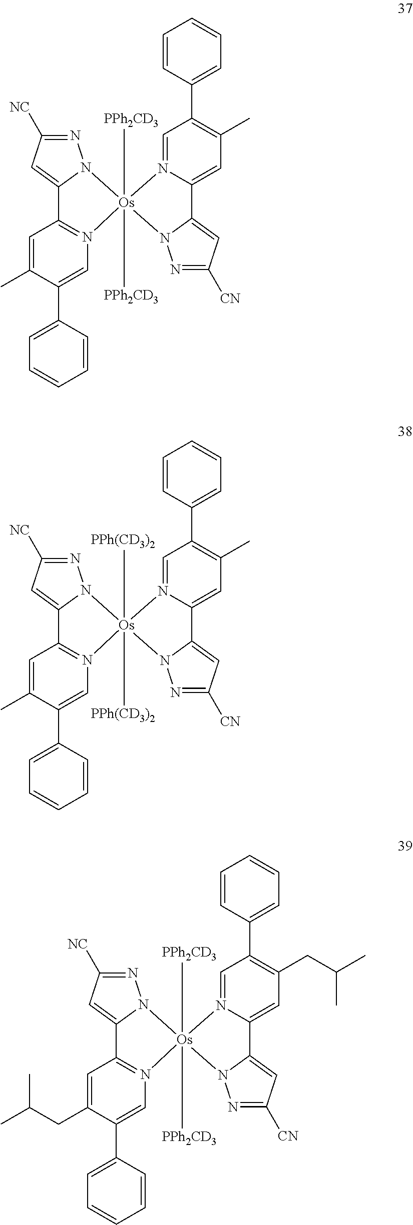

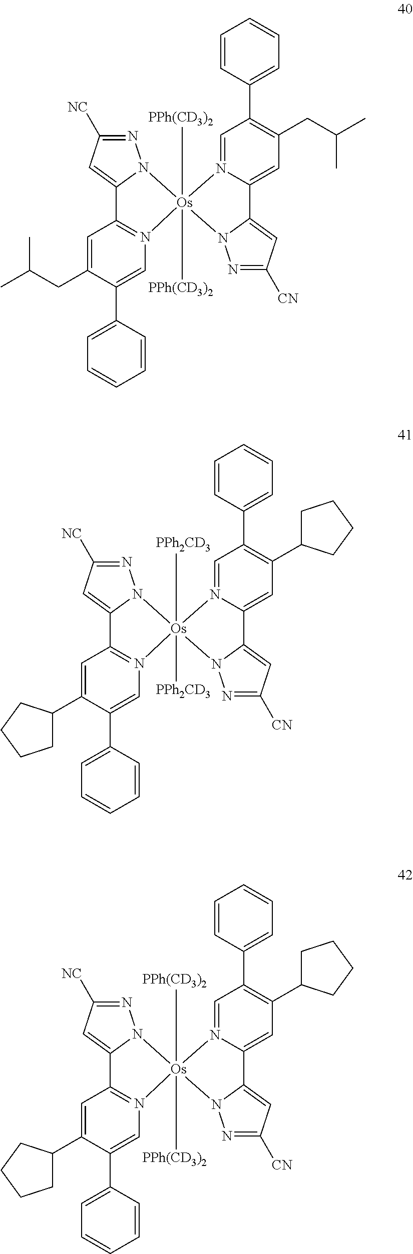

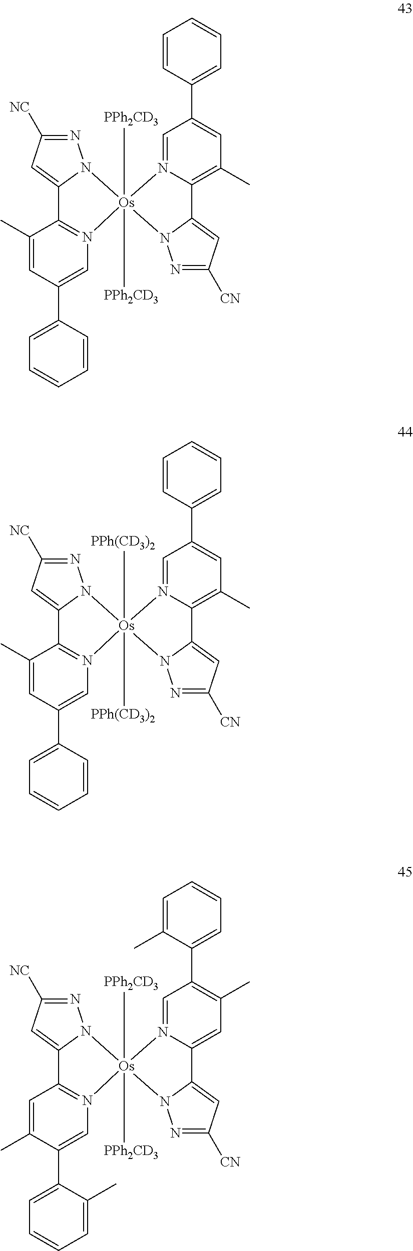

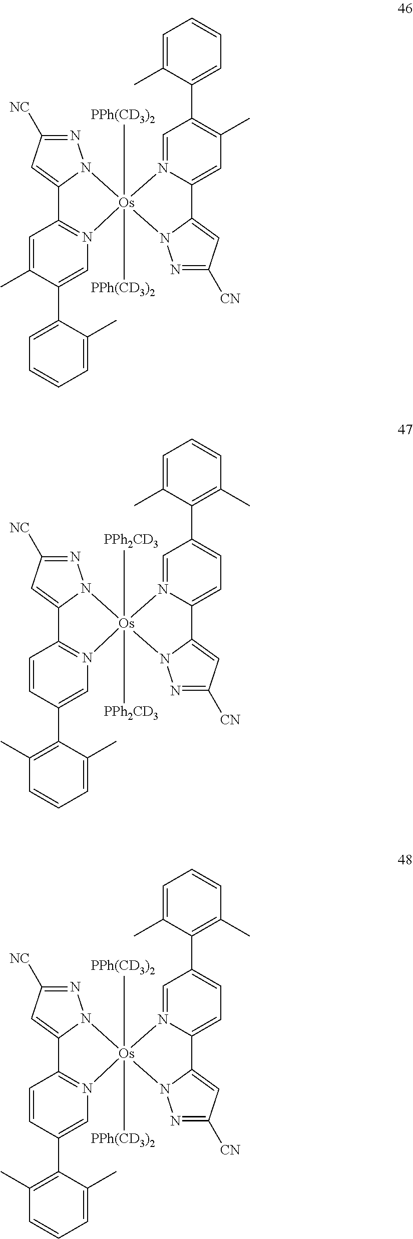

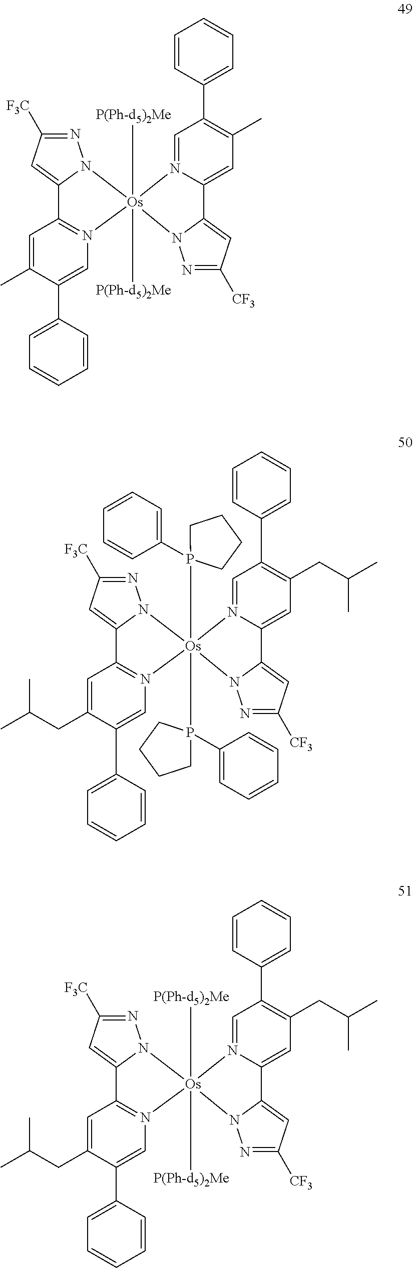

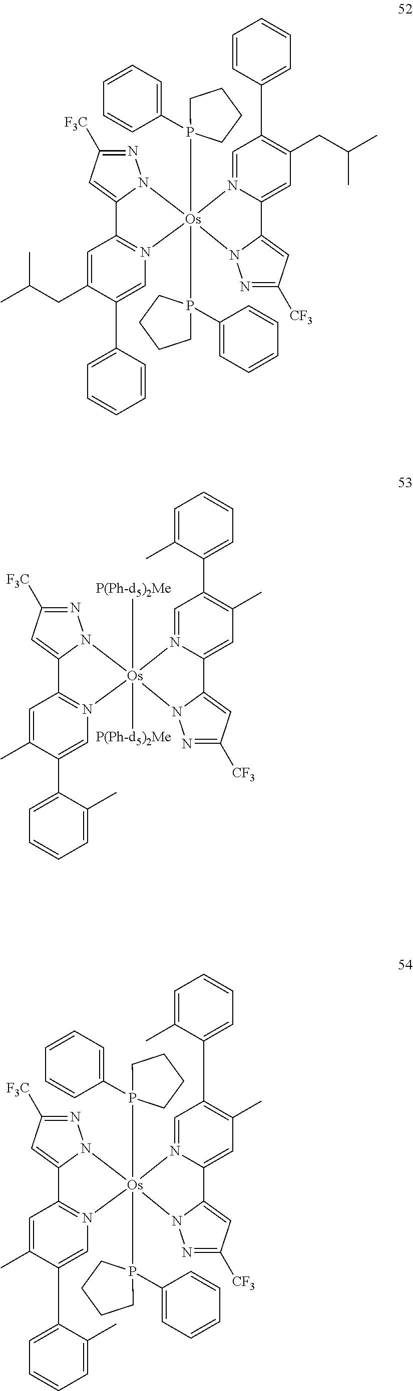

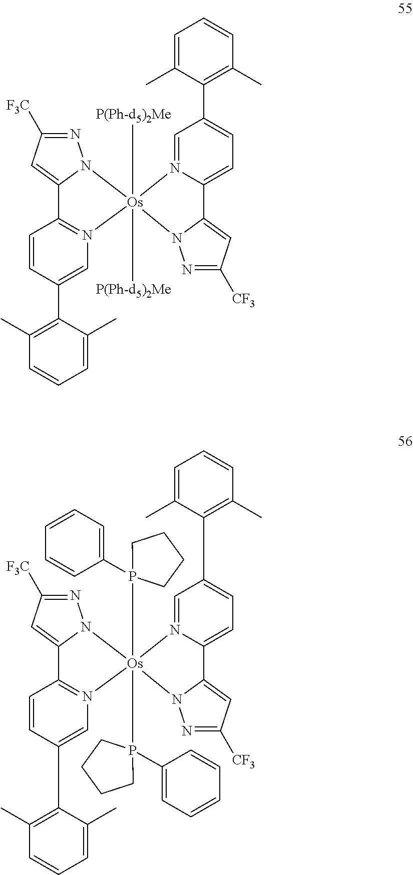

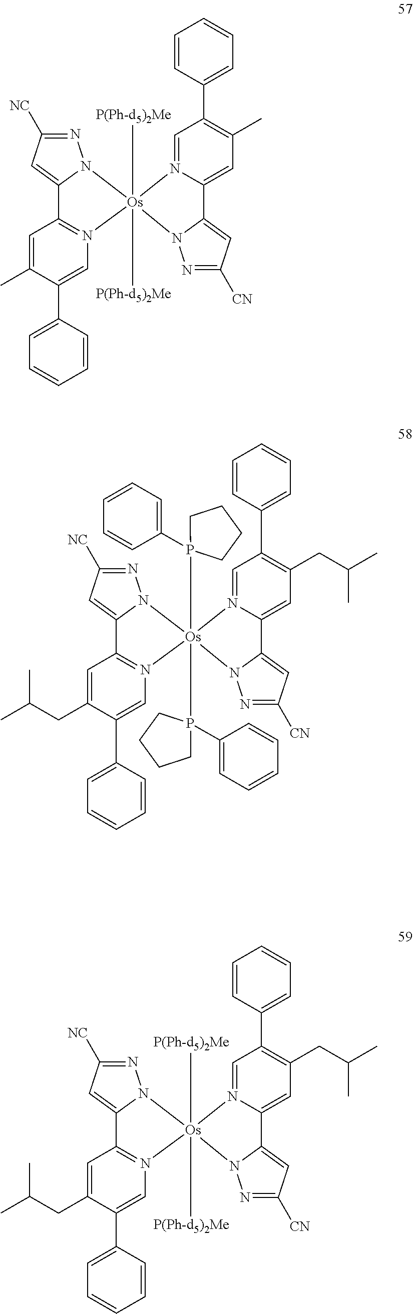

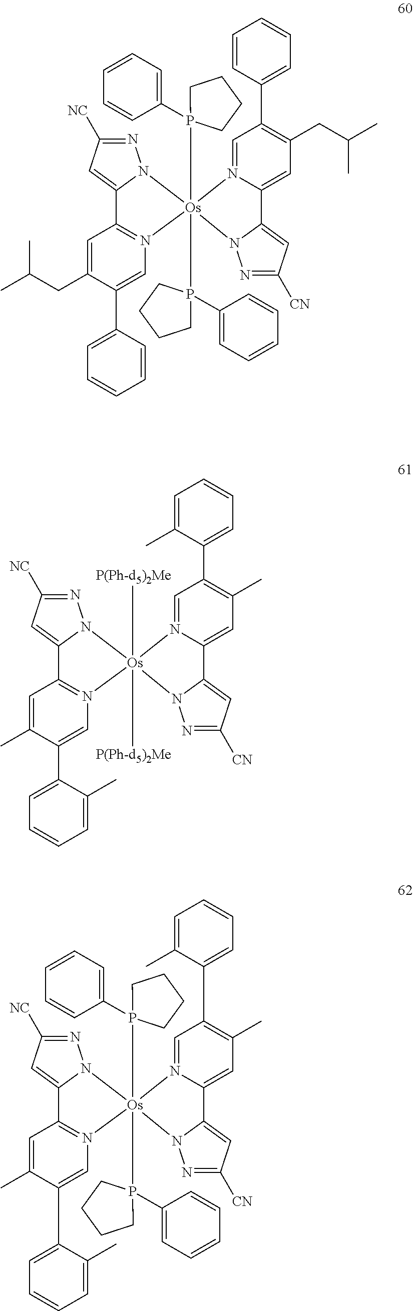

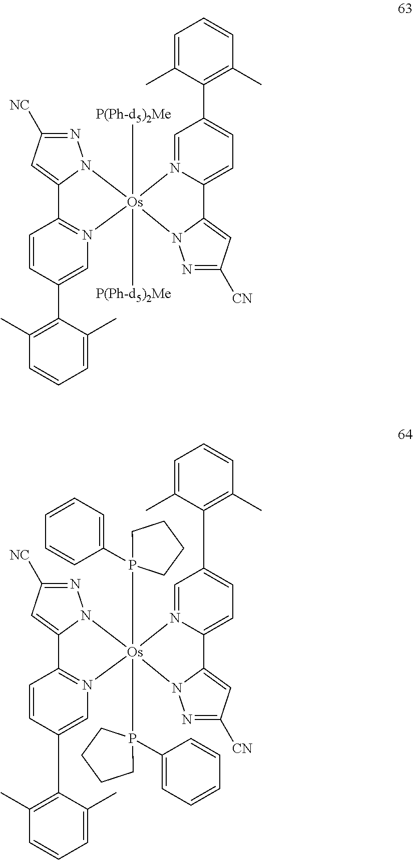

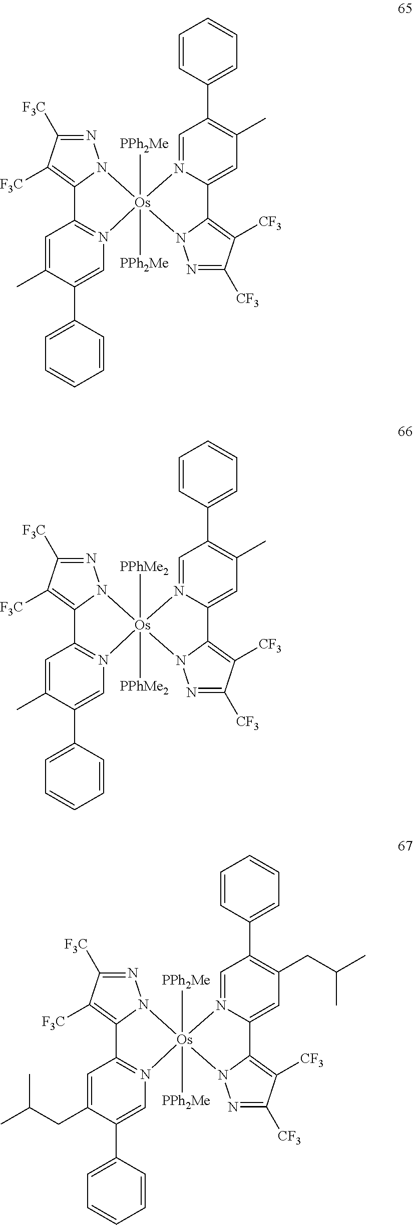

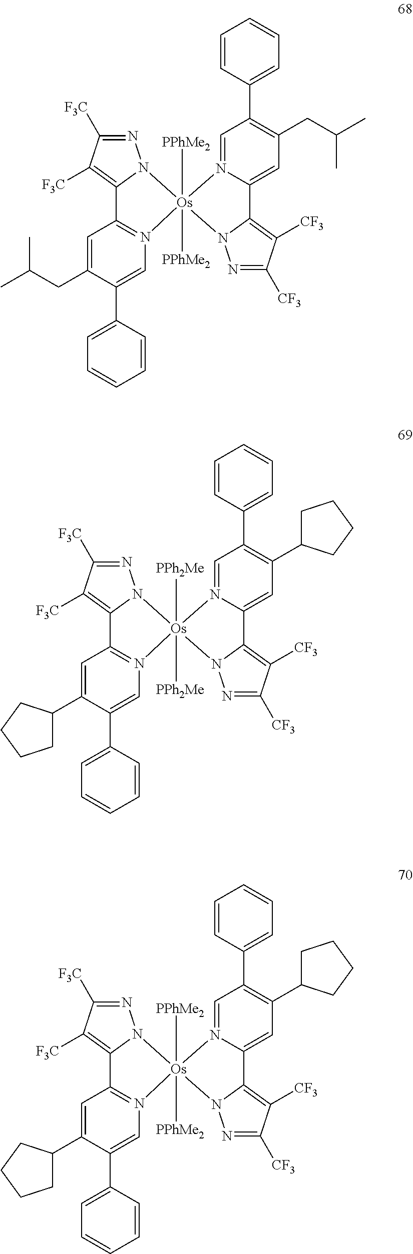

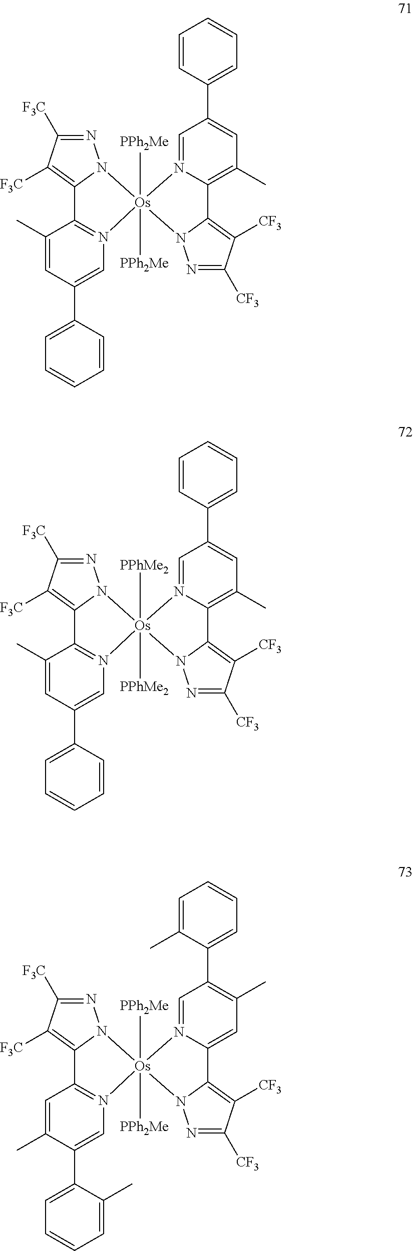

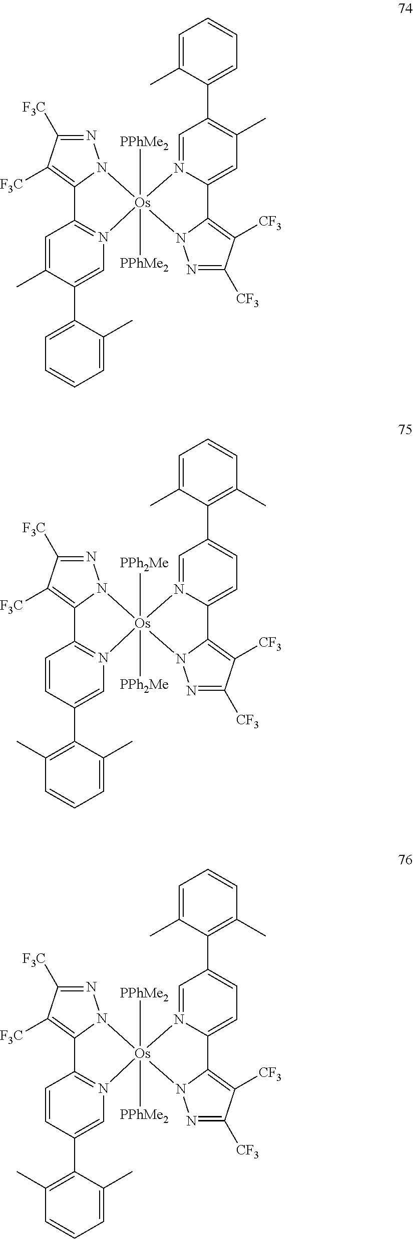

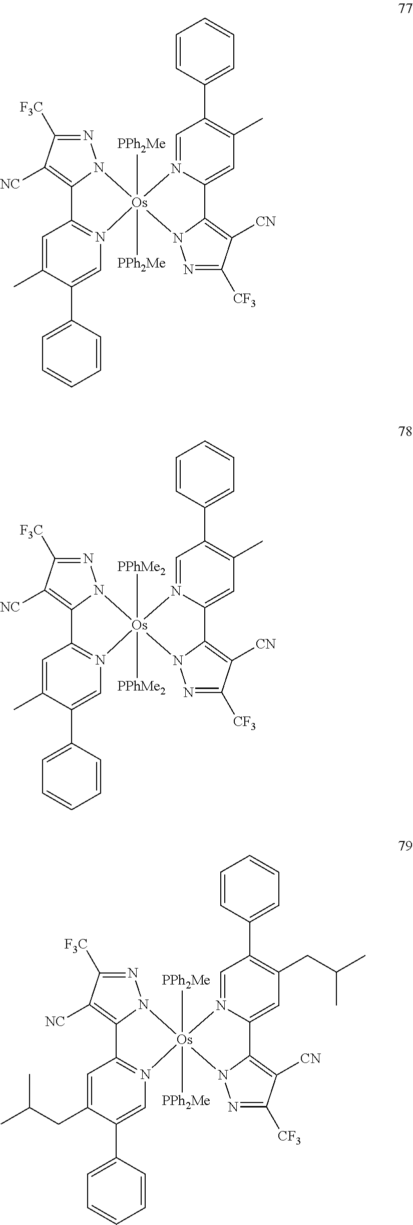

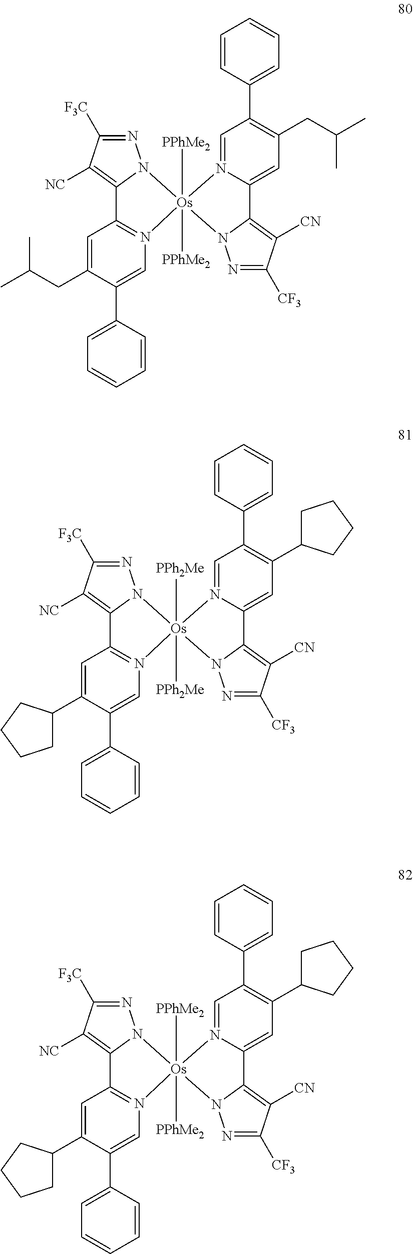

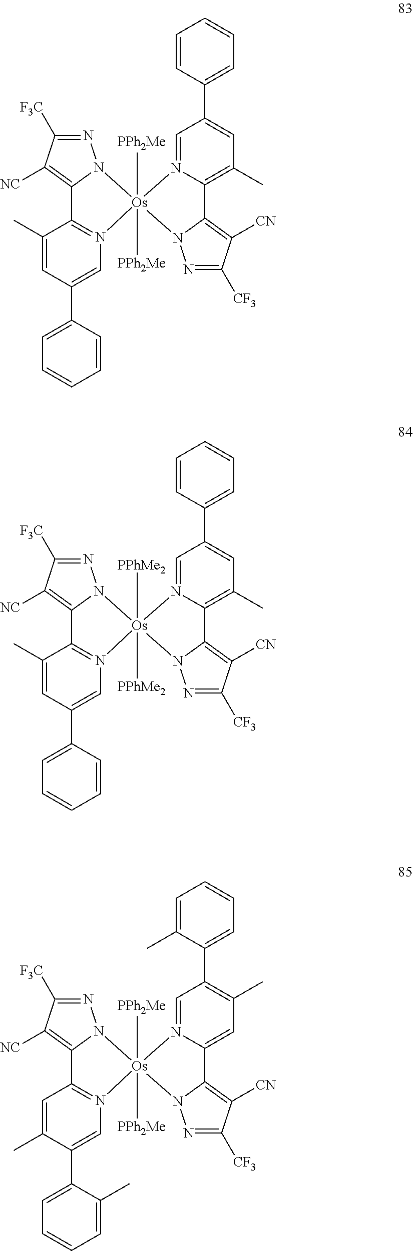

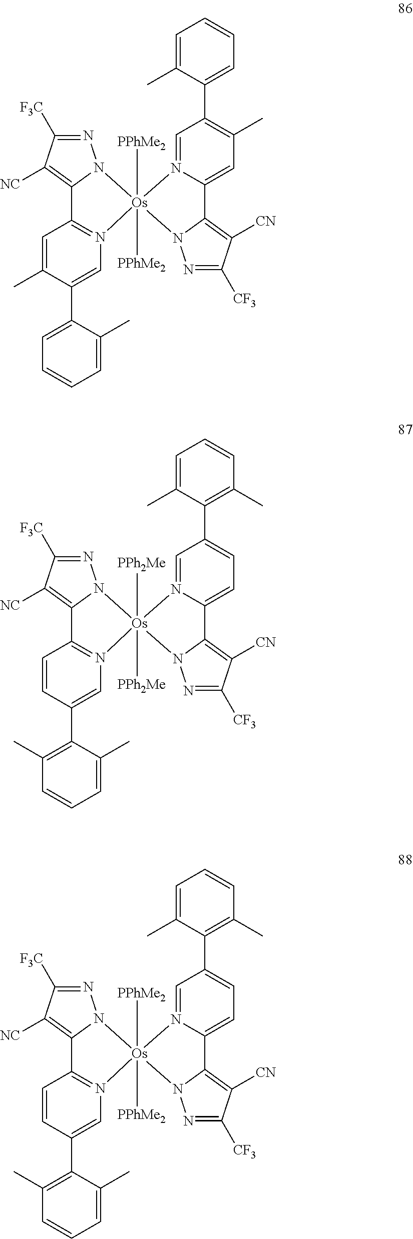

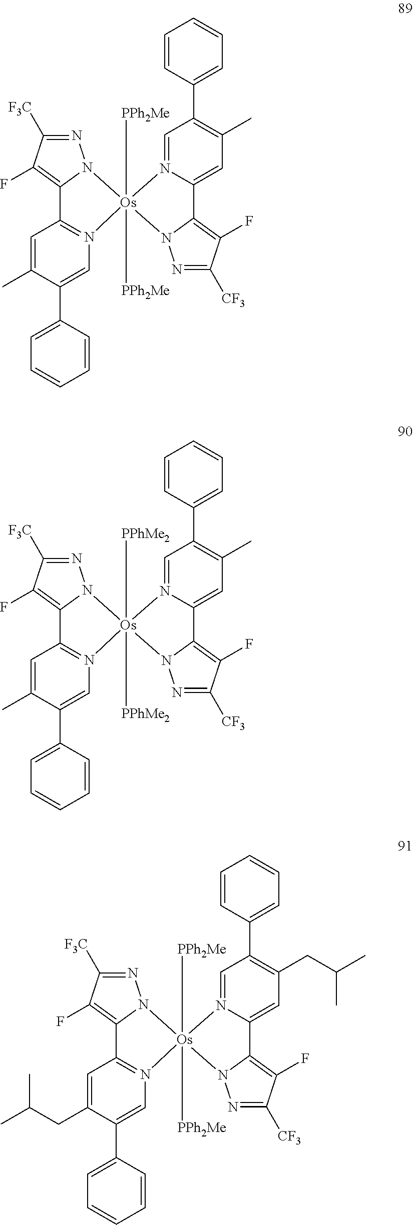

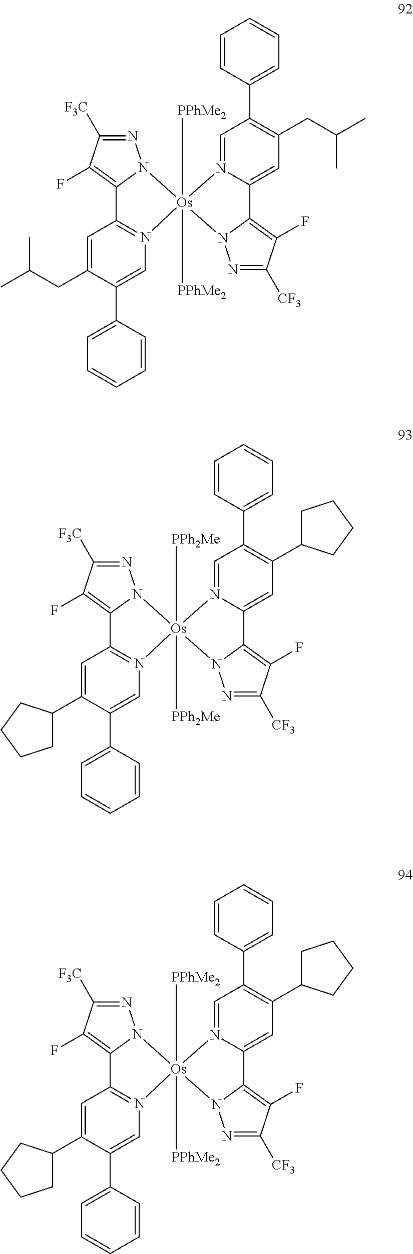

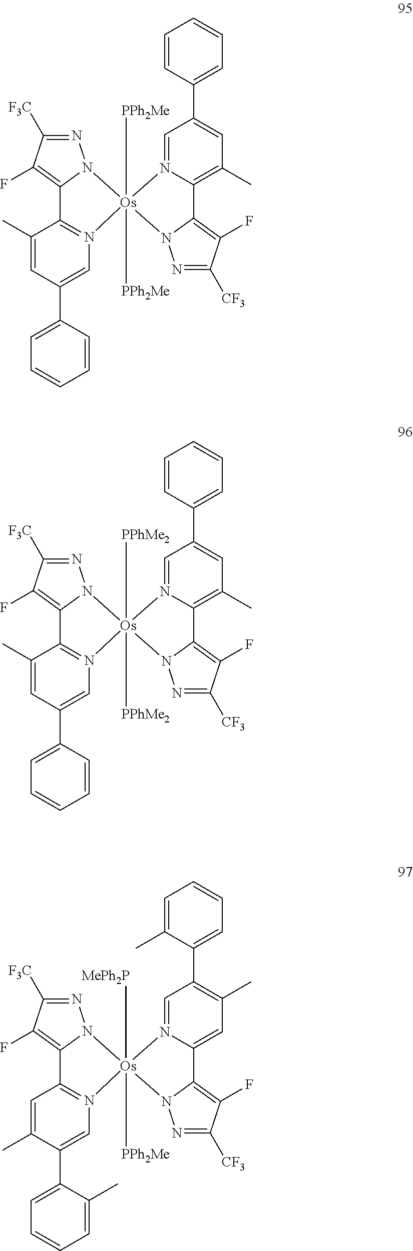

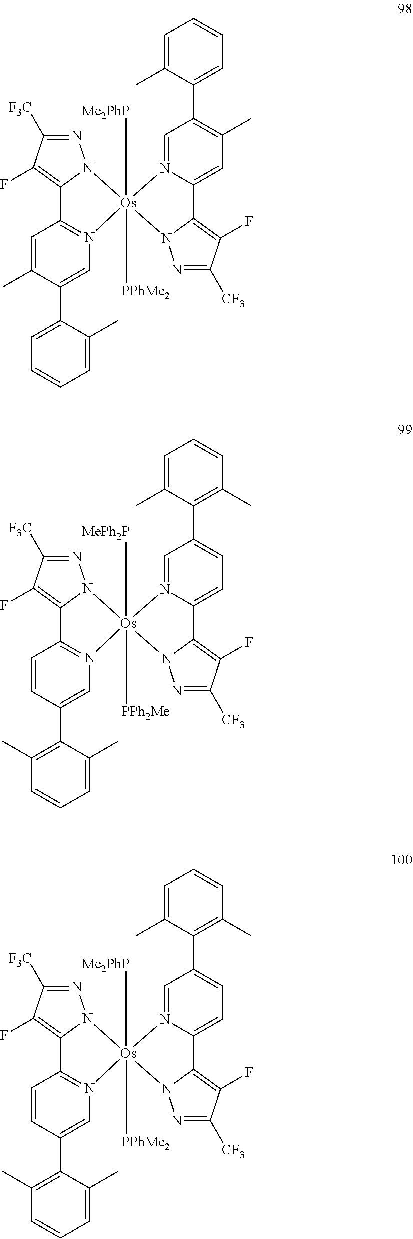

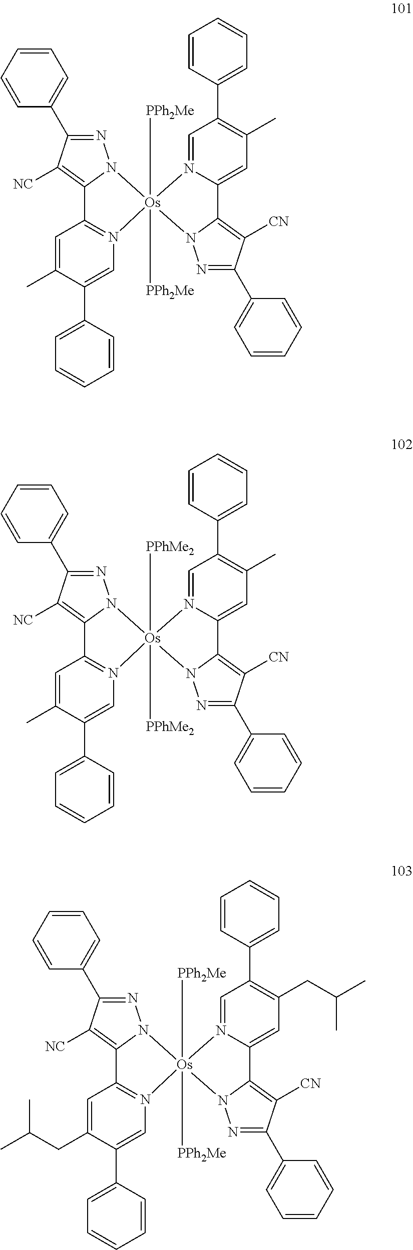

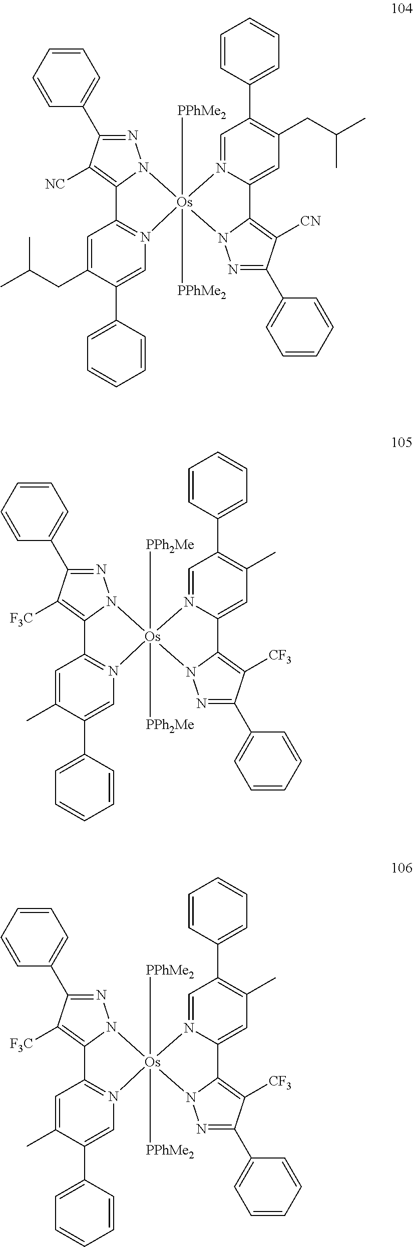

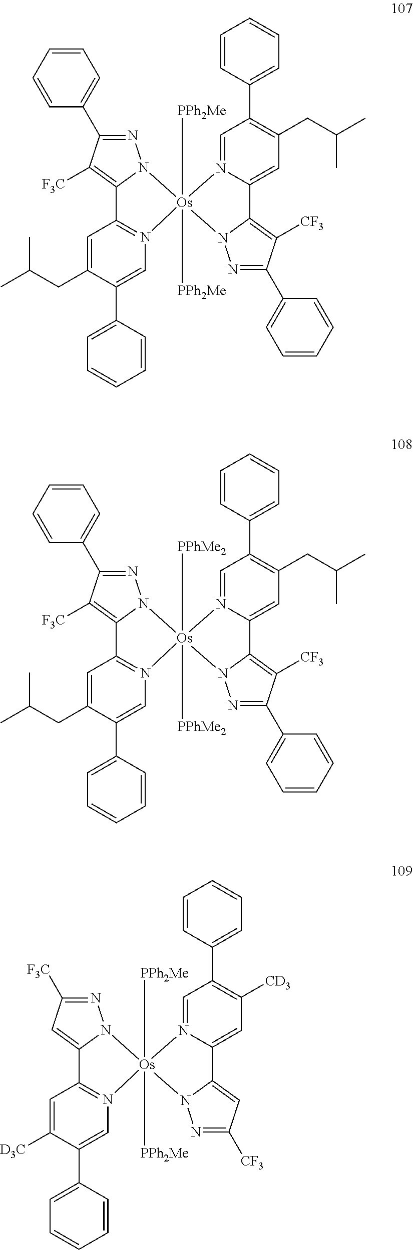

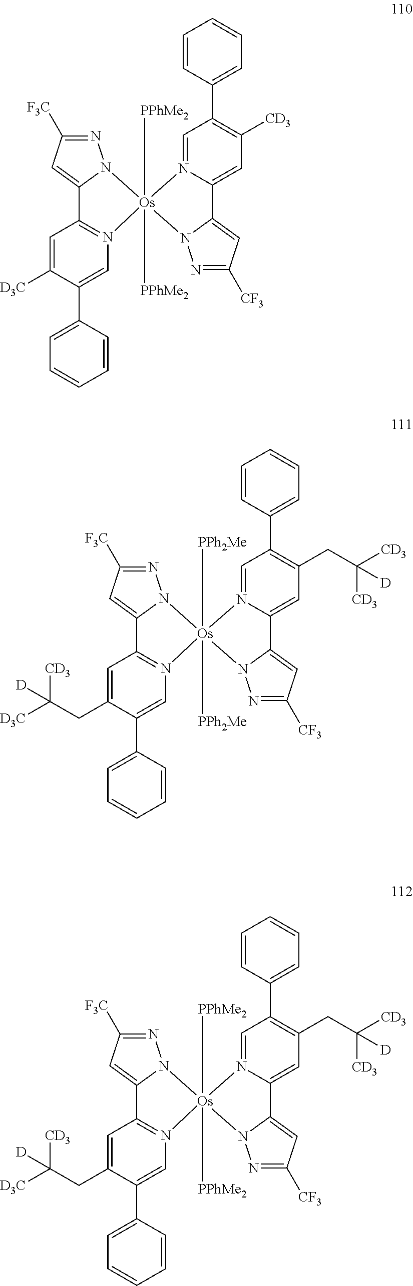

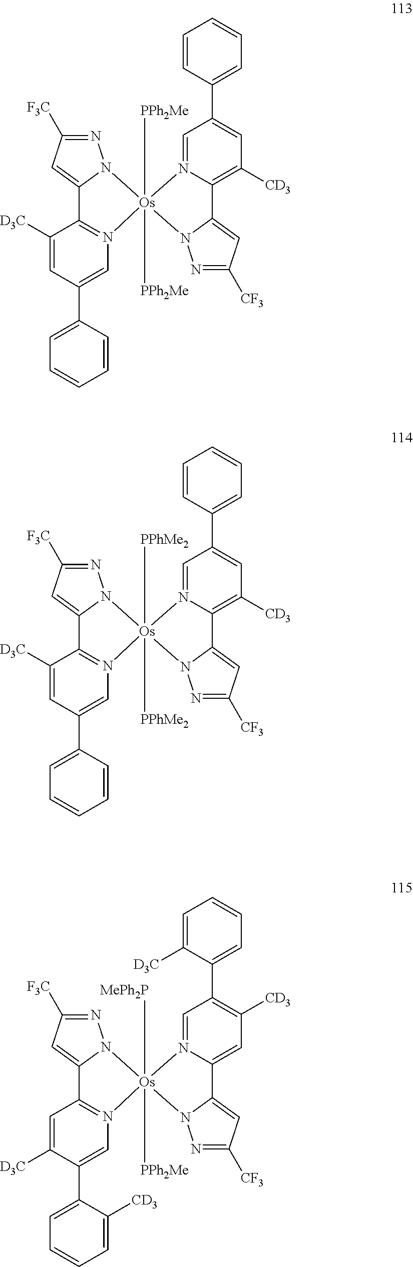

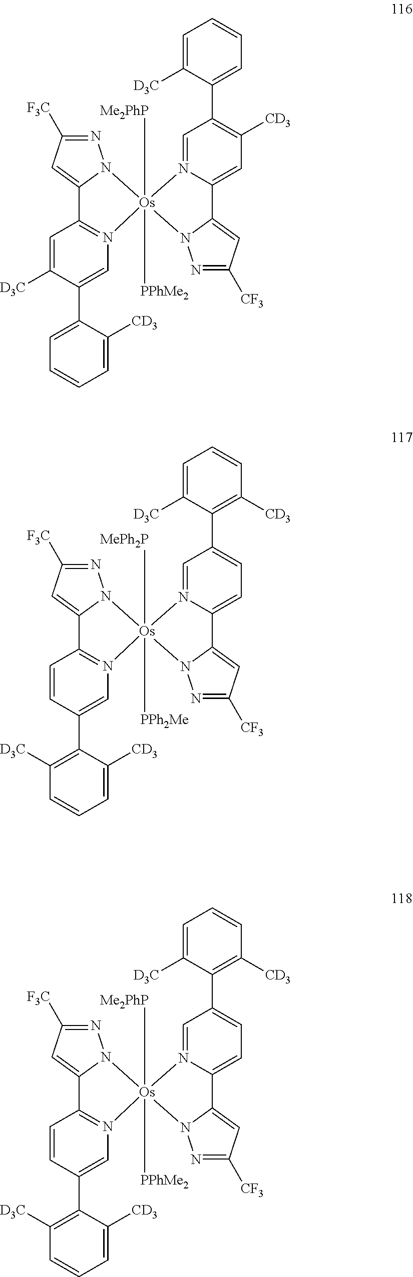

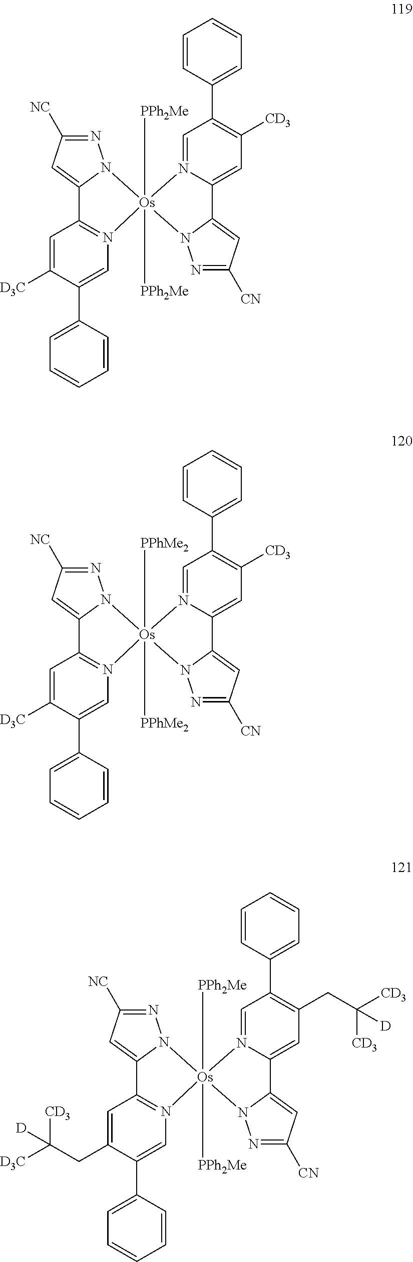

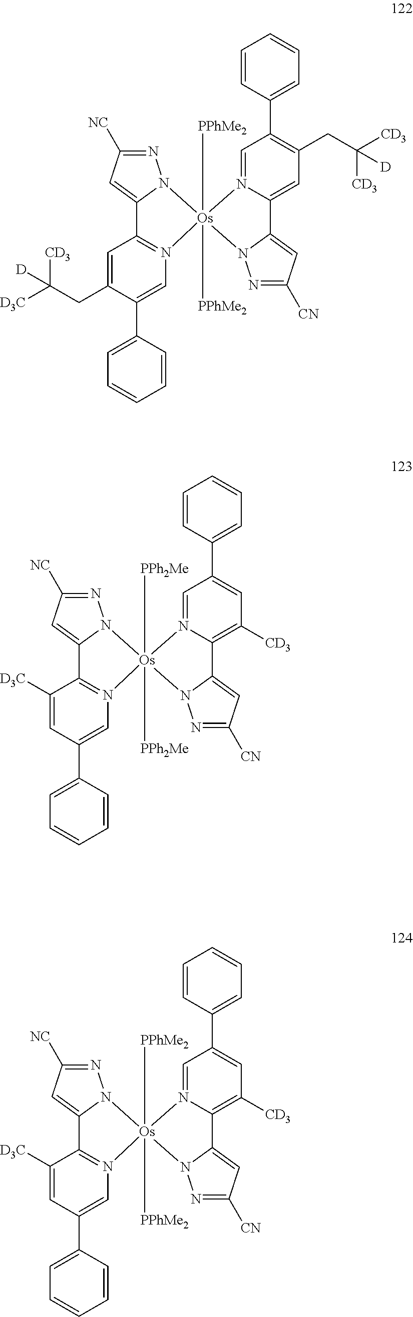

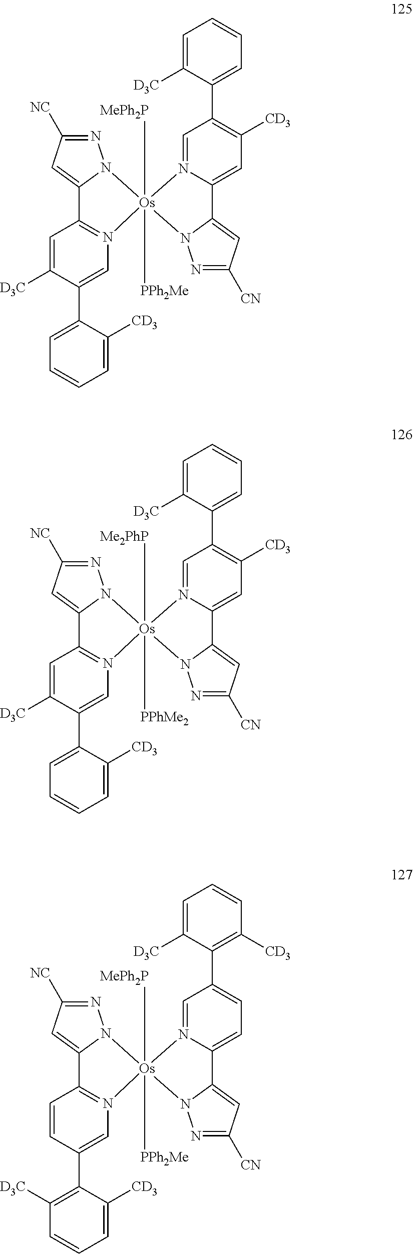

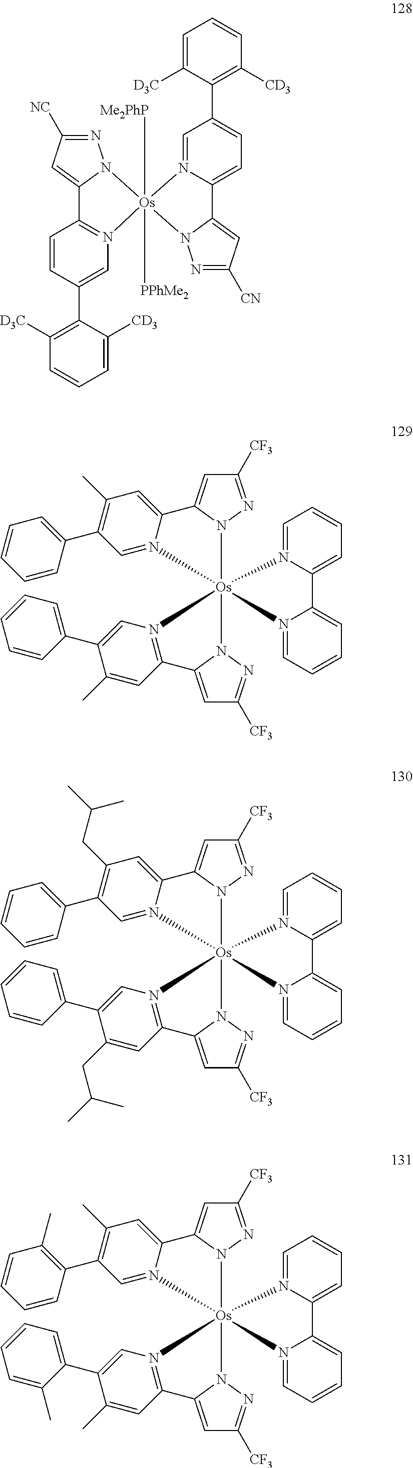

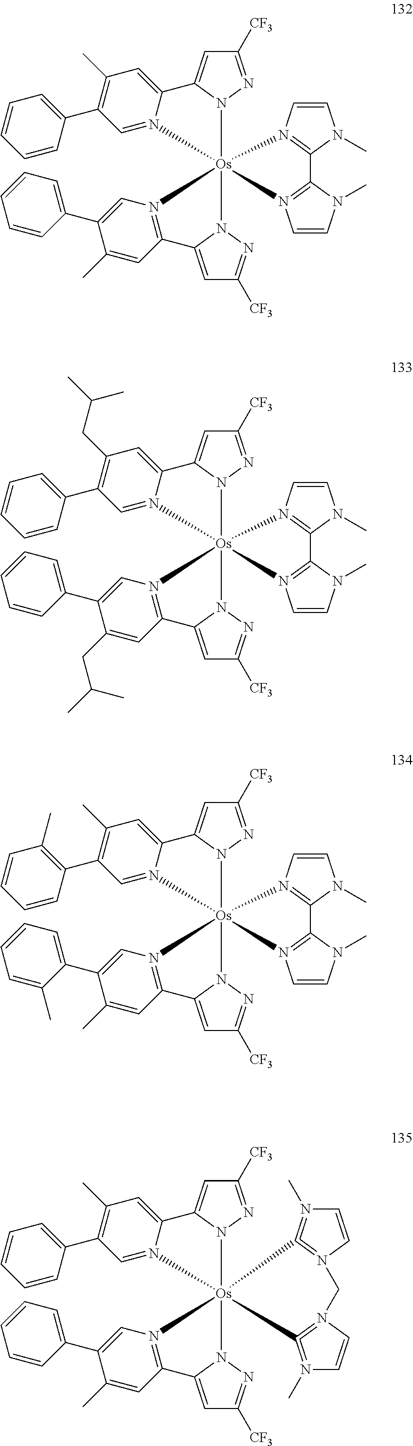

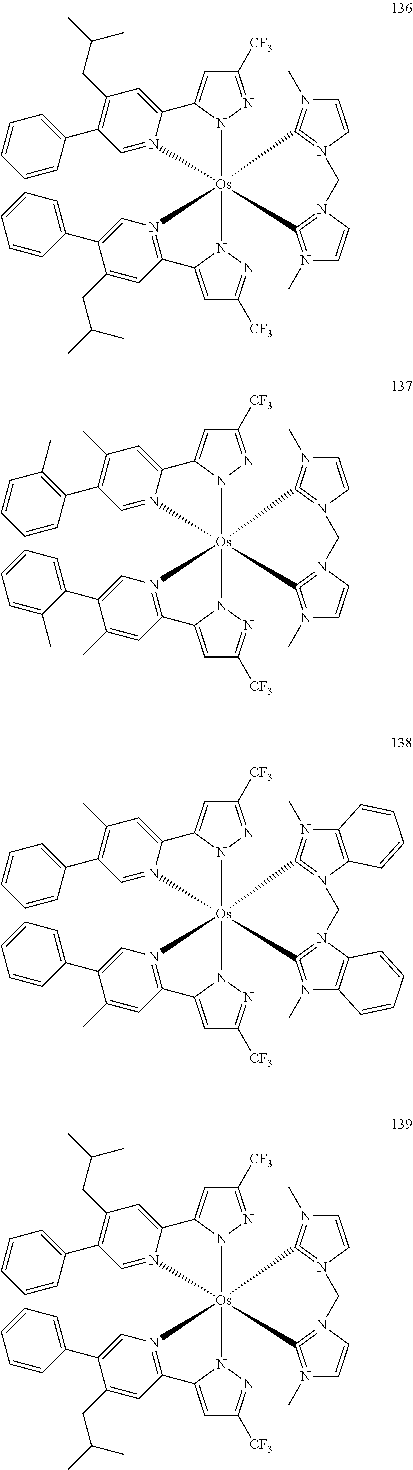

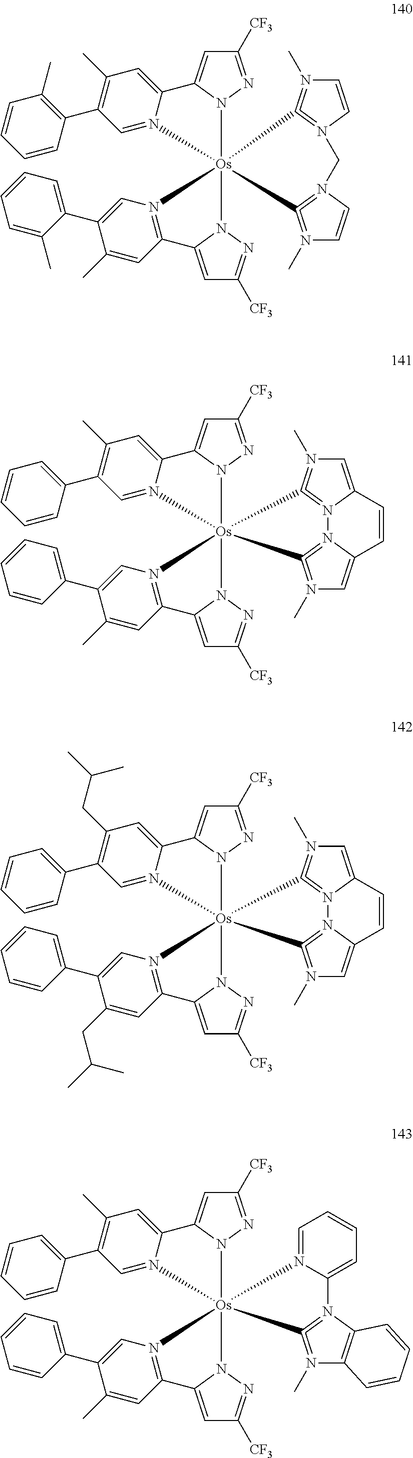

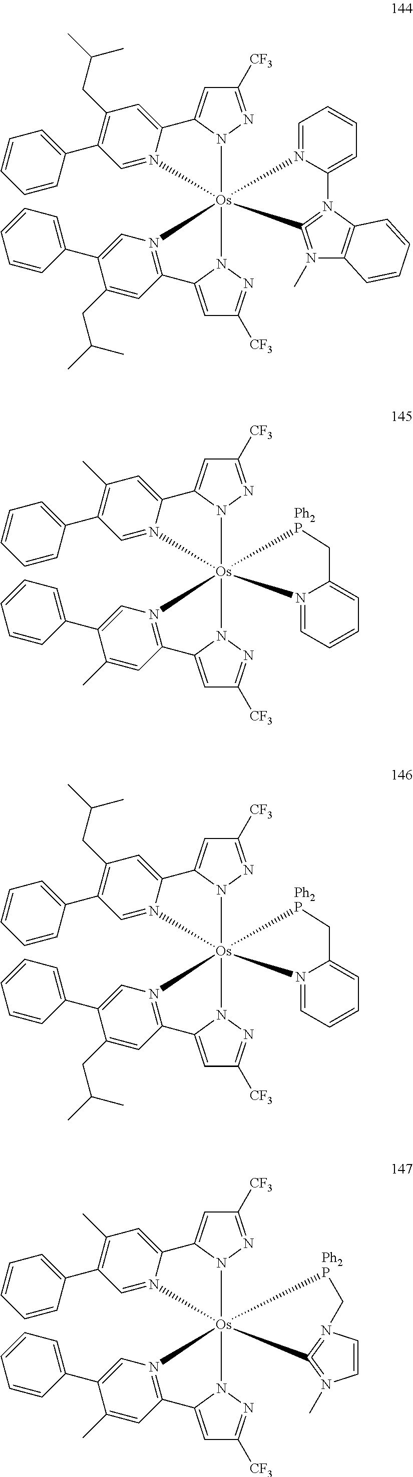

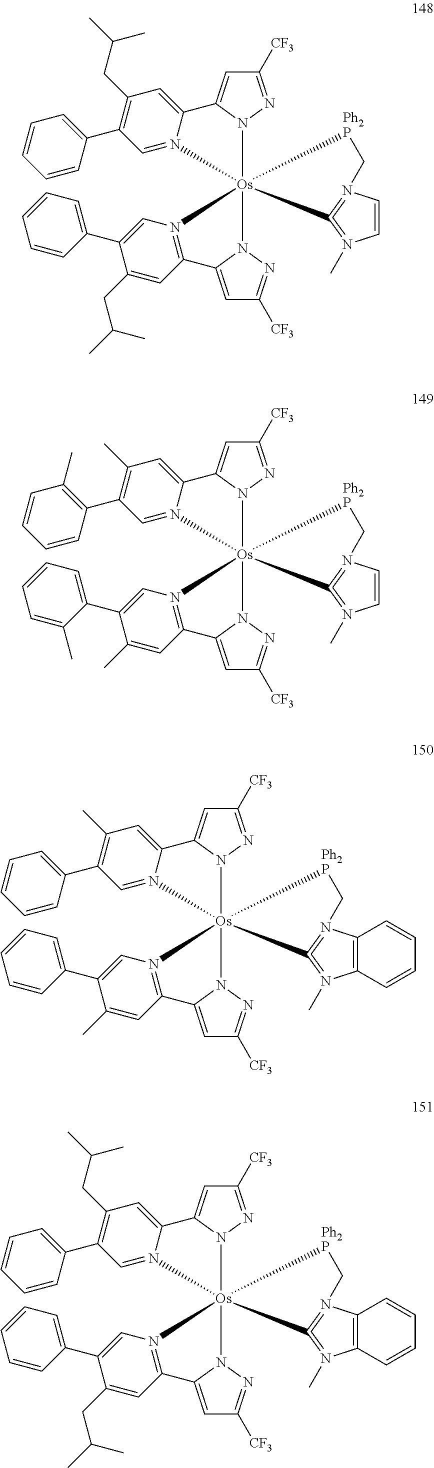

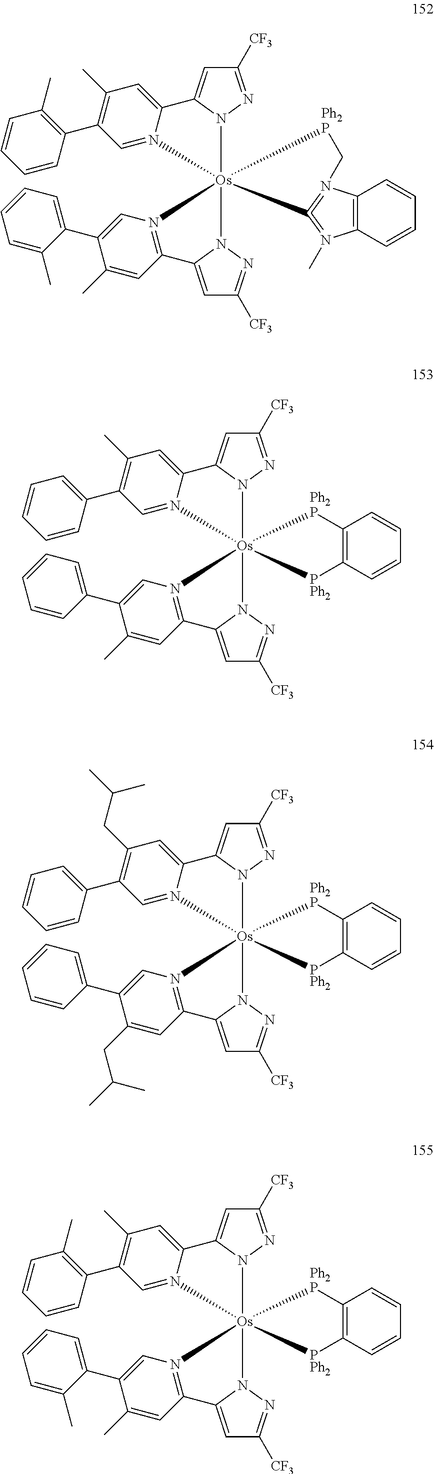

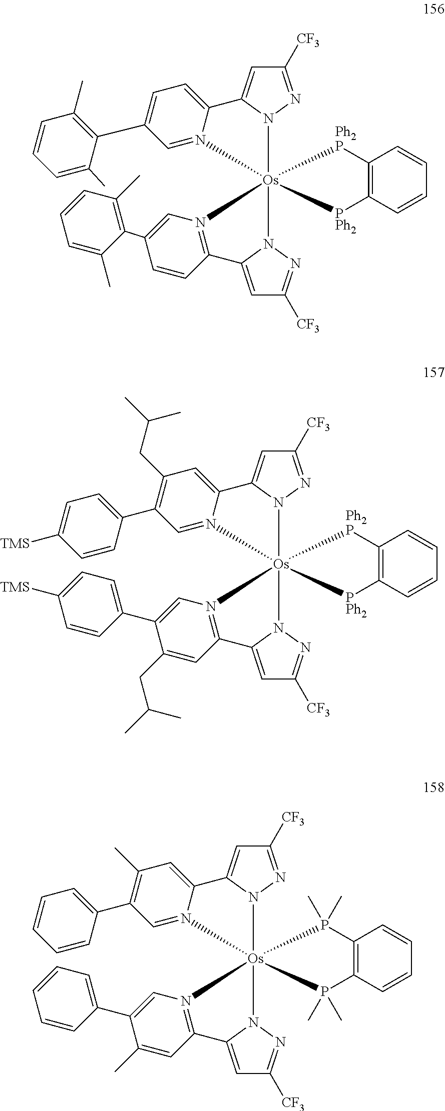

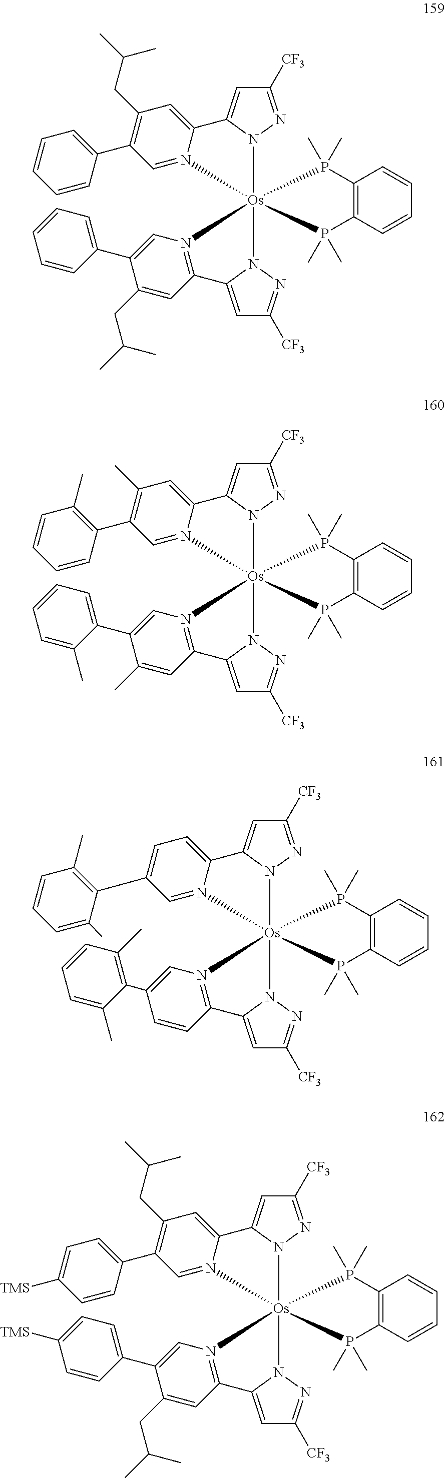

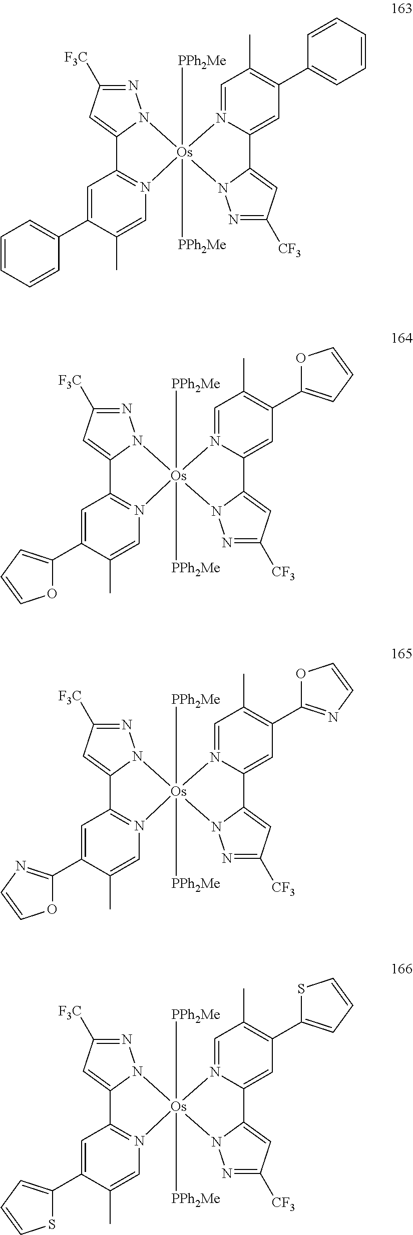

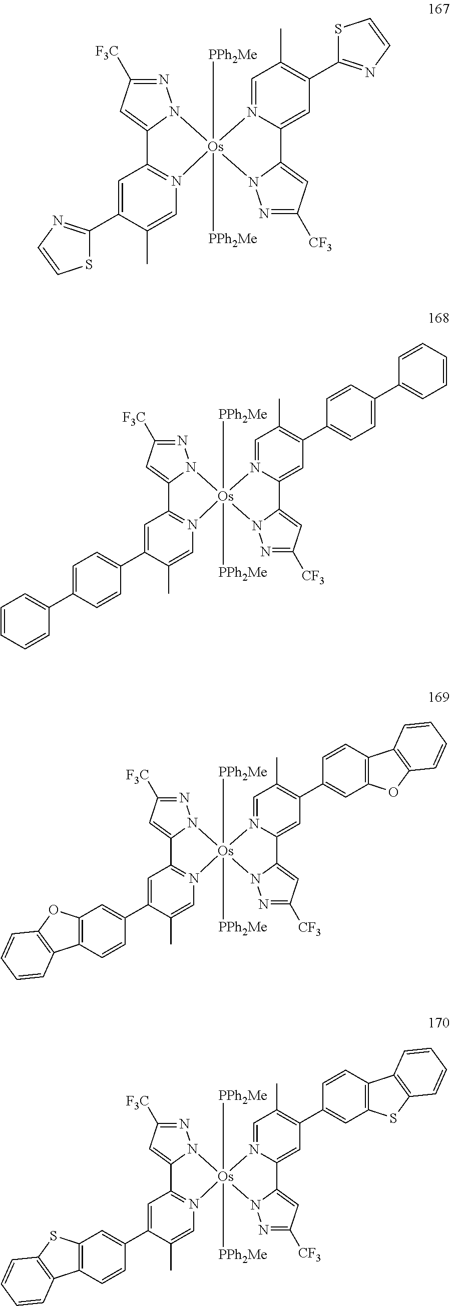

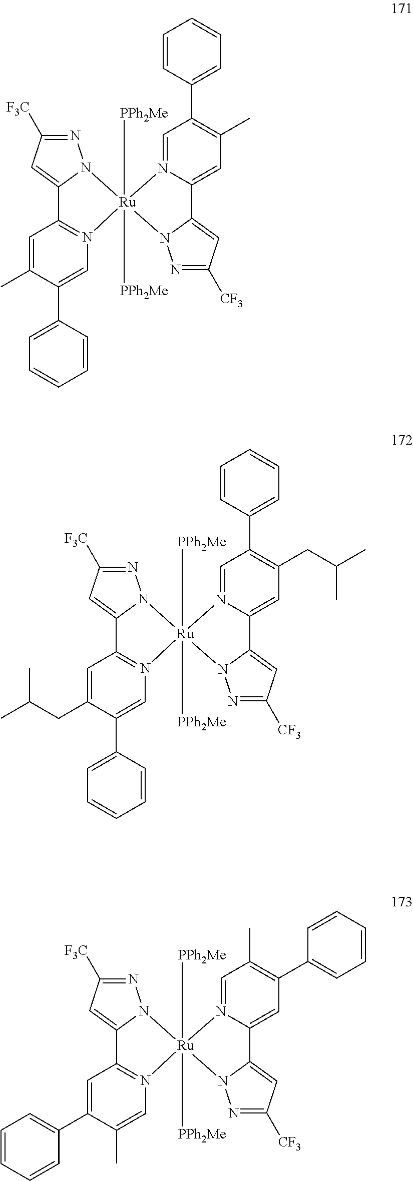

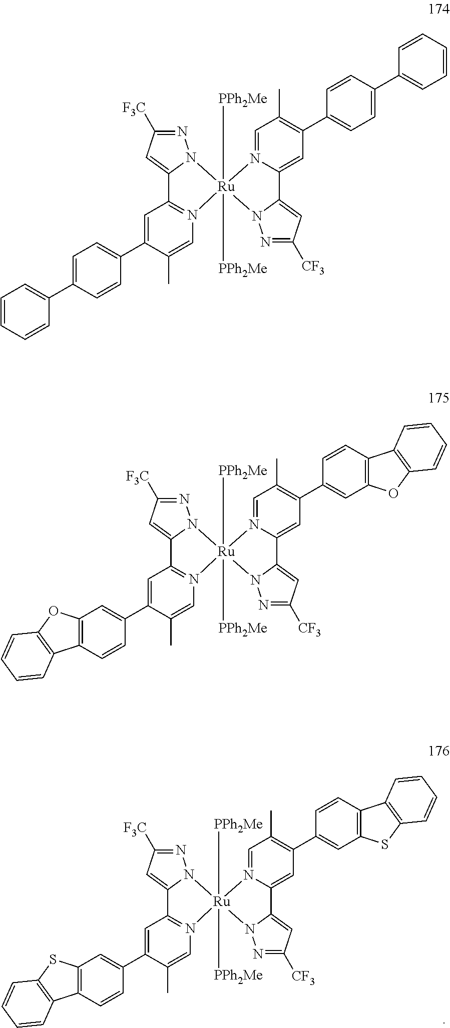

19. An organic light-emitting device comprising:
a first electrode;
a second electrode; and
an organic layer disposed between the first electrode and the second electrode,
wherein the organic layer comprises an emission layer and at least one organometallic compound of claim 1.

20. The organic light-emitting device of claim 19, wherein the emission layer comprises the at least one organometallic compound.
